(19) United States
(12) Patent Application Publication
(10) Pub. No.: US 2003/0015767 A1
(43) Pub. Date: Jan. 23, 2003

(54) Structure and method for fabricating semiconductor structures and devices with integrated control components

(75) Inventors: Rudy M. Emrick, Gilbert, AZ (US); Nestor J. Escalera, Gilbert, AZ (US); Bryan K. Farber, Chandler, AZ (US); Stephen K. Rockwell, Mesa, AZ (US); John E. Holmes, Scottsdale, AZ (US); Bruce A. Bosco, Phoenix, AZ (US); Steven J. Franson, Scottsdale, AZ (US)

Correspondence Address: OBLON SPIVAK MCCLELLAND MAIER & NEUSTADT PC, FOURTH FLOOR, 1755 JEFFERSON DAVIS HIGHWAY, ARLINGTON, VA, 22202, US

(73) Assignee: MOTOROLA, INC., Schaumburg, IL

(21) Appl. No.: 09/905,932

(22) Filed: Jul. 17, 2001

(51) Int. Cl. H01L 29/00

(52) U.S. Cl. 257/528; 257/499

(57) ABSTRACT

Controlling and controlled components are integrated on a monolithic device. High quality epitaxial layers of monocrystalline materials can be grown overlying monocrystalline substrates such as large silicon wafers by forming a compliant substrate for growing the monocrystalline layers. An accommodating buffer layer comprises a layer of monocrystalline oxide spaced apart from a silicon wafer by an amorphous interface layer of silicon oxide. The amorphous interface layer dissipates strain and permits the growth of a high quality monocrystalline oxide accommodating buffer layer. The accommodating buffer layer is lattice matched to both the underlying silicon wafer and the overlying monocrystalline material layer. Any lattice mismatch between the accommodating buffer layer and the underlying silicon substrate is taken care of by the amorphous interface layer. In addition, formation of a compliant substrate may include utilizing surfactant enhanced epitaxy, epitaxial growth of single crystal silicon onto single crystal oxide, and epitaxial growth of Zintl phase materials. By providing both compound and Group IV semiconductor materials in one integrated circuit, both control and controlled components are integrated on one device.

### CROSS REFERENCE TO RELATED APPLICATIONS

This application is related to application Docket No. JG00474, by Rudy M. Emrick and Nestor J. Escalera, entitled “Structure and Method for Fabricating Power Combining Amplifiers,” filed concurrently herewith and assigned to Motorola, Inc.

### FIELD OF THE INVENTION

This invention relates generally to semiconductor structures and devices and to a method for their fabrication, and more specifically to semiconductor structures and devices and to the fabrication and use of integrated control semiconductor structures, devices, and integrated circuits that include a monocrystalline material layer comprised of semiconductor material, compound semiconductor material, and/or other types of material such as metals and non-metals.

### BACKGROUND OF THE INVENTION

Control devices are fabricated on silicon. Any integrated components being controlled are also formed in the same silicon. The silicon used for the integrated control semiconductor structures limits the controlled components characteristics. Alternatively, the control semiconductor structures are not integrated with the controlled components, resulting in larger circuits with lossy connections.

Semiconductor devices often include multiple layers of conductive, insulating, and semiconductive layers. Often, the desirable properties of such layers improve with the crystallinity of the layer. For example, the electron mobility and band gap of semiconductive layers improves as the crystallinity of the layer increases. Similarly, the free electron concentration of conductive layers and the electron charge displacement and electron energy recoverability of insulative or dielectric films improves as the crystallinity of these layers increases.

For many years, attempts have been made to grow various monolithic thin films on a foreign substrate such as silicon (Si). To achieve optimal characteristics of the various monolithic layers, however, a monocrystalline film of high crystalline quality is desired. Attempts have been made, for example, to grow various monocrystalline layers on a substrate such as germanium, silicon, and various insulators. These attempts have generally been unsuccessful because lattice mismatches between the host crystal and the grown crystal have caused the resulting layer of monocrystalline material to be of low crystalline quality.

If a large area thin film of high quality monocrystalline material was available at low cost, a variety of semiconductor devices could advantageously be fabricated in or using that film at a low cost compared to the cost of fabricating such devices beginning with a bulk wafer of semiconductor material or in an epitaxial film of such material on a bulk wafer of semiconductor material. In addition, if a thin film of high quality monocrystalline material could be realized beginning with a bulk wafer such as a silicon wafer, an integrated device structure could be achieved that took advantage of the best properties of both the silicon and the high quality monocrystalline material.

Accordingly, a need exists for a semiconductor structure that provides a high quality monocrystalline film or layer over another monocrystalline material and for a process for making such a structure. In other words, there is a need for providing the formation of a monocrystalline substrate that is compliant with a high quality monocrystalline material layer so that true two-dimensional growth can be achieved for the formation of quality semiconductor structures, devices and integrated circuits having grown monocrystalline film having the same crystal orientation as an underlying substrate. This monocrystalline material layer may be comprised of a semiconductor material, a compound semiconductor material, and other types of material such as metals and non-metals.

### BRIEF DESCRIPTION OF THE DRAWINGS

The present invention is illustrated by way of example and not limitation in the accompanying figures, in which like references indicate similar elements, and in which:

FIGS. 1, 2, and 3 illustrate schematically, in cross section, device structures in accordance with various embodiments of the invention;

FIG. 4 illustrates graphically the relationship between maximum attainable film thickness and lattice mismatch between a host crystal and a grown crystalline overlayer;

FIG. 5 illustrates a high resolution Transmission Electron Micrograph of a structure including a monocrystalline accommodating buffer layer;

FIG. 6 illustrates an x-ray diffraction spectrum of a structure including a monocrystalline accommodating buffer layer;

FIG. 7 illustrates a high resolution Transmission Electron Micrograph of a structure including an amorphous oxide layer;

FIG. 8 illustrates an x-ray diffraction spectrum of a structure including an amorphous oxide layer;

FIGS. 9-12 illustrate schematically, in cross-section, the formation of a device structure in accordance with another embodiment of the invention;

FIGS. 13-16 illustrate a probable molecular bonding structure of the device structures illustrated in FIGS. 9-12;

FIGS. 17-20 illustrate schematically, in cross-section, the formation of a device structure in accordance with still another embodiment of the invention;

FIGS. 21-23 illustrate schematically, in cross-section, the formation of yet another embodiment of a device structure in accordance with the invention;

FIGS. 24, 25 illustrate schematically, in cross section, device structures that can be used in accordance with various embodiments of the invention;

FIGS. 26-30 include illustrations of cross-sectional views of a portion of an integrated circuit that includes a compound semiconductor portion, a bipolar portion, and an MOS portion in accordance with what is shown herein;

FIGS. 31-37 include illustrations of cross-sectional views of a portion of another integrated circuit that includes a semiconductor laser and a MOS transistor in accordance with what is shown herein;

FIG. 38 illustrates a circuit diagram of an integrated temperature control circuit formed on a monolithic device;

FIG. 39 illustrates a circuit diagram of a temperature sensor integrated circuit of one embodiment;

FIG. 40 illustrates a circuit diagram of an integrated bias voltage control circuit with a constant current circuit formed on a monolithic device;

FIG. 41 illustrates a circuit diagram of an integrated drain and gate bias control circuit formed on a monolithic device;

FIG. 42 illustrates a circuit diagram of a voltage regulator of one embodiment;

FIG. 43 illustrates a circuit diagram of an integrated bias control circuit with a feedback loop formed on a monolithic device;

FIG. 44 illustrates a circuit diagram of an integrated bias control circuit with selectable bias connections formed on a monolithic device;

FIGS. 45 and 47 illustrate circuit diagrams of integrated modulation control circuits formed on a monolithic device;

FIG. 46 illustrates a circuit diagram of an integrated frequency control circuit formed on a monolithic device;

FIG. 48 illustrates a circuit diagram of an integrated automatic gain control and telemetry circuits formed on a monolithic device;

FIG. 49 illustrates a circuit diagram of an integrated redundant or selectable circuit control circuit formed on a monolithic device;

FIGS. 50 and 51 illustrate circuit diagrams of integrated circuit selection control circuits formed on a monolithic device;

FIGS. 52 and 53 illustrate circuit diagrams of integrated controlling and controlled devices formed on a monolithic device;

FIG. 54 illustrates a flow chart summarizing the process of one embodiment for fabricating a semiconductor structure.

Skilled artisans will appreciate that elements in the figures are illustrated for simplicity and clarity and have not necessarily been drawn to scale. For example, the dimensions of some of the elements in the figures may be exaggerated relative to other elements to help to improve understanding of embodiments of the present invention.

### DETAILED DESCRIPTION OF THE DRAWINGS

Control and controlled circuits are integrated onto one monolithic device having two different monocrystalline semiconductor materials, such as monocrystalline silicon and monocrystalline compound semiconductor material. Control semiconductor components formed in one material, such as a Group IV material, are integrated with controlled components formed in another material, such as compound semiconductor materials. Both control and controlled components using different materials may be integrated on one monolithic device. For example, radio or microwave frequency circuits formed in compound semiconductors are controlled by transistor or other circuits formed in silicon on the same semiconductor structure or monolithic device. Integration on one monolithic device allows for low cost, low loss implementation of control and controlled circuits with maximized application. In alternative embodiments, a plurality of control and controlled components are formed in compound semiconductor materials that are larger due to growth on a Group IV substrate.

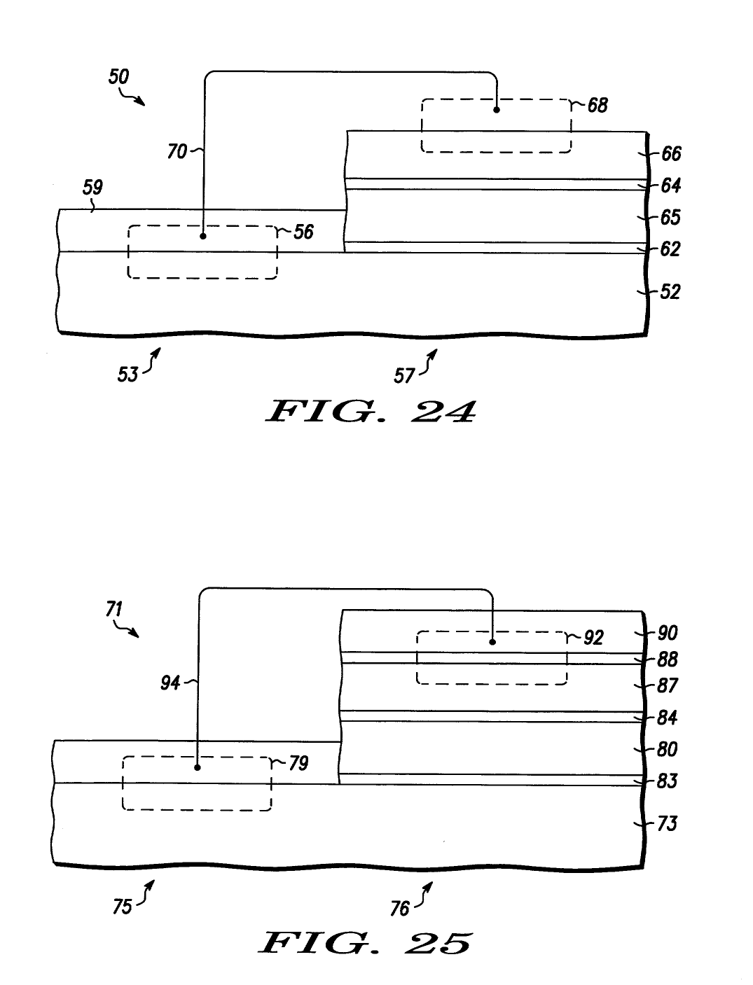

The integrated control and controlled circuit is (1) formed on a monolithic device having a plurality of different semiconductor materials, (2) formed of active or passive devices, and (3) comprises integrated combinations of the active and/or passive devices. The description related to FIGS. 1-23 describe formation of the monolithic device or semiconductor structure. The description related to FIGS. 24-37 describes formation of exemplary active and passive devices. The description related to FIGS. 38-53 describes the combinations of the devices to form integrated circuits with control and controlled components.

FIG. 1 illustrates schematically, in cross section, a portion of a semiconductor structure 20 in accordance with an embodiment of the invention. Semiconductor structure 20 includes a monocrystalline substrate 22, accommodating buffer layer 24 comprising a monocrystalline material, and a monocrystalline material layer 26. In this context, the term “monocrystalline” shall have the meaning commonly used within the semiconductor industry. The term shall refer to materials that are a single crystal or that are substantially a single crystal and shall include those materials having a relatively small number of defects such as dislocations and the like as are commonly found in substrates of silicon or germanium or mixtures of silicon and germanium and epitaxial layers of such materials commonly found in the semiconductor industry.

In accordance with one embodiment of the invention, structure 20 also includes an amorphous intermediate layer 28 positioned between substrate 22 and accommodating buffer layer 24. Structure 20 may also include a template layer 30 between the accommodating buffer layer and monocrystalline material layer 26. As will be explained more fully below, the template layer helps to initiate the growth of the monocrystalline material layer on the accommodating buffer layer. The amorphous intermediate layer helps to relieve the strain in the accommodating buffer layer and by doing so, aids in the growth of a high crystalline quality accommodating buffer layer.

Substrate 22, in accordance with an embodiment of the invention, is a monocrystalline semiconductor or compound semiconductor wafer, preferably of large diameter. The wafer can be of, for example, a material from Group IV of the periodic table. Examples of Group IV semiconductor materials include silicon, germanium, mixed silicon and germanium, mixed silicon and carbon, mixed silicon, germanium and carbon, and the like. Preferably substrate 22 is a wafer containing silicon or germanium, and most preferably is a high quality monocrystalline silicon wafer as used in the semiconductor industry. Accommodating buffer layer 24 is preferably a monocrystalline oxide or nitride material epitaxially grown on the underlying substrate. In accordance with one embodiment of the invention, amorphous intermediate layer 28 is grown on substrate 22 at the interface between substrate 22 and the growing accommodating buffer layer by the oxidation of substrate 22 during the growth of layer 24. The amorphous intermediate layer serves to relieve strain that might otherwise occur in the monocrystalline accommodating buffer layer as a result of differences in the lattice constants of the substrate and the buffer layer. As used herein, lattice constant refers to the distance between atoms of a cell measured in the plane of the surface. If such strain is not relieved by the amorphous intermediate layer, the strain may cause defects in the crystalline structure of the accommodating buffer layer. Defects in the crystalline structure of the accommodating buffer layer, in turn, would make it difficult to achieve a high quality crystalline structure in monocrystalline material layer 26 which may comprise a semiconductor material, a compound semiconductor material, or another type of material such as a metal or a non-metal.

Accommodating buffer layer 24 is preferably a monocrystalline oxide or nitride material selected for its crystalline compatibility with the underlying substrate and with the overlying material layer. For example, the material could be an oxide or nitride having a lattice structure closely matched to the substrate and to the subsequently applied monocrystalline material layer. Materials that are suitable for the accommodating buffer layer include metal oxides such as the alkaline earth metal titanates, alkaline earth metal zirconates, alkaline earth metal hafnates, alkaline earth metal tantalates, alkaline earth metal ruthenates, alkaline earth metal niobates, alkaline earth metal vanadates, alkaline earth metal tin-based perovskites, lanthanum aluminate, lanthanum scandium oxide, and gadolinium oxide. Additionally, various nitrides such as gallium nitride, aluminum nitride, and boron nitride may also be used for the accommodating buffer layer. Most of these materials are insulators, although strontium ruthenate, for example, is a conductor. Generally, these materials are metal oxides or metal nitrides, and more particularly, these metal oxide or nitrides typically include at least two different metallic elements. In some specific applications, the metal oxides or nitrides may include three or more different metallic elements.

Amorphous interface layer 28 is preferably an oxide formed by the oxidation of the surface of substrate 22, and more preferably is composed of a silicon oxide. The thickness of layer 28 is sufficient to relieve strain attributed to mismatches between the lattice constants of substrate 22 and accommodating buffer layer 24. Typically, layer 28 has a thickness in the range of approximately 0.5-5 nm.

The material for monocrystalline material layer 26 can be selected, as desired, for a particular structure or application. For example, the monocrystalline material of layer 26 may comprise a compound semiconductor which can be selected, as needed for a particular semiconductor structure, from any of the Group IIIA and VA elements (III-V semiconductor compounds), mixed III-V compounds, Group II(A or B) and VIA elements (II-VI semiconductor compounds), and mixed II-VI compounds. Examples include gallium arsenide (GaAs), gallium indium arsenide (GaInAs), gallium aluminum arsenide (GaAlAs), indium phosphide (InP), cadmium sulfide (CdS), cadmium mercury telluride (CdHgTe), zinc selenide (ZnSe), zinc sulfur selenide (ZnSSe), and the like. However, monocrystalline material layer 26 may also comprise other semiconductor materials, metals, or non-metal materials, which are used in the formation of semiconductor structures, devices and/or integrated circuits.

Appropriate materials for template 30 are discussed below. Suitable template materials chemically bond to the surface of the accommodating buffer layer 24 at selected sites and provide sites for the nucleation of the epitaxial growth of monocrystalline material layer 26. When used, template layer 30 has a thickness ranging from about 1 to about 10 monolayers.

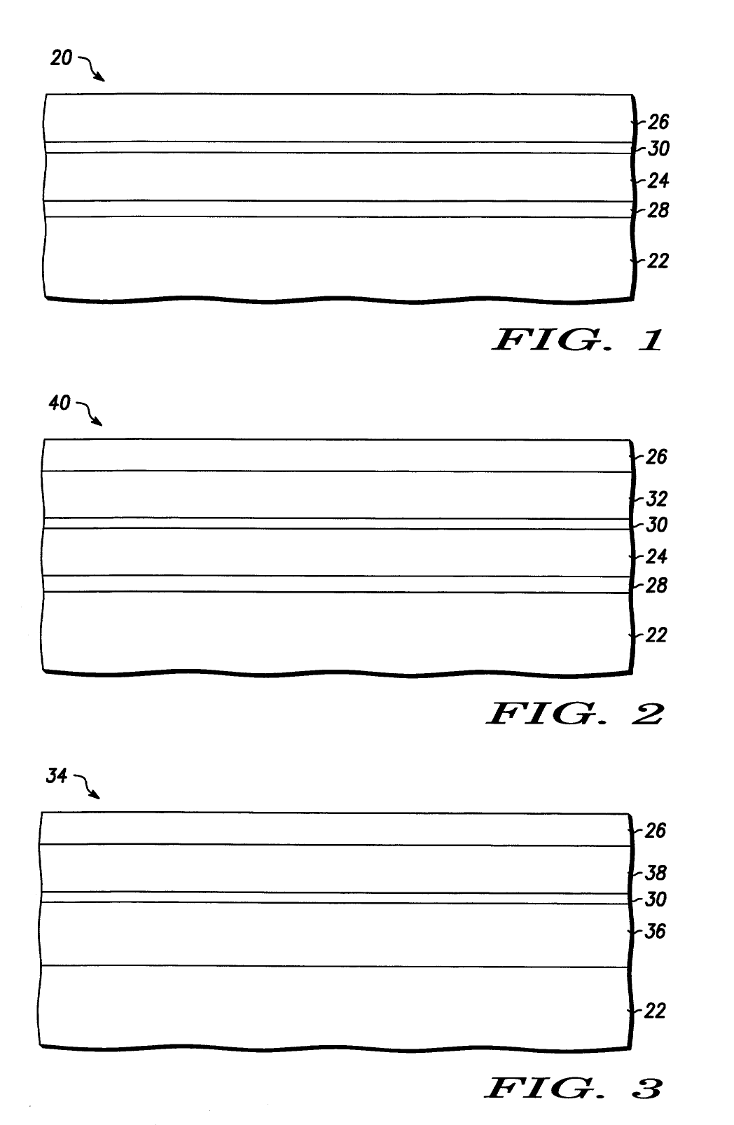

FIG. 2 illustrates, in cross section, a portion of a semiconductor structure 40 in accordance with a further embodiment of the invention. Structure 40 is similar to the previously described semiconductor structure 20, except that an additional buffer layer 32 is positioned between accommodating buffer layer 24 and monocrystalline material layer 26. Specifically, the additional buffer layer is positioned between template layer 30 and the overlying layer of monocrystalline material. The additional buffer layer, formed of a semiconductor or compound semiconductor material when the monocrystalline material layer 26 comprises a semiconductor or compound semiconductor material, serves to provide a lattice compensation when the lattice constant of the accommodating buffer layer cannot be adequately matched to the overlying monocrystalline semiconductor or compound semiconductor material layer.

FIG. 3 schematically illustrates, in cross section, a portion of a semiconductor structure 34 in accordance with another exemplary embodiment of the invention. Structure 34 is similar to structure 20, except that structure 34 includes an amorphous layer 36, rather than accommodating buffer layer 24 and amorphous interface layer 28, and an additional monocrystalline layer 38.

As explained in greater detail below, amorphous layer 36 may be formed by first forming an accommodating buffer layer and an amorphous interface layer in a similar manner to that described above. Monocrystalline layer 38 is then formed (by epitaxial growth) overlying the monocrystalline accommodating buffer layer. The accommodating buffer layer is then exposed to an anneal process to convert the monocrystalline accommodating buffer layer to an amorphous layer. Amorphous layer 36 formed in this manner comprises materials from both the accommodating buffer and interface layers, which amorphous layers may or may not amalgamate. Thus, layer 36 may comprise one or two amorphous layers. Formation of amorphous layer 36 between substrate 22 and additional monocrystalline layer 26 (subsequent to layer 38 formation) relieves stresses between layers 22 and 38 and provides a true compliant substrate for subsequent processing—e.g., monocrystalline material layer 26 formation.

The processes previously described above in connection with FIGS. 1 and 2 are adequate for growing monocrystalline material layers over a monocrystalline substrate. However, the process described in connection with FIG. 3, which includes transforming a monocrystalline accommodating buffer layer to an amorphous oxide layer, may be better for growing monocrystalline material layers because it allows any strain in layer 26 to relax.

Additional monocrystalline layer 38 may include any of the materials described throughout this application in connection with either of monocrystalline material layer 26 or additional buffer layer 32. For example, when monocrystalline material layer 26 comprises a semiconductor or compound semiconductor material, layer 38 may include monocrystalline Group IV or monocrystalline compound semiconductor materials.

In accordance with one embodiment of the present invention, additional monocrystalline layer 38 serves as an anneal cap during layer 36 formation and as a template for subsequent monocrystalline layer 26 formation. Accordingly, layer 38 is preferably thick enough to provide a suitable template for layer 26 growth (at least one monolayer) and thin enough to allow layer 38 to form as a substantially defect free monocrystalline material.

In accordance with another embodiment of the invention, additional monocrystalline layer 38 comprises monocrystalline material (e.g., a material discussed above in connection with monocrystalline layer 26) that is thick enough to form devices within layer 38. In this case, a semiconductor structure in accordance with the present invention does not include monocrystalline material layer 26. In other words, the semiconductor structure in accordance with this embodiment only includes one monocrystalline layer disposed above amorphous oxide layer 36.

The following non-limiting, illustrative examples illustrate various combinations of materials useful in structures 20, 40, and 34 in accordance with various alternative embodiments of the invention. These examples are merely illustrative, and it is not intended that the invention be limited to these illustrative examples.

### EXAMPLE 1

In accordance with one embodiment of the invention, monocrystalline substrate 22 is a silicon substrate oriented in the (100) direction. The silicon substrate can be, for example, a silicon substrate as is commonly used in making complementary metal oxide semiconductor (CMOS) integrated circuits having a diameter of about 200-300 mm. In accordance with this embodiment of the invention, accommodating buffer layer 24 is a monocrystalline layer of Sr_{z}Ba_{1-z}TiO₃ where z ranges from 0 to 1 and the amorphous intermediate layer is a layer of silicon oxide (SiOₓ) formed at the interface between the silicon substrate and the accommodating buffer layer. The value of z is selected to obtain one or more lattice constants closely matched to corresponding lattice constants of the subsequently formed layer 26. The accommodating buffer layer can have a thickness of about 2 to about 100 nanometers (nm) and preferably has a thickness of about 5 nm. In general, it is desired to have an accommodating buffer layer thick enough to isolate the monocrystalline material layer 26 from the substrate to obtain the desired electrical and optical properties. Layers thicker than 100 nm usually provide little additional benefit while increasing cost unnecessarily; however, thicker layers may be fabricated if needed. The amorphous intermediate layer of silicon oxide can have a thickness of about 0.5-5 nm, and preferably a thickness of about 1 to 2 nm.

In accordance with this embodiment of the invention, monocrystalline material layer 26 is a compound semiconductor layer of gallium arsenide (GaAs) or aluminum gallium arsenide (AlGaAs) having a thickness of about 1 nm to about 100 micrometers (μm) and preferably a thickness of about 0.5 μm to 10 μm. The thickness generally depends on the application for which the layer is being prepared. To facilitate the epitaxial growth of the gallium arsenide or aluminum gallium arsenide on the monocrystalline oxide, a template layer is formed by capping the oxide layer. The template layer is preferably 1-10 monolayers of Ti—As, Sr—O—As, Sr—Ga—O, or Sr—Al—O. By way of a preferred example, 1-2 monolayers of Ti—As or Sr—Ga—O have been illustrated to successfully grow GaAs layers.

### EXAMPLE 2

In accordance with a further embodiment of the invention, monocrystalline substrate 22 is a silicon substrate as described above. The accommodating buffer layer is a monocrystalline oxide of strontium or barium zirconate or hafnate in a cubic or orthorhombic phase with an amorphous intermediate layer of silicon oxide formed at the interface between the silicon substrate and the accommodating buffer layer. The accommodating buffer layer can have a thickness of about 2-100 nm and preferably has a thickness of at least 5 nm to ensure adequate crystalline and surface quality and is formed of a monocrystalline SrZrO₃, BaZrO₃, SrHfO₃, BaSnO₃ or BaHfO₃. For example, a monocrystalline oxide layer of BaZrO₃ can grow at a temperature of about 700 degrees C. The lattice structure of the resulting crystalline oxide exhibits a 45-degree rotation with respect to the substrate silicon lattice structure.

An accommodating buffer layer formed of these zirconate or hafnate materials is suitable for the growth of a monocrystalline material layer that comprises compound semiconductor materials in the indium phosphide (InP) system. In this system, the compound semiconductor material can be, for example, indium phosphide (InP), indium gallium arsenide (InGaAs), aluminum indium arsenide, (AlInAs), or aluminum gallium indium arsenic phosphide (AlGaInAsP), having a thickness of about 1.0 nm to 10 μm. A suitable template for this structure is 1-10 monolayers of zirconium-arsenic (Zr—As), zirconium-phosphorus (Zr—P), hafnium-arsenic (Hf—As), hafnium-phosphorus (Hf—P), strontium-oxygen-arsenic (Sr—O—As), strontium-oxygen-phosphorus (Sr—O—P), barium-oxygen-arsenic (Ba—O—As), indium-strontium-oxygen (In—Sr—O), or bariumoxygen-phosphorus (Ba—O—P), and preferably 1-2 monolayers of one of these materials. By way of an example, for a barium zirconate accommodating buffer layer, the surface is terminated with 1-2 monolayers of zirconium followed by deposition of 1-2 monolayers of arsenic to form a Zr—As template. A monocrystalline layer of the compound semiconductor material from the indium phosphide system is then grown on the template layer. The resulting lattice structure of the compound semiconductor material exhibits a 45-degree rotation with respect to the accommodating buffer layer lattice structure and a lattice mismatch to (100) InP of less than 2.5%, and preferably less than about 1.0%.

### EXAMPLE 3

In accordance with a further embodiment of the invention, a structure is provided that is suitable for the growth of an epitaxial film of a monocrystalline material comprising a II-VI material overlying a silicon substrate. The substrate is preferably a silicon wafer as described above. A suitable accommodating buffer layer material is SrₓBa₁₋ₓTiO₃, where x ranges from 0 to 1, having a thickness of about 2-100 nm and preferably a thickness of about 5-15 nm. Where the monocrystalline layer comprises a compound semiconductor material, the II-VI compound semiconductor material can be, for example, zinc selenide (ZnSe) or zinc sulfur selenide (ZnSSe). A suitable template for this material system includes 1-10 monolayers of zinc-oxygen (Zn—O) followed by 1-2 monolayers of an excess of zinc followed by the selenidation of zinc on the surface. Alternatively, a template can be, for example, 1-10 monolayers of strontium-sulfur (Sr—S) followed by the ZnSeS.

### EXAMPLE 4

This embodiment of the invention is an example of structure 40 illustrated in FIG. 2. Substrate 22, accommodating buffer layer 24, and monocrystalline material layer 26 can be similar to those described in example 1. In addition, an additional buffer layer 32 serves to alleviate any strains that might result from a mismatch of the crystal lattice of the accommodating buffer layer and the lattice of the monocrystalline material. Buffer layer 32 can be a layer of germanium or a GaAs, an aluminum gallium arsenide (AlGaAs), an indium gallium phosphide (InGaP), an aluminum gallium phosphide (AlGaP), an indium gallium arsenide (InGaAs), an aluminum indium phosphide (AlInP), a gallium arsenide phosphide (GaAsP), or an indium gallium phosphide (InGaP) strain compensated superlattice. In accordance with one aspect of this embodiment, buffer layer 32 includes a GaAsₓP₁₋ₓ superlattice, wherein the value of x ranges from 0 to 1. In accordance with another aspect, buffer layer 32 includes an InyGa_{1-y}P superlattice, wherein the value of y ranges from 0 to 1. By varying the value of x or y, as the case may be, the lattice constant is varied from bottom to top across the superlattice to create a match between lattice constants of the underlying oxide and the overlying monocrystalline material which in this example is a compound semiconductor material. The compositions of other compound semiconductor materials, such as those listed above, may also be similarly varied to manipulate the lattice constant of layer 32 in a like manner. The superlattice can have a thickness of about 50-500 nm and preferably has a thickness of about 100-200 nm. The template for this structure can be the same of that described in example 1. Alternatively, buffer layer 32 can be a layer of monocrystalline germanium having a thickness of 1-50 nm and preferably having a thickness of about 2-20 nm. In using a germanium buffer layer, a template layer of either germanium-strontium (Ge—Sr) or germanium-titanium (Ge—Ti) having a thickness of about one monolayer can be used as a nucleating site for the subsequent growth of the monocrystalline material layer which in this example is a compound semiconductor material. The formation of the oxide layer is capped with either a monolayer of strontium or a monolayer of titanium to act as a nucleating site for the subsequent deposition of the monocrystalline germanium. The monolayer of strontium or titanium provides a nucleating site to which the first monolayer of germanium can bond.

### EXAMPLE 5

This example also illustrates materials useful in a structure 40 as illustrated in FIG. 2. Substrate material 22, accommodating buffer layer 24, monocrystalline material layer 26 and template layer 30 can be the same as those described above in example 2. In addition, additional buffer layer 32 is inserted between the accommodating buffer layer and the overlying monocrystalline material layer. The buffer layer, a further monocrystalline material which in this instance comprises a semiconductor material, can be, for example, a graded layer of indium gallium arsenide (InGaAs) or indium aluminum arsenide (InAlAs). In accordance with one aspect of this embodiment, additional buffer layer 32 includes InGaAs, in which the indium composition varies from 0 to about 50%. The additional buffer layer 32 preferably has a thickness of about 10-30 nm. Varying the composition of the buffer layer from GaAs to InGaAs serves to provide a lattice match between the underlying monocrystalline oxide material and the overlying layer of monocrystalline material which in this example is a compound semiconductor material. Such a buffer layer is especially advantageous if there is a lattice mismatch between accommodating buffer layer 24 and monocrystalline material layer 26.

### EXAMPLE 6

This example provides exemplary materials useful in structure 34, as illustrated in FIG. 3. Substrate material 22, template layer 30, and monocrystalline material layer 26 may be the same as those described above in connection with example 1.

Amorphous layer 36 is an amorphous oxide layer which is suitably formed of a combination of amorphous intermediate layer materials (e.g., layer 28 materials as described above) and accommodating buffer layer materials (e.g., layer 24 materials as described above). For example, amorphous layer 36 may include a combination of SiOₓ and Sr_{z}Ba_{1-z}, TiO₃ (where z ranges from 0 to 1), which combine or mix, at least partially, during an anneal process to form amorphous oxide layer 36.

The thickness of amorphous layer 36 may vary from application to application and may depend on such factors as desired insulating properties of layer 36, type of monocrystalline material comprising layer 26, and the like. In accordance with one exemplary aspect of the present embodiment, layer 36 thickness is about 2 nm to about 100 nm, preferably about 2-10 nm, and more preferably about 5-6 nm.

Layer 38 comprises a monocrystalline material that can be grown epitaxially over a monocrystalline oxide material such as material used to form accommodating buffer layer 24. In accordance with one embodiment of the invention, layer 38 includes the same materials as those comprising layer 26. For example, if layer 26 includes GaAs, layer 38 also includes GaAs. However, in accordance with other embodiments of the present invention, layer 38 may include materials different from those used to form layer 26. In accordance with one exemplary embodiment of the invention, layer 38 is about 1 monolayer to about 100 nm thick.

Referring again to FIGS. 1-3, substrate 22 is a monocrystalline substrate such as a monocrystalline silicon or gallium arsenide substrate. The crystalline structure of the monocrystalline substrate is characterized by a lattice constant and by a lattice orientation. In similar manner, accommodating buffer layer 24 is also a monocrystalline material and the lattice of that monocrystalline material is characterized by a lattice constant and a crystal orientation. The lattice constants of the accommodating buffer layer and the monocrystalline substrate must be closely matched or, alternatively, must be such that upon rotation of one crystal orientation with respect to the other crystal orientation, a substantial match in lattice constants is achieved. In this context the terms “substantially equal” and “substantially matched” mean that there is sufficient similarity between the lattice constants to permit the growth of a high quality crystalline layer on the underlying layer.

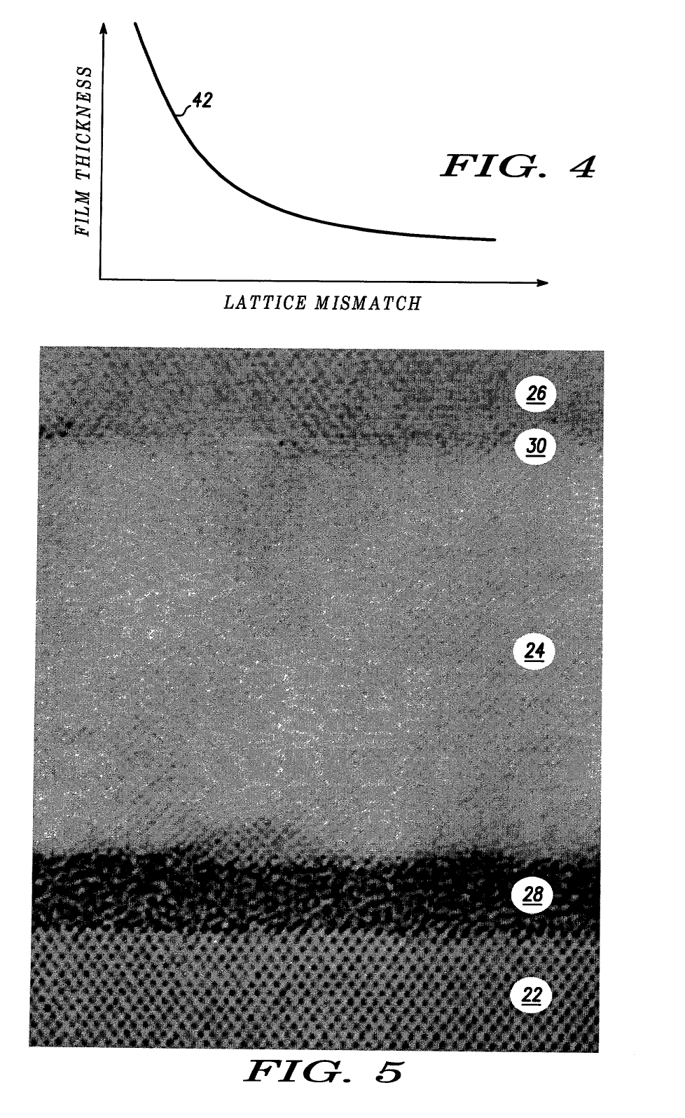

FIG. 4 illustrates graphically the relationship of the achievable thickness of a grown crystal layer of high crystalline quality as a function of the mismatch between the lattice constants of the host crystal and the grown crystal. Curve 42 illustrates the boundary of high crystalline quality material. The area to the right of curve 42 represents layers that have a large number of defects. With no lattice mismatch, it is theoretically possible to grow an infinitely thick, high quality epitaxial layer on the host crystal. As the mismatch in lattice constants increases, the thickness of achievable, high quality crystalline layer decreases rapidly. As a reference point, for example, if the lattice constants between the host crystal and the grown layer are mismatched by more than about 2%, monocrystalline epitaxial layers in excess of about 20 nm cannot be achieved.

In accordance with one embodiment of the invention, substrate 22 is a (100) or ((111) oriented monocrystalline silicon wafer and accommodating buffer layer 24 is a layer of strontium barium titanate. Substantial matching of lattice constants between these two materials is achieved by rotating the crystal orientation of the titanate material by 45° with respect to the crystal orientation of the silicon substrate wafer. The inclusion in the structure of amorphous interface layer 28, a silicon oxide layer in this example, if it is of sufficient thickness, serves to reduce strain in the titanate monocrystalline layer that might result from any mismatch in the lattice constants of the host silicon wafer and the grown titanate layer. As a result, in accordance with an embodiment of the invention, a high quality, thick, monocrystalline titanate layer is achievable.

Still referring to FIGS. 1-3, layer 26 is a layer of epitaxially grown monocrystalline material and that crystalline material is also characterized by a crystal lattice constant and a crystal orientation. In accordance with one embodiment of the invention, the lattice constant of layer 26 differs from the lattice constant of substrate 22. To achieve high crystalline quality in this epitaxially grown monocrystalline layer, the accommodating buffer layer must be of high crystalline quality. In addition, in order to achieve high crystalline quality in layer 26, substantial matching between the crystal lattice constant of the host crystal, in this case, the monocrystalline accommodating buffer layer, and the grown crystal is desired. With properly selected materials this substantial matching of lattice constants is achieved as a result of rotation of the crystal orientation of the grown crystal with respect to the orientation of the host crystal. For example, if the grown crystal is gallium arsenide, aluminum gallium arsenide, zinc selenide, or zinc sulfur selenide and the accommodating buffer layer is monocrystalline SrₓBa₁₋ₓTiO₃, substantial matching of crystal lattice constants of the two materials is achieved, wherein the crystal orientation of the grown layer is rotated by 45° with respect to the orientation of the host monocrystalline oxide. Similarly, if the host material is a strontium or barium zirconate or a strontium or barium hafnate or barium tin oxide and the compound semiconductor layer is indium phosphide or gallium indium arsenide or aluminum indium arsenide, substantial matching of crystal lattice constants can be achieved by rotating the orientation of the grown crystal layer by 45° with respect to the host oxide crystal. In some instances, a crystalline semiconductor buffer layer between the host oxide and the grown monocrystalline material layer can be used to reduce strain in the grown monocrystalline material layer that might result from small differences in lattice constants. Better crystalline quality in the grown monocrystalline material layer can thereby be achieved.

The following example illustrates a process, in accordance with one embodiment of the invention, for fabricating a semiconductor structure such as the structures depicted in FIGS. 1-3. The process starts by providing a monocrystalline semiconductor substrate comprising silicon or germanium. In accordance with a preferred embodiment of the invention, the semiconductor substrate is a silicon wafer having a (100) orientation. The substrate is preferably oriented on axis or, at most, about 4° off axis. At least a portion of the semiconductor substrate has a bare surface, although other portions of the substrate, as described below, may encompass other structures. The term “bare” in this context means that the surface in the portion of the substrate has been cleaned to remove any oxides, contaminants, or other foreign material. As is well known, bare silicon is highly reactive and readily forms a native oxide. The term “bare” is intended to encompass such a native oxide. A thin silicon oxide may also be intentionally grown on the semiconductor substrate, although such a grown oxide is not essential to the process in accordance with the invention. In order to epitaxially grow a monocrystalline oxide layer overlying the monocrystalline substrate, the native oxide layer must first be removed to expose the crystalline structure of the underlying substrate. The following process is preferably carried out by molecular beam epitaxy (MBE), although other epitaxial processes may also be used in accordance with the present invention. The native oxide can be removed by first thermally depositing a thin layer of strontium, barium, a combination of strontium and barium, or other alkaline earth metals or combinations of alkaline earth metals in an MBE apparatus. In the case where strontium is used, the substrate is then heated to a temperature of about 750° C. to cause the strontium to react with the native silicon oxide layer. The strontium serves to reduce the silicon oxide to leave a silicon oxide-free surface. The resultant surface, which exhibits an ordered 2×1 structure, includes strontium, oxygen, and silicon. The ordered 2×1 structure forms a template for the ordered growth of an overlying layer of a monocrystalline oxide. The template provides the necessary chemical and physical properties to nucleate the crystalline growth of an overlying layer.

In accordance with an alternate embodiment of the invention, the native silicon oxide can be converted and the substrate surface can be prepared for the growth of a monocrystalline oxide layer by depositing an alkaline earth metal oxide, such as strontium oxide, strontium barium oxide, or barium oxide, onto the substrate surface by MBE at a low temperature and by subsequently heating the structure to a temperature of about 750° C. At this temperature a solid state reaction takes place between the strontium oxide and the native silicon oxide causing the reduction of the native silicon oxide and leaving an ordered 2×1 structure with strontium, oxygen, and silicon remaining on the substrate surface. Again, this forms a template for the subsequent growth of an ordered monocrystalline oxide layer.

Following the removal of the silicon oxide from the surface of the substrate, in accordance with one embodiment of the invention, the substrate is cooled to a temperature in the range of about 200-800° C. and a layer of strontium titanate is grown on the template layer by molecular beam epitaxy. The MBE process is initiated by opening shutters in the MBE apparatus to expose strontium, titanium and oxygen sources. The ratio of strontium and titanium is approximately 1:1. The partial pressure of oxygen is initially set at a minimum value to grow stoichiometric strontium titanate at a growth rate of about 0.3-0.5 nm per minute. After initiating growth of the strontium titanate, the partial pressure of oxygen is increased above the initial minimum value. The overpressure of oxygen causes the growth of an amorphous silicon oxide layer at the interface between the underlying substrate and the growing strontium titanate layer. The growth of the silicon oxide layer results from the diffusion of oxygen through the growing strontium titanate layer to the interface where the oxygen reacts with silicon at the surface of the underlying substrate. The strontium titanate grows as an ordered (100) monocrystal with the (100) crystalline orientation rotated by 45° with respect to the underlying substrate. Strain that otherwise might exist in the strontium titanate layer because of the small mismatch in lattice constant between the silicon substrate and the growing crystal is relieved in the amorphous silicon oxide intermediate layer.

After the strontium titanate layer has been grown to the desired thickness, the monocrystalline strontium titanate is capped by a template layer that is conducive to the subsequent growth of an epitaxial layer of a desired monocrystalline material. For example, for the subsequent growth of a monocrystalline compound semiconductor material layer of gallium arsenide, the MBE growth of the strontium titanate monocrystalline layer can be capped by terminating the growth with 1-2 monolayers of titanium, 1-2 monolayers of titanium-oxygen or with 1-2 monolayers of strontium-oxygen. Following the formation of this capping layer, arsenic is deposited to form a Ti—As bond, a Ti—O—As bond or a Sr—O—As. Any of these form an appropriate template for deposition and formation of a gallium arsenide monocrystalline layer. Following the formation of the template, gallium is subsequently introduced to the reaction with the arsenic and gallium arsenide forms. Alternatively, gallium can be deposited on the capping layer to form a Sr—O—Ga bond, and arsenic is subsequently introduced with the gallium to form the GaAs.

FIG. 5 is a high resolution Transmission Electron Micrograph (TEM) of semiconductor material manufactured in accordance with one embodiment of the present invention. Single crystal SrTiO₃ accommodating buffer layer 24 was grown epitaxially on silicon substrate 22. During this growth process, amorphous interfacial layer 28 is formed which relieves strain due to lattice mismatch. GaAs compound semiconductor layer 26 was then grown epitaxially using template layer 30.

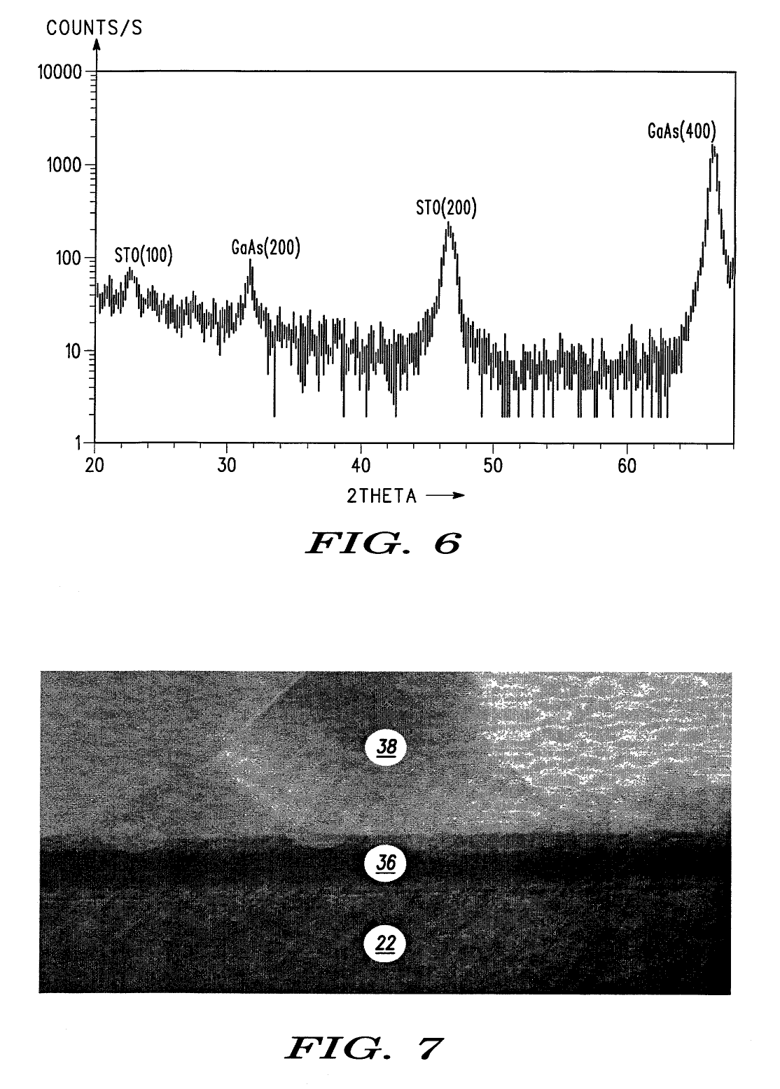

FIG. 6 illustrates an x-ray diffraction spectrum taken on a structure including GaAs monocrystalline layer 26 comprising GaAs grown on silicon substrate 22 using accommodating buffer layer 24. The peaks in the spectrum indicate that both the accommodating buffer layer 24 and GaAs compound semiconductor layer 26 are single crystal and (100) orientated.

The structure illustrated in FIG. 2 can be formed by the process discussed above with the addition of an additional buffer layer deposition step. The additional buffer layer 32 is formed overlying the template layer before the deposition of the monocrystalline material layer. If the buffer layer is a monocrystalline material comprising a compound semiconductor superlattice, such a superlattice can be deposited, by MBE for example, on the template described above. If instead the buffer layer is a monocrystalline material layer comprising a layer of germanium, the process above is modified to cap the strontium titanate monocrystalline layer with a final layer of either strontium or titanium and then by depositing germanium to react with the strontium or titanium. The germanium buffer layer can then be deposited directly on this template.

Structure 34, illustrated in FIG. 3, may be formed by growing an accommodating buffer layer, forming an amorphous oxide layer over substrate 22, and growing semiconductor layer 38 over the accommodating buffer layer, as described above. The accommodating buffer layer and the amorphous oxide layer are then exposed to an anneal process sufficient to change the crystalline structure of the accommodating buffer layer from monocrystalline to amorphous, thereby forming an amorphous layer such that the combination of the amorphous oxide layer and the now amorphous accommodating buffer layer form a single amorphous oxide layer 36. Layer 26 is then subsequently grown over layer 38. Alternatively, the anneal process may be carried out subsequent to growth of layer 26.

In accordance with one aspect of this embodiment, layer 36 is formed by exposing substrate 22, the accommodating buffer layer, the amorphous oxide layer, and monocrystalline layer 38 to a rapid thermal anneal process with a peak temperature of about 700° C. to about 1000° C. and a process time of about 5 seconds to about 10 minutes. However, other suitable anneal processes may be employed to convert the accommodating buffer layer to an amorphous layer in accordance with the present invention. For example, laser annealing, electron beam annealing, or “conventional” thermal annealing processes (in the proper environment) may be used to form layer 36. When conventional thermal annealing is employed to form layer 36, an overpressure of one or more constituents of layer 30 may be required to prevent degradation of layer 38 during the anneal process. For example, when layer 38 includes GaAs, the anneal environment preferably includes an overpressure of arsenic to mitigate degradation of layer 38.

As noted above, layer 38 of structure 34 may include any materials suitable for either of layers 32 or 26. Accordingly, any deposition or growth methods described in connection with either layer 32 or 26, may be employed to deposit layer 38.

FIG. 7 is a high resolution TEM of semiconductor material manufactured in accordance with the embodiment of the invention illustrated in FIG. 3. In accordance with this embodiment, a single crystal SrTiO₃ accommodating buffer layer was grown epitaxially on silicon substrate 22. During this growth process, an amorphous interfacial layer forms as described above. Next, additional monocrystalline layer 38 comprising a compound semiconductor layer of GaAs is formed above the accommodating buffer layer and the accommodating buffer layer is exposed to an anneal process to form amorphous oxide layer 36.

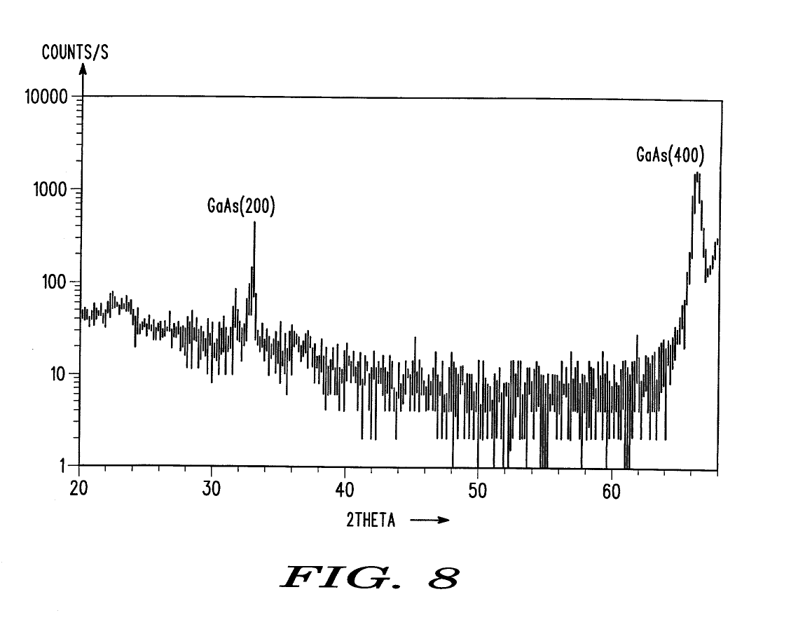

FIG. 8 illustrates an x-ray diffraction spectrum taken on a structure including additional monocrystalline layer 38 comprising a GaAs compound semiconductor layer and amorphous oxide layer 36 formed on silicon substrate 22. The peaks in the spectrum indicate that GaAs compound semiconductor layer 38 is single crystal and (100) orientated and the lack of peaks around 40 to 50 degrees indicates that layer 36 is amorphous.

The process described above illustrates a process for forming a semiconductor structure including a silicon substrate, an overlying oxide layer, and a monocrystalline material layer comprising a gallium arsenide compound semiconductor layer by the process of molecular beam epitaxy. The process can also be carried out by the process of chemical vapor deposition (CVD), metal organic chemical vapor deposition (MOCVD), migration enhanced epitaxy (MEE), atomic layer epitaxy (ALE), physical vapor deposition (PVD), chemical solution deposition (CSD), pulsed laser deposition (PLD), or the like. Further, by a similar process, other monocrystalline accommodating buffer layers such as alkaline earth metal titanates, zirconates, hafnates, tantalates, vanadates, ruthenates, and niobates, alkaline earth metal tin-based perovskites, lanthanum aluminate, lanthanum scandium oxide, and gadolinium oxide can also be grown. Further, by a similar process such as MBE, other monocrystalline material layers comprising other III-V and II-VI monocrystalline compound semiconductors, semiconductors, metals and non-metals can be deposited overlying the monocrystalline oxide accommodating buffer layer.

Each of the variations of monocrystalline material layer and monocrystalline oxide accommodating buffer layer uses an appropriate template for initiating the growth of the monocrystalline material layer. For example, if the accommodating buffer layer is an alkaline earth metal zirconate, the oxide can be capped by a thin layer of zirconium. The deposition of zirconium can be followed by the deposition of arsenic or phosphorus to react with the zirconium as a precursor to depositing indium gallium arsenide, indium aluminum arsenide, or indium phosphide respectively. Similarly, if the monocrystalline oxide accommodating buffer layer is an alkaline earth metal hafnate, the oxide layer can be capped by a thin layer of hafnium. The deposition of hafnium is followed by the deposition of arsenic or phosphorous to react with the hafnium as a precursor to the growth of an indium gallium arsenide, indium aluminum arsenide, or indium phosphide layer, respectively. In a similar manner, strontium titanate can be capped with a layer of strontium or strontium and oxygen and barium titanate can be capped with a layer of barium or barium and oxygen. Each of these depositions can be followed by the deposition of arsenic or phosphorus to react with the capping material to form a template for the deposition of a monocrystalline material layer comprising compound semiconductors such as indium gallium arsenide, indium aluminum arsenide, or indium phosphide.

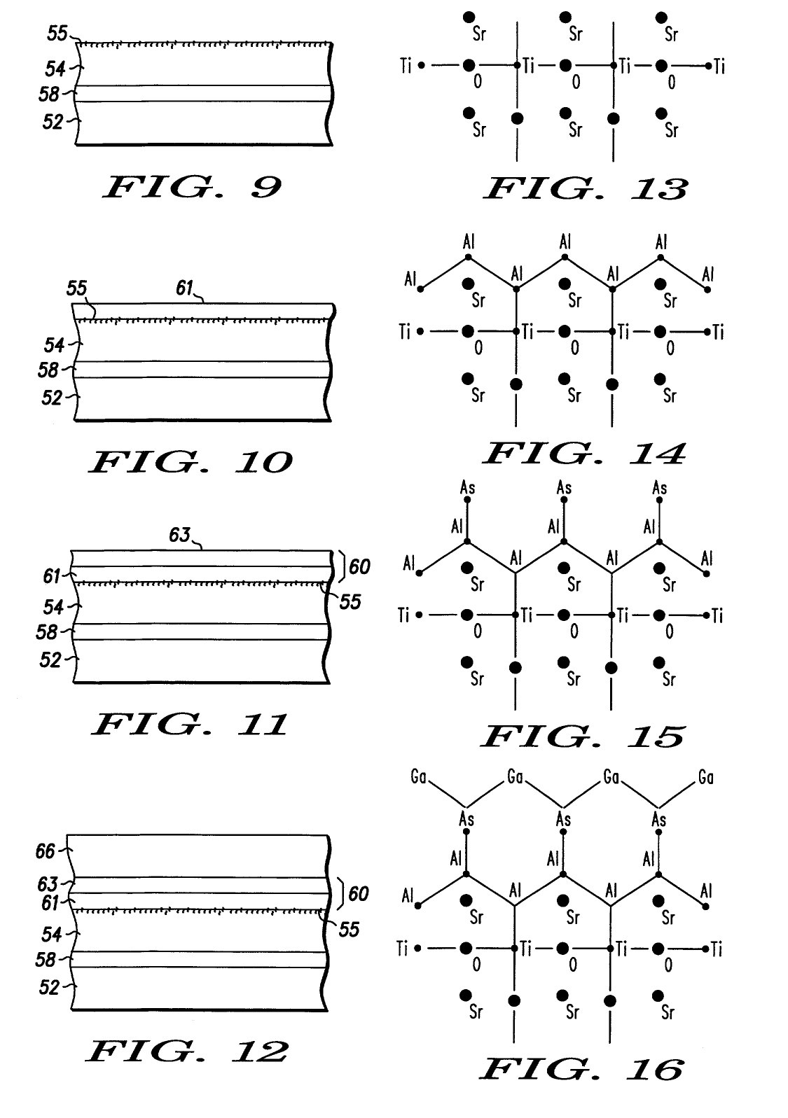

The formation of a device structure in accordance with another embodiment of the invention is illustrated schematically in cross-section in FIGS. 9-12. Like the previously described embodiments referred to in FIGS. 1-3, this embodiment of the invention involves the process of forming a compliant substrate utilizing the epitaxial growth of single crystal oxides, such as the formation of accommodating buffer layer 24 previously described with reference to FIGS. 1 and 2 and amorphous layer 36 previously described with reference to FIG. 3, and the formation of a template layer 30. However, the embodiment illustrated in FIGS. 9-12 utilizes a template that includes a surfactant to facilitate layer-by-layer monocrystalline material growth.

Turning now to FIG. 9, an amorphous intermediate layer 58 is grown on substrate 52 at the interface between substrate 52 and a growing accommodating buffer layer 54, which is preferably a monocrystalline crystal oxide layer, by the oxidation of substrate 52 during the growth of layer 54. Layer 54 is preferably a monocrystalline oxide material such as a monocrystalline layer of Sr_{z}Ba_{1-z}TiO₃ where z ranges from 0 to 1. However, layer 54 may also comprise any of those compounds previously described with reference layer 24 in FIGS. 1-2 and any of those compounds previously described with reference to layer 36 in FIG. 3 which is formed from layers 24 and 28 referenced in FIGS. 1 and 2.

Layer 54 is grown with a strontium (Sr) terminated surface represented in FIG. 9 by hatched line 55 which is followed by the addition of a template layer 60 which includes a surfactant layer 61 and capping layer 63 as illustrated in FIGS. 10 and 11. Surfactant layer 61 may comprise, but is not limited to, elements such as Al, In and Ga, but will be dependent upon the composition of layer 54 and the overlying layer of monocrystalline material for optimal results. In one exemplary embodiment, aluminum (Al) is used for surfactant layer 61 and functions to modify the surface and surface energy of layer 54. Preferably, surfactant layer 61 is epitaxially grown, to a thickness of one to two monolayers, over layer 54 as illustrated in FIG. 10 by way of molecular beam epitaxy (MBE), although other epitaxial processes may also be performed including chemical vapor deposition (CVD), metal organic chemical vapor deposition (MOCVD), migration enhanced epitaxy (MEE), atomic layer epitaxy (ALE), physical vapor deposition (PVD), chemical solution deposition (CSD), pulsed laser deposition (PLD), or the like.

Surfactant layer 61 is then exposed to a Group V element such as arsenic, for example, to form capping layer 63 as illustrated in FIG. 11. Surfactant layer 61 may be exposed to a number of materials to create capping layer 63 such as elements which include, but are not limited to, As, P, Sb and N. Surfactant layer 61 and capping layer 63 combine to form template layer 60.

Monocrystalline material layer 66, which in this example is a compound semiconductor such as GaAs, is then deposited via MBE, CVD, MOCVD, MEE, ALE, PVD, CSD, PLD, and the like to form the final structure illustrated in FIG. 12.

FIGS. 13-16 illustrate possible molecular bond structures for a specific example of a compound semiconductor structure formed in accordance with the embodiment of the invention illustrated in FIGS. 9-12. More specifically, FIGS. 13-16 illustrate the growth of GaAs (layer 66) on the strontium terminated surface of a strontium titanate monocrystalline oxide (layer 54) using a surfactant containing template (layer 60).

The growth of a monocrystalline material layer 66 such as GaAs on an accommodating buffer layer 54 such as a strontium titanium oxide over amorphous interface layer 58 and substrate layer 52, both of which may comprise materials previously described with reference to layers 28 and 22, respectively in FIGS. 1 and 2, illustrates a critical thickness of about 1000 Angstroms where the two-dimensional (2D) and three-dimensional (3D) growth shifts because of the surface energies involved. In order to maintain a true layer by layer growth (Frank Van der Mere growth), the following relationship must be satisfied:

δ_{STO}>(δ_{INT}+δ_{GaAs})

where the surface energy of the monocrystalline oxide layer 54 must be greater than the surface energy of the amorphous interface layer 58 added to the surface energy of the GaAs layer 66. Since it is impracticable to satisfy this equation, a surfactant containing template was used, as described above with reference to FIGS. 10-12, to increase the surface energy of the monocrystalline oxide layer 54 and also to shift the crystalline structure of the template to a diamond-like structure that is in compliance with the original GaAs layer.

FIG. 13 illustrates the molecular bond structure of a strontium terminated surface of a strontium titanate monocrystalline oxide layer. An aluminum surfactant layer is deposited on top of the strontium terminated surface and bonds with that surface as illustrated in FIG. 14, which reacts to form a capping layer comprising a monolayer of Al₂Sr having the molecular bond structure illustrated in FIG. 14 which forms a diamond-like structure with an sp³ hybrid terminated surface that is compliant with compound semiconductors such as GaAs. The structure is then exposed to As to form a layer of AlAs as shown in FIG. 15. GaAs is then deposited to complete the molecular bond structure illustrated in FIG. 16 which has been obtained by 2D growth. The GaAs can be grown to any thickness for forming other semiconductor structures, devices, or integrated circuits. Alkaline earth metals such as those in Group IIA are those elements preferably used to form the capping surface of the monocrystalline oxide layer 54 because they are capable of forming a desired molecular structure with aluminum.

In this embodiment, a surfactant containing template layer aids in the formation of a compliant substrate for the monolithic integration of various material layers including those comprised of Group III-V compounds to form high quality semiconductor structures, devices and integrated circuits. For example, a surfactant containing template may be used for the monolithic integration of a monocrystalline material layer such as a layer comprising Germanium (Ge), for example, to form high efficiency photocells.

Turning now to FIGS. 17-20, the formation of a device structure in accordance with still another embodiment of the invention is illustrated in cross-section. This embodiment utilizes the formation of a compliant substrate which relies on the epitaxial growth of single crystal oxides on silicon followed by the epitaxial growth of single crystal silicon onto the oxide.

An accommodating buffer layer 74 such as a monocrystalline oxide layer is first grown on a substrate layer 72, such as silicon, with an amorphous interface layer 78 as illustrated in FIG. 17. Monocrystalline oxide layer 74 may be comprised of any of those materials previously discussed with reference to layer 24 in FIGS. 1 and 2, while amorphous interface layer 78 is preferably comprised of any of those materials previously described with reference to the layer 28 illustrated in FIGS. 1 and 2. Substrate 72, although preferably silicon, may also comprise any of those materials previously described with reference to substrate 22 in FIGS. 1-3.

Next, a silicon layer 81 is deposited over monocrystalline oxide layer 74 via MBE, CVD, MOCVD, MEE, ALE, PVD, CSD, PLD, and the like as illustrated in FIG. 18 with a thickness of a few hundred Angstroms but preferably with a thickness of about 50 Angstroms. Monocrystalline oxide layer 74 preferably has a thickness of about 20 to 100 Angstroms.

Rapid thermal annealing is then conducted in the presence of a carbon source such as acetylene or methane, for example at a temperature within a range of about 800° C. to 1000° C. to form capping layer 82 and silicate amorphous layer 86. However, other suitable carbon sources may be used as long as the rapid thermal annealing step functions to amorphize the monocrystalline oxide layer74 into a silicate amorphous layer 86 and carbonize the top silicon layer 81 to form capping layer 82 which in this example would be a silicon carbide (SiC) layer as illustrated in FIG. 19. The formation of amorphous layer 86 is similar to the formation of layer 36 illustrated in FIG. 3 and may comprise any of those materials described with reference to layer 36 in FIG. 3 but the preferable material will be dependent upon the capping layer 82 used for silicon layer 81.

Finally, a compound semiconductor layer 96, such as gallium nitride (GaN) is grown over the SiC surface by way of MBE, CVD, MOCVD, MEE, ALE, PVD, CSD, PLD, or the like to form a high quality compound semiconductor material for device formation. More specifically, the deposition of GaN and GaN based systems such as GaInN and AlGaN will result in the formation of dislocation nets confined at the silicon/amorphous region. The resulting nitride containing compound semiconductor material may comprise elements from groups III, IV and V of the periodic table and is defect free.

Although GaN has been grown on SiC substrate in the past, this embodiment of the invention possesses a one step formation of the compliant substrate containing a SiC top surface and an amorphous layer on a Si surface. More specifically, this embodiment of the invention uses an intermediate single crystal oxide layer that is amorphosized to form a silicate layer which adsorbs the strain between the layers. Moreover, unlike past use of a SiC substrate, this embodiment of the invention is not limited by wafer size which is usually less than 50 mm in diameter for prior art SiC substrates.

The monolithic integration of nitride containing semiconductor compounds containing group III-V nitrides and silicon devices can be used for high temperature RF applications and optoelectronics. GaN systems have particular use in the photonic industry for the blue/green and UV light sources and detection. High brightness light emitting diodes (LEDs) and lasers may also be formed within the GaN system.

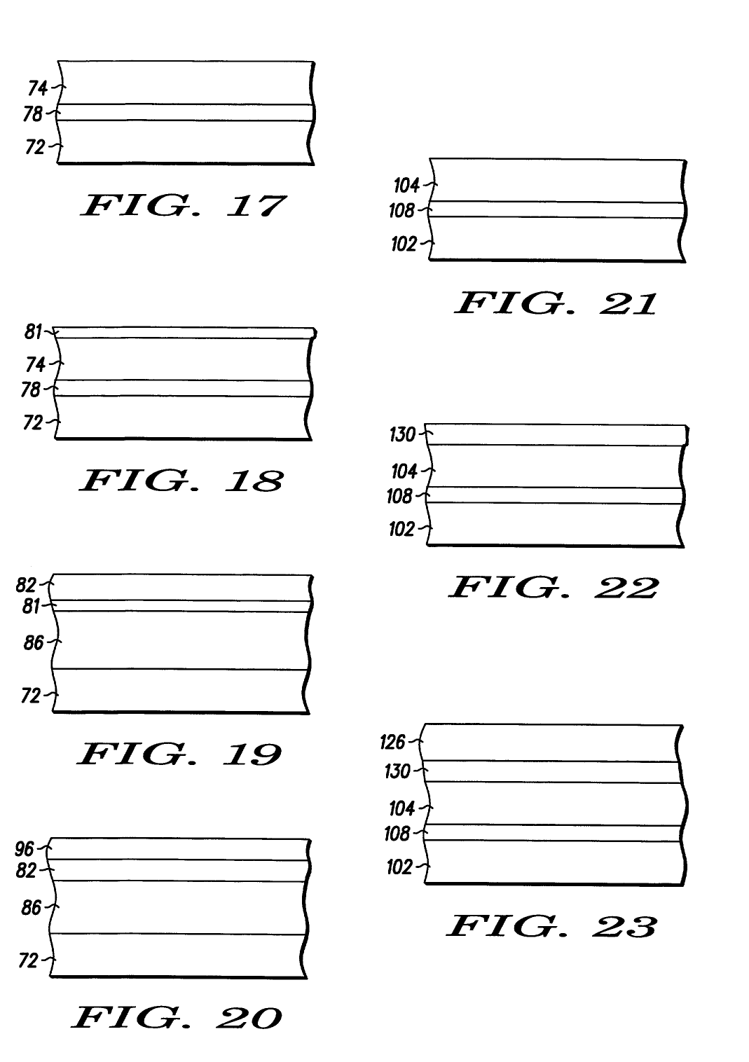

FIGS. 21-23 schematically illustrate, in cross-section, the formation of another embodiment of a device structure in accordance with the invention. This embodiment includes a compliant layer that functions as a transition layer that uses clathrate or Zintl type bonding. More specifically, this embodiment utilizes an intermetallic template layer to reduce the surface energy of the interface between material layers thereby allowing for two-dimensional layer by layer growth.

The structure illustrated in FIG. 21 includes a monocrystalline substrate 102, an amorphous interface layer 108 and an accommodating buffer layer 104. Amorphous interface layer 108 is formed on substrate 102 at the interface between substrate 102 and accommodating buffer layer 104 as previously described with reference to FIGS. 1 and 2. Amorphous interface layer 108 may comprise any of those materials previously described with reference to amorphous interface layer 28 in FIGS. 1 and 2. Substrate 102 is preferably silicon but may also comprise any of those materials previously described with reference to substrate 22 in FIGS. 1-3.

A template layer 130 is deposited over accommodating buffer layer 104 as illustrated in FIG. 22 and preferably comprises a thin layer of Zintl type phase material composed of metals and metalloids having a great deal of ionic character. As in previously described embodiments, template layer 130 is deposited by way of MBE, CVD, MOCVD, MEE, ALE, PVD, CSD, PLD, or the like to achieve a thickness of one monolayer. Template layer 130 functions as a “soft” layer with non-directional bonding but high crystallinity which absorbs stress build up between layers having lattice mismatch. Materials for template 130 may include, but are not limited to, materials containing Si, Ga, In, and Sb such as, for example, AlSr₂, (MgCaYb)Ga₂, (Ca,Sr,Eu,Yb)In₂, BaGe₂As, and SrSn₂As₂

A monocrystalline material layer 126 is epitaxially grown over template layer 130 to achieve the final structure illustrated in FIG. 23. As a specific example, an SrAl₂ layer may be used as template layer 130 and an appropriate monocrystalline material layer 126 such as a compound semiconductor material GaAs is grown over the SrAl₂. The Al-Ti (from the accommodating buffer layer of layer of Sr_{z}Ba_{1-z}TiO₃ where z ranges from 0 to 1) bond is mostly metallic while the Al—As (from the GaAs layer) bond is weakly covalent. The Sr participates in two distinct types of bonding with part of its electric charge going to the oxygen atoms in the lower accommodating buffer layer 104 comprising Sr_{z}Ba_{1-z}TiO₃ to participate in ionic bonding and the other part of its valence charge being donated to Al in a way that is typically carried out with Zintl phase materials. The amount of the charge transfer depends on the relative electronegativity of elements comprising the template layer 130 as well as on the interatomic distance. In this example, Al assumes an sp3 hybridization and can readily form bonds with monocrystalline material layer 126, which in this example, comprises compound semiconductor material GaAs.

The compliant substrate produced by use of the Zintl type template layer used in this embodiment can absorb a large strain without a significant energy cost. In the above example, the bond strength of the Al is adjusted by changing the volume of the SrAl₂ layer thereby making the device tunable for specific applications which include the monolithic integration of III-V and Si devices and the monolithic integration of high-k dielectric materials for CMOS technology.

Clearly, those embodiments specifically describing structures having compound semiconductor portions and Group IV semiconductor portions, are meant to illustrate embodiments of the present invention and not limit the present invention. There are a multiplicity of other combinations and other embodiments of the present invention. For example, the present invention includes structures and methods for fabricating material layers which form semiconductor structures, devices and integrated circuits including other layers such as metal and non-metal layers. More specifically, the invention includes structures and methods for forming a compliant substrate that is used in the fabrication of semiconductor structures, devices and integrated circuits and the material layers suitable for fabricating those structures, devices, and integrated circuits. By using embodiments of the present invention, it is now simpler to integrate devices that include monocrystalline layers comprising semiconductor and compound semiconductor materials as well as other material layers that are used to form those devices with other components that work better or are easily and/or inexpensively formed within semiconductor or compound semiconductor materials. This allows a device to be shrunk, the manufacturing costs to decrease, and yield and reliability to increase.

In accordance with one embodiment of this invention, a monocrystalline semiconductor or compound semiconductor wafer can be used in forming monocrystalline material layers over the wafer. In this manner, the wafer is essentially a “handle” wafer used during the fabrication of semiconductor electrical components within a monocrystalline layer overlying the wafer. Therefore, electrical components can be formed within semiconductor materials over a wafer of at least approximately 200 millimeters in diameter and possibly at least approximately 300 millimeters.

By the use of this type of substrate, a relatively inexpensive “handle” wafer overcomes the fragile nature of compound semiconductor or other monocrystalline material wafers by placing them over a relatively more durable and easy to fabricate base material. Therefore, an integrated circuit can be formed such that all electrical components, and particularly all active electronic devices, can be formed within or using the monocrystalline material layer even though the substrate itself may include a monocrystalline semiconductor material. Fabrication costs for compound semiconductor devices and other devices employing non-silicon monocrystalline materials should decrease because larger substrates can be processed more economically and more readily compared to the relatively smaller and more fragile substrates (e.g. conventional compound semiconductor wafers).

Any of the monolithic devices or semiconductor structures discussed above having a plurality of different semiconductor materials are used to form one or more active or passive devices. Control components integrated with controlled circuits are formed by integration of these devices. The description below for FIGS. 24-37 describes formation of some exemplary devices. Many alternative or additional semiconductor devices now known or later developed may be formed in any one or more of the different materials of the monolithic device.

FIG. 24 illustrates schematically, in cross section, a device structure 50 in accordance with a further embodiment. Device structure 50 includes a monocrystalline semiconductor substrate 52, preferably a monocrystalline silicon wafer. Monocrystalline semiconductor substrate 52 includes two regions, 53 and 57. An electrical semiconductor component generally indicated by the dashed line 56 is formed, at least partially, in region 53. Electrical component 56 can be part of a controlled circuit or a control component, such as a resistor, a capacitor, an active semiconductor component such as a diode or a transistor or an integrated circuit such as a CMOS integrated circuit. For example, electrical semiconductor component 56 can be a CMOS integrated circuit configured to perform digital signal processing or another function for which silicon integrated circuits are well suited. Conventional semiconductor processing as well known and widely practiced in the semiconductor industry can form the electrical semiconductor component in region 53. A layer of insulating material 59 such as a layer of silicon dioxide or the like may overlie electrical semiconductor component 56.

Insulating material 59 and any other layers that may have been formed or deposited during the processing of semiconductor component 56 in region 53 are removed from the surface of region 57 to provide a bare silicon surface in that region. As is well known, bare silicon surfaces are highly reactive and a native silicon oxide layer can quickly form on the bare surface. A layer of barium or barium and oxygen is deposited onto the native oxide layer on the surface of region 57 and is reacted with the oxidized surface to form a first template layer (not shown). In accordance with one embodiment, a monocrystalline oxide layer is formed overlying the template layer by a process of molecular beam epitaxy. Reactants including barium, titanium and oxygen are deposited onto the template layer to form the monocrystalline oxide layer. Initially during the deposition the partial pressure of oxygen is kept near the minimum necessary to fully react with the barium and titanium to form monocrystalline barium titanate layer. The partial pressure of oxygen is then increased to provide an overpressure of oxygen and to allow oxygen to diffuse through the growing monocrystalline oxide layer. The oxygen diffusing through the barium titanate reacts with silicon at the surface of region 57 to form an amorphous layer of silicon oxide 62 on second region 57 and at the interface between silicon substrate 52 and the monocrystalline oxide layer 65. Layers 65 and 62 may be subject to an annealing process as described above in connection with FIG. 3 to form a single amorphous accommodating layer.

In accordance with an embodiment, the step of depositing the monocrystalline oxide layer 65 is terminated by depositing a second template layer 64, which can be 110 monolayers of titanium, barium, barium and oxygen, or titanium and oxygen. A layer 66 of a monocrystalline compound semiconductor material is then deposited overlying second template layer 64 by a process of molecular beam epitaxy. The deposition of layer 66 is initiated by depositing a layer of arsenic onto template 64. Depositing gallium and arsenic to form monocrystalline gallium arsenide 66 follows this initial step. Alternatively, strontium can be substituted for barium in the above example.

In accordance with a further embodiment, a semiconductor component, generally indicated by a dashed line 68 is formed in compound semiconductor layer 66. Semiconductor component 68 can be formed by processing steps conventionally used in the fabrication of gallium arsenide or other III-V compound semiconductor material devices. Semiconductor component 68 can be any active or passive component, and preferably is a semiconductor laser, light emitting diode, photodetector, hetero-junction bipolar transistor (HBT), high frequency MESFET, or other component that utilizes and takes advantage of the physical properties of compound semiconductor materials. A metallic conductor schematically indicated by the line 70 can be formed to electrically couple device 68 and device 56, thus implementing an integrated device that includes at least one component formed in silicon substrate 52 and one device formed in monocrystalline compound semiconductor material layer 66. Although illustrative structure 50 has been described as a structure formed on a silicon substrate 52 and having a barium (or strontium) titanate layer 65 and a gallium arsenide layer 66, similar devices can be fabricated using other substrates, monocrystalline oxide layers and other compound semiconductor layers as described elsewhere in this disclosure.

FIG. 25 illustrates a semiconductor structure 71 in accordance with a further embodiment. Structure 71 includes a monocrystalline semiconductor substrate 73 such as a monocrystalline silicon wafer that includes a region 75 and a region 76. An electrical component schematically illustrated by the dashed line 79 is formed in region 75 using conventional silicon device processing techniques commonly used in the semiconductor industry. Using process steps similar to those described above, a monocrystalline oxide layer 80 and an intermediate amorphous silicon oxide layer 83 are formed overlying region 76 of substrate 73. A template layer 84 and subsequently a monocrystalline semiconductor layer 87 are formed overlying monocrystalline oxide layer 80. In accordance with a further embodiment, an additional monocrystalline oxide layer 88 is formed overlying layer 87 by process steps similar to those used to form layer 80, and an additional monocrystalline semiconductor layer 90 is formed overlying monocrystalline oxide layer 88 by process steps similar to those used to form layer 86. In accordance with one embodiment, at least one of layers 87 and 90 are formed from a compound semiconductor material. Layers 80 and 83 may be subject to an annealing process as described above in connection with FIG. 3 to form a single amorphous accommodating layer.

A semiconductor component generally indicated by a dashed line 92 is formed at least partially in monocrystalline semiconductor layer 87. In accordance with one embodiment, semiconductor component 92 may include a field effect transistor having a gate dielectric formed, in part, by monocrystalline oxide layer 88. In addition, monocrystalline semiconductor layer 90 can be used to implement the gate electrode of that field effect transistor. In accordance with one embodiment, monocrystalline semiconductor layer 87 is formed from a group III-V compound and semiconductor component 92 is a radio frequency amplifier that takes advantage of the high mobility characteristic of group III-v component materials. In accordance with yet a further embodiment, an electrical interconnection schematically illustrated by the line 94 electrically interconnects component 79 and component 92. Structure 71 thus integrates components that take advantage of the unique properties of the two monocrystalline semiconductor materials.

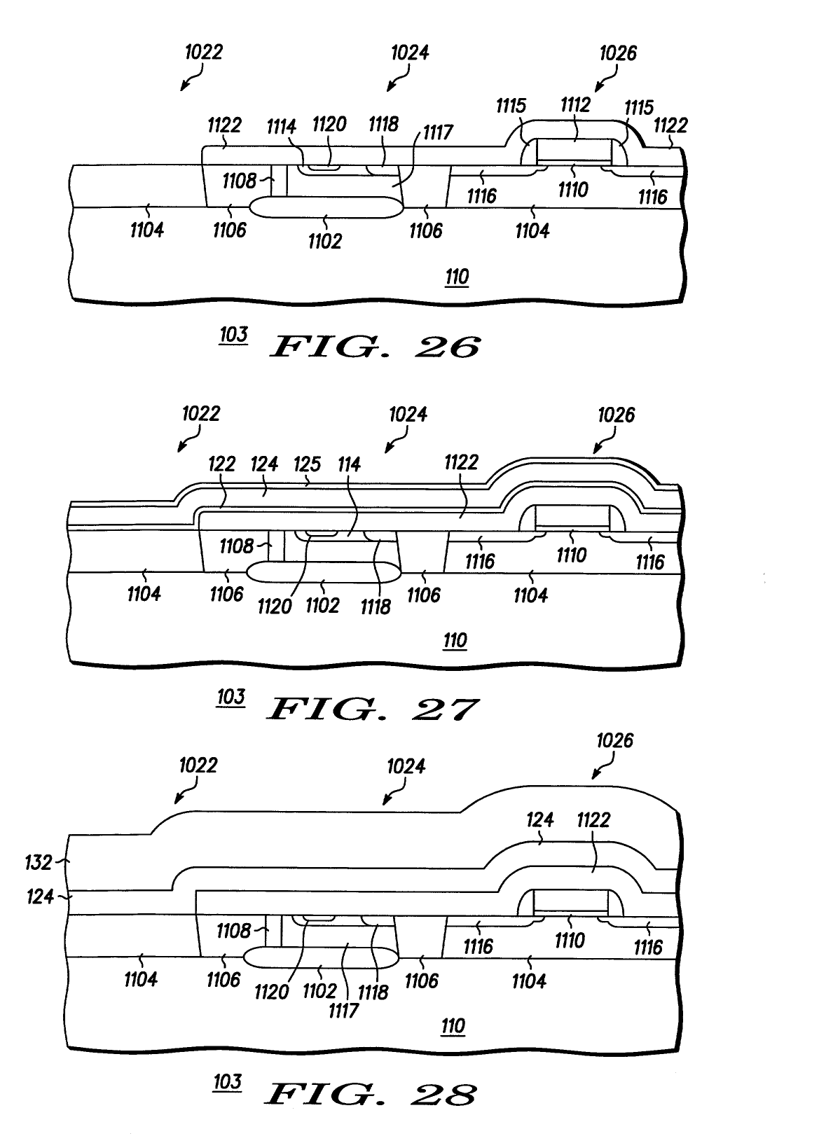

Attention is now directed to a method for forming exemplary portions of illustrative composite semiconductor structures or composite integrated circuits like 50 or 71. In particular, the illustrative composite semiconductor structure or integrated circuit 103 shown in FIGS. 26-30 includes a compound semiconductor portion 1022, a bipolar portion 1024, and a MOS portion 1026. In FIG. 26, a p-type doped, monocrystalline silicon substrate 110 is provided having a compound semiconductor portion 1022, a bipolar portion 1024, and an MOS portion 1026. Within bipolar portion 1024, the monocrystalline silicon substrate 110 is doped to form an N+buried region 1102. A lightly p-type doped epitaxial monocrystalline silicon layer 1104 is then formed over the buried region 1102 and the substrate 110. A doping step is then performed to create a lightly n-type doped drift region 1117 above the N+buried region 1102. The doping step converts the dopant type of the lightly p-type epitaxial layer within a section of the bipolar region 1024 to a lightly n-type monocrystalline silicon region. A field isolation region 1106 is then formed between and around the bipolar portion 1024 and the MOS portion 1026. A gate dielectric layer 1110 is formed over a portion of the epitaxial layer 1104 within MOS portion 1026, and the gate electrode 1112 is then formed over the gate dielectric layer 1110. Sidewall spacers 1115 are formed along vertical sides of the gate electrode 1112 and gate dielectric layer 1110.

A p-type dopant is introduced into the drift region 1117 to form an active or intrinsic base region 1114. An n-type, deep collector region 1108 is then formed within the bipolar portion 1024 to allow electrical connection to the buried region 1102. Selective n-type doping is performed to form N+ doped regions 1116 and the emitter region 1120. N+ doped regions 1116 are formed within layer 1104 along adjacent sides of the gate electrode 1112 and are source, drain, or source/drain regions for the MOS transistor. The N+ doped regions 1116 and emitter region 1120 have a doping concentration of at least 1E19 atoms per cubic centimeter to allow ohmic contacts to be formed. A p-type doped region is formed to create the inactive or extrinsic base region 1118 which is a P⁺ doped region (doping concentration of at least 1E19 atoms per cubic centimeter).

In the embodiment described, several processing steps have been performed but are not illustrated or further described, such as the formation of well regions, threshold adjusting implants, channel punchthrough prevention implants, field punchthrough prevention implants, as well as a variety of masking layers. The formation of the device up to this point in the process is performed using conventional steps. As illustrated, a standard N-channel MOS transistor has been formed within the MOS region 1026, and a vertical NPN bipolar transistor has been formed within the bipolar portion 1024. Although illustrated with a NPN bipolar transistor and a N-channel MOS transistor, device structures and circuits in accordance with various embodiments may additionally or alternatively include other electronic devices formed using the silicon substrate. As of this point, no circuitry has been formed within the compound semiconductor portion 1022.

After the silicon devices are formed in regions 1024 and 1026, a protective layer 1122 is formed overlying devices in regions 1024 and 1026 to protect devices in regions 1024 and 1026 from potential damage resulting from device formation in region 1022. Layer 1122 may be formed of, for example, an insulating material such as silicon oxide or silicon nitride.

All of the layers that have been formed during the processing of the bipolar and MOS portions of the integrated circuit, except for epitaxial layer 1104 but including protective layer 1122, are now removed from the surface of compound semiconductor portion 1022. A bare silicon surface is thus provided for the subsequent processing of this portion, for example in the manner set forth above.

An accommodating buffer layer 124 is then formed over the substrate 110 as illustrated in FIG. 27. The accommodating buffer layer will form as a monocrystalline layer over the properly prepared (i.e., having the appropriate template layer) bare silicon surface in portion 1022. The portion of layer 124 that forms over portions 1024 and 1026, however, may be polycrystalline or amorphous because it is formed over a material that is not monocrystalline, and therefore, does not nucleate monocrystalline growth. The accommodating buffer layer 124 typically is a monocrystalline metal oxide (e.g. monocrystalline perovskite oxide) or nitride layer and typically has a thickness in a range of approximately 2-100 nanometers. In one particular embodiment, the accommodating buffer layer is approximately 5-15 nm thick. During the formation of the accommodating buffer layer, an amorphous intermediate layer 122 is formed along the uppermost silicon surfaces of the integrated circuit 103. This amorphous intermediate layer 122 typically includes an oxide of silicon and has a thickness and range of approximately 1-5 nm. In one particular embodiment, the thickness is approximately 2 nm. Following the formation of the accommodating buffer layer 124 and the amorphous intermediate layer 122, a template layer 125 is then formed and has a thickness in a range of approximately one to ten monolayers of a material. In one particular embodiment, the material includes titanium-arsenic, strontium-oxygen-arsenic, or other similar materials as previously described with respect to FIGS. 1-5.

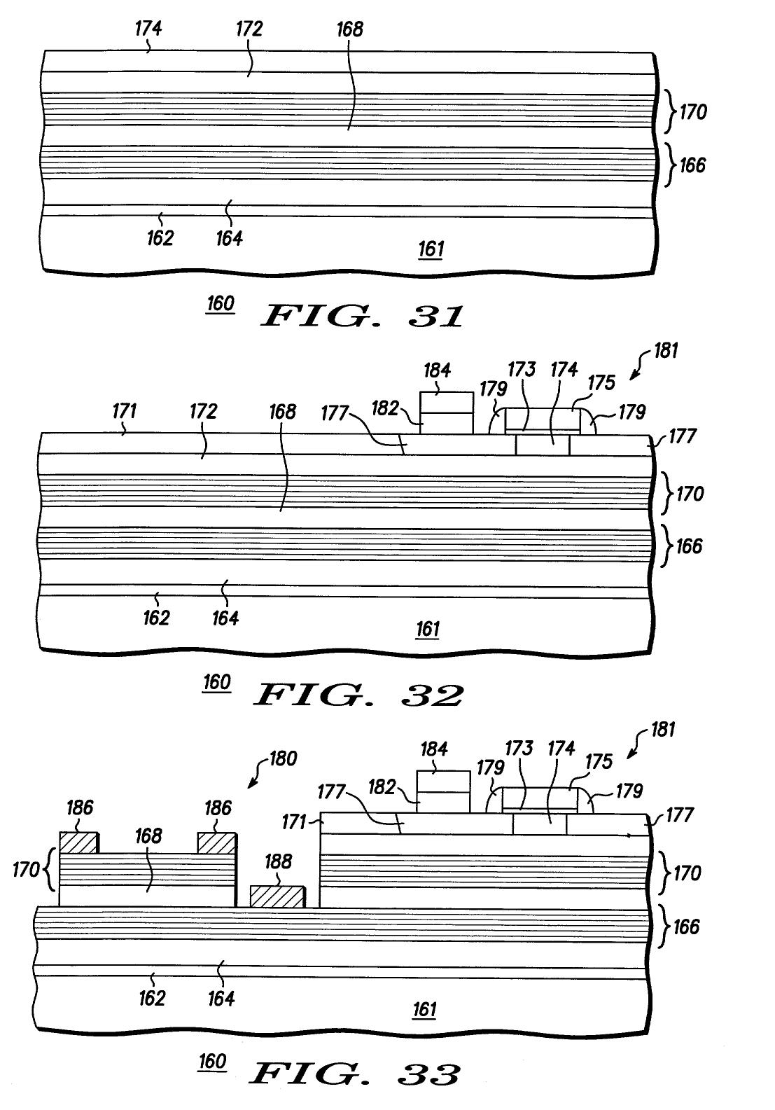

A monocrystalline compound semiconductor layer 132 is then epitaxially grown overlying the monocrystalline portion of accommodating buffer layer 124 as shown in FIG. 28. The portion of layer 132 that is grown over portions of layer 124 that are not monocrystalline may be polycrystalline or amorphous. The monocrystalline compound semiconductor layer can be formed by a number of methods and typically includes a material such as gallium arsenide, aluminum gallium arsenide, indium phosphide, or other compound semiconductor materials as previously mentioned. The thickness of the layer is in a range of approximately 1-5,000 nm, and more preferably 100-2000 nm. Furthermore, additional monocrystalline layers may be formed above layer-132, as discussed in more detail below in connection with FIGS. 31-32.

In this particular embodiment, each of the elements within the template layer are also present in the accommodating buffer layer 124, the monocrystalline compound semiconductor material 132, or both. Therefore, the delineation between the template layer 125 and its two immediately adjacent layers disappears during processing. Therefore, when a transmission electron microscopy (TEM) photograph is taken, an interface between the accommodating buffer layer 124 and the monocrystalline compound semiconductor layer 132 is seen.

After at least a portion of layer 132 is formed in region 1022, layers 122 and 124 may be subject to an annealing process as described above in connection with FIG. 3 to form a single amorphous accommodating layer. If only a portion of layer 132 is formed prior to the anneal process, the remaining portion may be deposited onto structure 103 prior to further processing.

At this point in time, sections of the compound semiconductor layer 132 and the accommodating buffer layer 124 (or of the amorphous accommodating layer if the annealing process described above has been carried out) are removed from portions overlying the bipolar portion 1024 and the MOS portion 1026 as shown in FIG. 29. After the section of the compound semiconductor layer and the accommodating buffer layer 124 are removed, an insulating layer 142 is formed over protective layer 1122. The insulating layer 142 can include a number of materials such as oxides, nitrides, oxynitrides, low-k dielectrics, or the like. As used herein, low-k is a material having a dielectric constant no higher than approximately 3.5. After the insulating layer 142 has been deposited, it is then polished or etched, removing portions of the insulating layer 142 that overlie monocrystalline compound semiconductor layer 132.

A transistor 144 is then formed within the monocrystalline compound semiconductor portion 1022. A gate electrode 148 is then formed on the monocrystalline compound semiconductor layer 132. Doped regions 146 are then formed within the monocrystalline compound semiconductor layer 132. In this embodiment, the transistor 144 is a metal-semiconductor field-effect transistor (MESFET). If the MESFET is an n-type MESFET, the doped regions 146 and at least a portion of monocrystalline compound semiconductor layer 132 are also n-type doped. If a p-type MESFET were to be formed, then the doped regions 146 and at least a portion of monocrystalline compound semiconductor layer 132 would have just the opposite doping type. The heavier doped (N+) regions 146 allow ohmic contacts to be made to the monocrystalline compound semiconductor layer 132. At this point in time, the active devices within the integrated circuit have been formed. Although not illustrated in the drawing figures, additional processing steps such as formation of well regions, threshold adjusting implants, channel punchthrough prevention implants, field punchthrough prevention implants, and the like may be performed in accordance with the present invention. This particular embodiment includes an n-type MESFET, a vertical NPN bipolar transistor, and a planar n-channel MOS transistor. Many other types of transistors, including P-channel MOS transistors, p-type vertical bipolar transistors, p-type MESFETs, and combinations of vertical and planar transistors, can be used. Also, other electrical components, such as resistors, capacitors, diodes, and the like, may be formed in one or more of the portions 1022, 1024, and 1026.

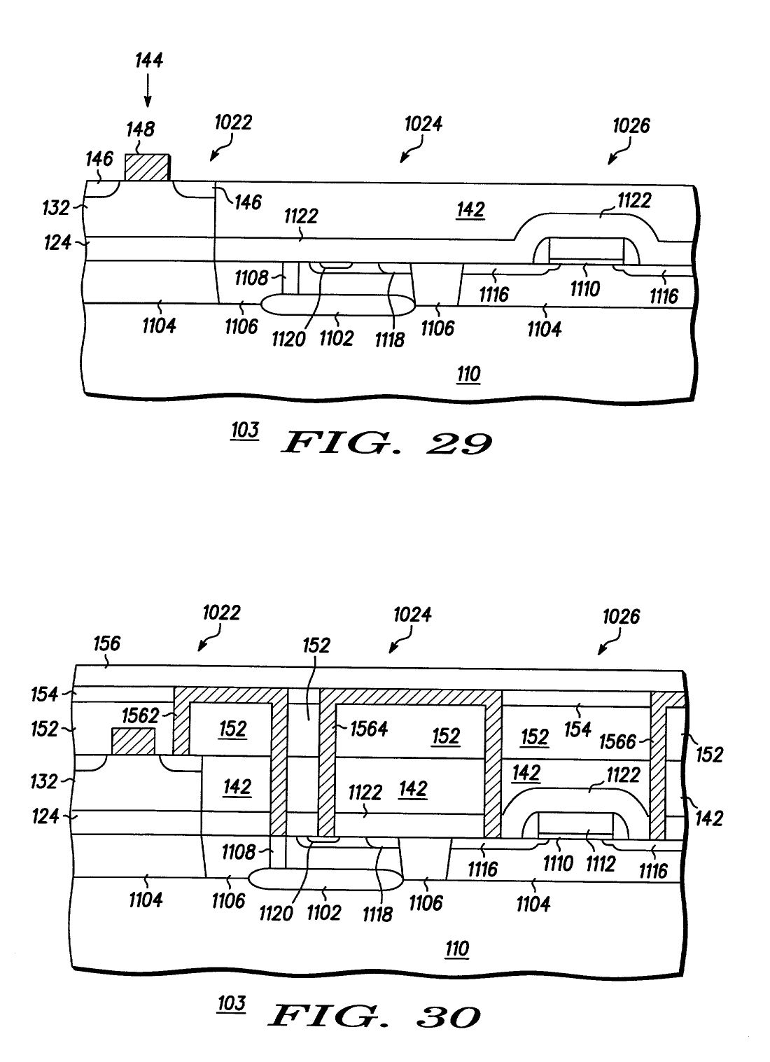

Processing continues to form a substantially completed integrated circuit 103 as illustrated in FIG. 30. An insulating layer 152 is formed over the substrate 110. The insulating layer 152 may include an etch-stop or polish-stop region that is not illustrated in FIG. 30. A second insulating layer 154 is then formed over the first insulating layer 152. Portions of layers 154, 152, 142, 124, and 122 are removed to define contact openings where the devices are to be interconnected. Interconnect trenches are formed within insulating layer 154 to provide the lateral connections between the contacts. As illustrated in FIG. 30, interconnect 1562 connects a source or drain region of the n-type MESFET within portion 1022 to the deep collector region 1108 of the NPN transistor within the bipolar portion 1024. The emitter region 1120 of the NPN transistor is connected to one of the doped regions 1116 of the n-channel MOS transistor within the MOS portion 1026. The other doped region 1116 is electrically connected to other portions of the integrated circuit that are not shown. Similar electrical connections are also formed to couple regions 1118 and 1112 to other regions of the integrated circuit.

A passivation layer 156 is formed over the interconnects 1562, 1564, and 1566 and insulating layer 154. Other electrical connections are made to the transistors as illustrated as well as to other electrical or electronic components within the integrated circuit 103 but are not illustrated in the FIGS. Further, additional insulating layers and interconnects may be formed as necessary to form the proper interconnections between the various components within the integrated circuit 103.

As can be seen from the previous embodiment, active devices for both compound semiconductor and Group IV semiconductor materials can be integrated into a single integrated circuit. Because there is some difficulty in incorporating both bipolar transistors and MOS transistors within a same integrated circuit, it may be possible to move some of the components within bipolar portion 1024 into the compound semiconductor portion 1022 or the MOS portion 1026. Therefore, the requirement of special fabricating steps solely used for making a bipolar transistor can be eliminated. Therefore, there would only be a compound semiconductor portion and a MOS portion to the integrated circuit.

In still another embodiment, an integrated circuit can be formed such that it includes an optical laser in a compound semiconductor portion and an optical interconnect (waveguide) to a MOS transistor within a Group IV semiconductor region of the same integrated circuit. FIGS. 31-37 include illustrations of one embodiment.

FIG. 31 includes an illustration of a cross-section view of a portion of an integrated circuit 160 that includes a monocrystalline silicon wafer 161. An amorphous intermediate layer 162 and an accommodating buffer layer 164, similar to those previously described, have been formed over wafer 161. Layers 162 and 164 may be subject to an annealing process as described above in connection with FIG. 3 to form a single amorphous accommodating layer. In this specific embodiment, the layers needed to form the optical laser will be formed first, followed by the layers needed for the MOS transistor. In FIG. 31, the lower mirror layer 166 includes alternating layers of compound semiconductor materials. For example, the first, third, and fifth films within the optical laser may include a material such as gallium arsenide, and the second, fourth, and sixth films within the lower mirror layer 166 may include aluminum gallium arsenide or vice versa. Layer 168 includes the active region that will be used for photon generation. Upper mirror layer 170 is formed in a similar manner to the lower mirror layer 166 and includes alternating films of compound semiconductor materials. In one particular embodiment, the upper mirror layer 170 may be p-type doped compound semiconductor materials, and the lower mirror layer 166 may be n-type doped compound semiconductor material.

Another accommodating buffer layer 172, similar to the accommodating buffer layer 164, is formed over the upper mirror layer 170. In an alternative embodiment, the accommodating buffer layers 164 and 172 may include different materials. However, their function is essentially the same in that each is used for making a transition between a compound semiconductor layer and a monocrystalline Group IV semiconductor layer. Layer 172 may be subject to an annealing process as described above in connection with FIG. 3 to form an amorphous accommodating layer. A monocrystalline Group IV semiconductor layer 174 is formed over the accommodating buffer layer 172. In one particular embodiment, the monocrystalline Group IV semiconductor layer 174 includes germanium, silicon germanium, silicon germanium carbide, or the like.

In FIG. 32, the MOS portion is processed to form electrical components within this upper monocrystalline Group IV semiconductor layer 174. As illustrated in FIG. 32, a field isolation region 171 is formed from a portion of layer 174. A gate dielectric layer 173 is formed over the layer 174, and a gate electrode 175 is formed over the gate dielectric layer 173. Doped regions 177 are source, drain, or source/drain regions for the transistor 181, as shown. Sidewall spacers 179 are formed adjacent to the vertical sides of the gate electrode 175. Other components can be made within at least a part of layer 174. These other components include other transistors (n-channel or p-channel), capacitors, transistors, diodes, and the like.

A monocrystalline Group IV semiconductor layer is epitaxially grown over one of the doped regions 177. An upper portion 184 is P+ doped, and a lower portion 182 remains substantially intrinsic (undoped) as illustrated in FIG. 32. The layer can be formed using a selective epitaxial process. In one embodiment, an insulating layer (not shown) is formed over the transistor 181 and the field isolation region 171. The insulating layer is patterned to define an opening that exposes one of the doped regions 177. At least initially, the selective epitaxial layer is formed without dopants. The entire selective epitaxial layer may be intrinsic, or a p-type dopant can be added near the end of the formation of the selective epitaxial layer. If the selective epitaxial layer is intrinsic, as formed, a doping step may be formed by implantation or by furnace doping. Regardless how the P+ upper portion 184 is formed, the insulating layer is then removed to form the resulting structure shown in FIG. 32.

The next set of steps is performed to define the optical laser 180 as illustrated in FIG. 33. The field isolation region 171 and the accommodating buffer layer 172 are removed over the compound semiconductor portion of the integrated circuit. Additional steps are performed to define the upper mirror layer 170 and active layer 168 of the optical laser 180. The sides of the upper mirror layer 170 and active layer 168 are substantially coterminous.

Contacts 186 and 188 are formed for making electrical contact to the upper mirror layer 170 and the lower mirror layer 166, respectively, as shown in FIG. 33. Contact 186 has an annular shape to allow light (photons) to pass out of the upper mirror layer 170 into a subsequently formed optical waveguide.

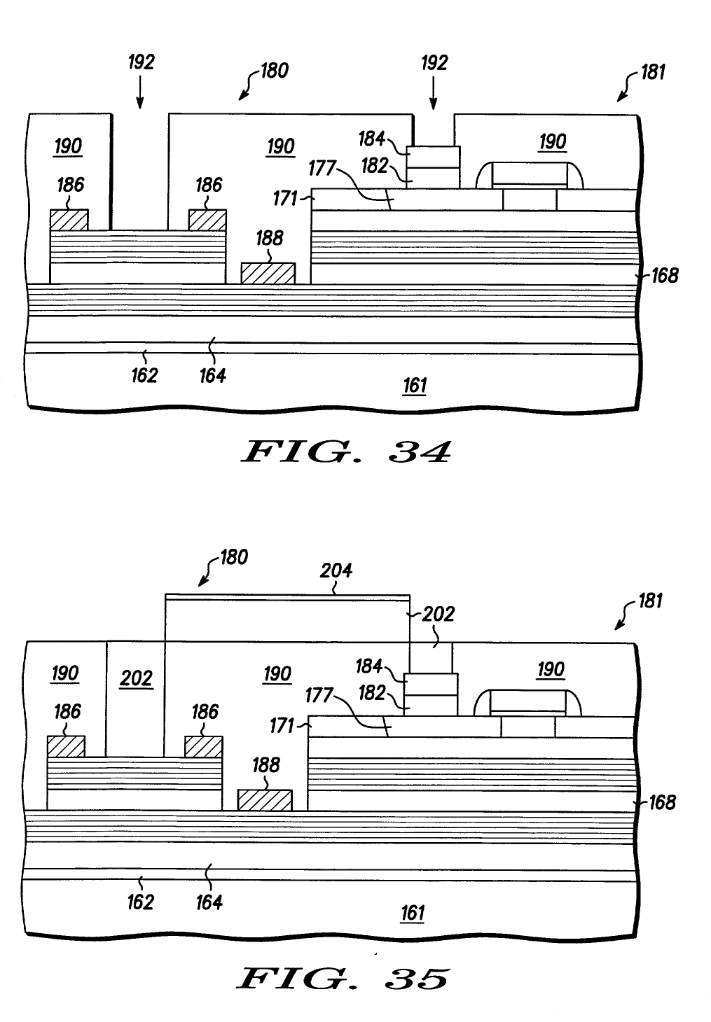

An insulating layer 190 is then formed and patterned to define optical openings extending to the contact layer 186 and one of the doped regions 177 as shown in FIG. 34. The insulating material can be any number of different materials, including an oxide, nitride, oxynitride, low-k dielectric, or any combination thereof. After defining the openings 192, a higher refractive index material 202 is then formed within the openings to fill them and to deposit the layer over the insulating layer 190 as illustrated in FIG. 35. With respect to the higher refractive index material 202, “higher” is in relation to the material of the insulating layer 190 (i.e., material 202 has a higher refractive index compared to the insulating layer 190). Optionally, a relatively thin lower refractive index film (not shown) could be formed before forming the higher refractive index material 202. A hard mask layer 204 is then formed over the high refractive index layer 202. Portions of the hard mask layer 204, and high refractive index layer 202 are removed from portions overlying the opening and to areas closer to the sides of FIG. 35.

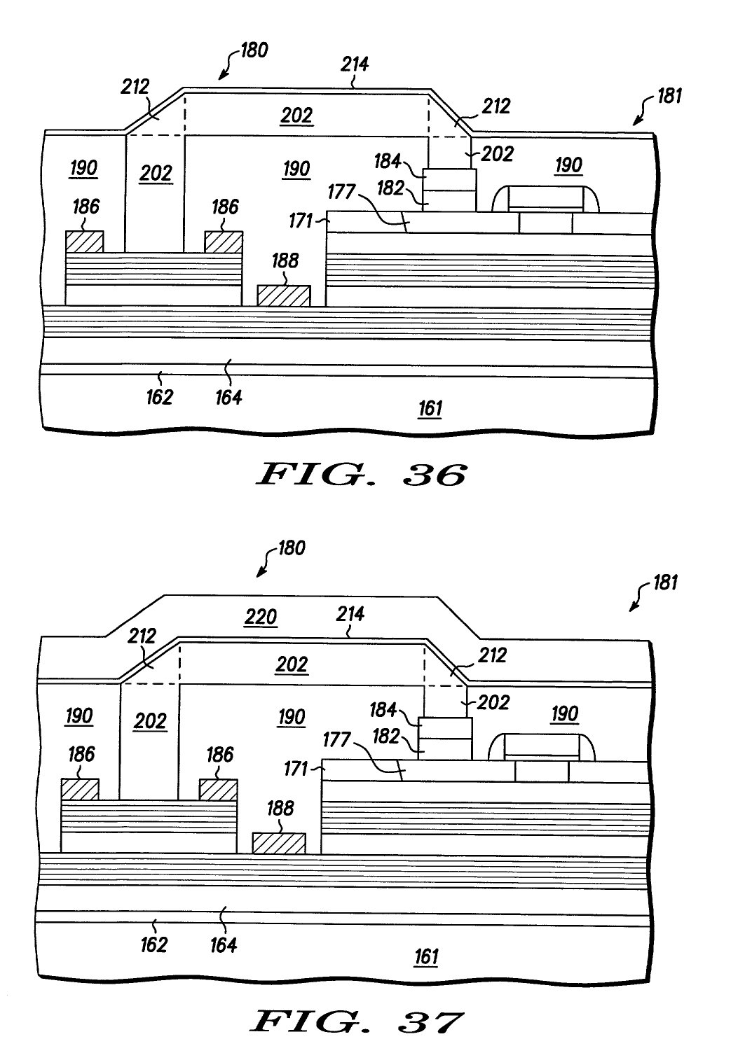

The balance of the formation of the optical waveguide, which is an optical interconnect, is completed as illustrated in FIG. 36. A deposition procedure (possibly a dep-etch process) is performed to effectively create sidewalls sections 212. In this embodiment, the sidewall sections 212 are made of the same material as material 202. The hard mask layer 204 is then removed, and a low refractive index layer 214 (low relative to material 202 and layer 212) is formed over the higher refractive index material 212 and 202 and exposed portions of the insulating layer 190. The dash lines in FIG. 36 illustrate the border between the high refractive index materials 202 and 212. This designation is used to identify that both are made of the same material but are formed at different times.

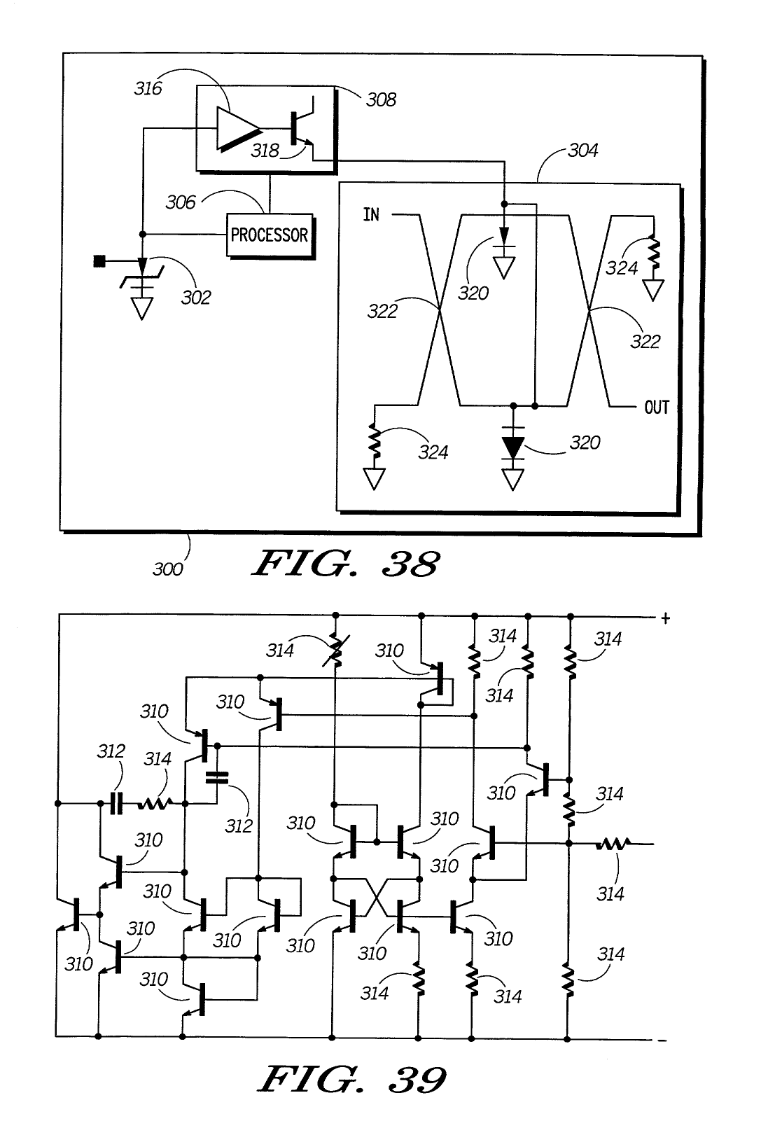

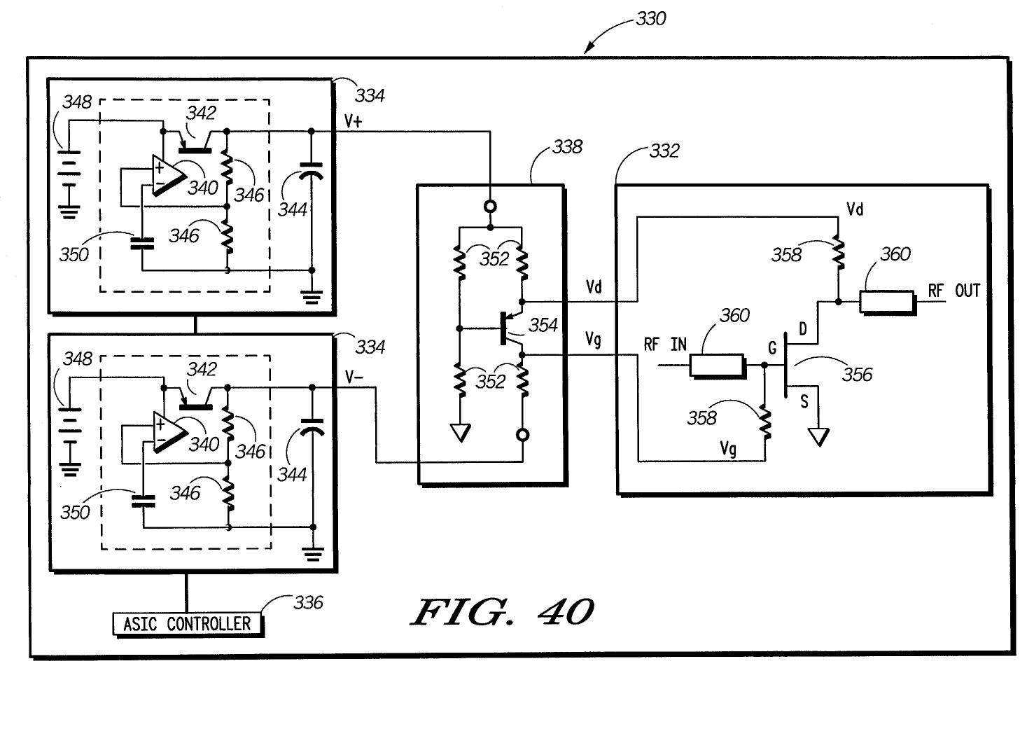

Processing is continued to form a substantially completed integrated circuit as illustrated in FIG. 37. A passivation layer 220 is then formed over the optical laser 180 and MOSFET transistor 181. Although not shown, other electrical or optical connections are made to the components within the integrated circuit but are not illustrated in FIG. 37. These interconnects can include other optical waveguides or may include metallic interconnects.

In other embodiments, other types of lasers can be formed. For example, another type of laser can emit light (photons) horizontally instead of vertically. If light is emitted horizontally, the MOSFET transistor could be formed within the substrate 161, and the optical waveguide would be reconfigured, so that the laser is properly coupled (optically connected) to the transistor. In one specific embodiment, the optical waveguide can include at least a portion of the accommodating buffer layer. Other configurations are possible.

Clearly, these embodiments of integrated circuits having compound semiconductor portions and Group IV semiconductor portions, are meant to illustrate what can be done and are not intended to be exhaustive of all possibilities or to limit what can be done. Monocrystalline semiconductor material layer configurations having three or more different layers of semiconductor material discussed above or other configurations may be used for forming active or passive devices. There is a multiplicity of other possible devices, combinations and embodiments.

Active and passive devices integrated as control and controlled devices in the monolithic device or semiconductor structure discussed above include many devices. For example, any type of transistor now known or later developed can be integrated. The types of transistors are a function of the material in which each transistor is formed. Bi-polar junction transistors (BJT), laterally diffused metal-oxide semiconductors (LDMOS), complementary metal-oxide semiconductors (CMOS), hetero-junction bi-polar transistors (BBT), BiCMOS transistors or other transistors can be formed in silicon or Group IV materials. Field effect transistors (FET), MESFET, high electron mobility transistor (HEMT), pseudomorphic high electron mobility transistor (PHEMT), HBT or other transistors can be formed in gallium arsenide or other compound semiconductor materials. For example, HBT, HEMT, FET or other transistors can be formed in indium phosphide. The material is selected as a function of the desired device characteristics, such as bandwidth or other performance characteristic. Using a plurality of materials provides for a broader range of operation of an integrated circuit.

Other active components or devices can be formed in the monolithic device. For example, the compound semiconductor portion may include light emitting diodes, photodetectors, other diodes, or the like. In one embodiment, a diode comprises a FET or other transistor with the source and drain connected to provide an PN junction formed in the semiconductor structure. As another example, a Zener diode or other diode is formed in a Group IV material or other semiconductor material. Other diodes now know or later developed can be formed.

Passive devices or components can also be formed in the monolithic device. Passive components include resistors, capacitors, inductors, transmission lines, line couplers or other devices. For resistors, nichrome, tantalum nitride or other lossy material forms the resistor. Alternatively, an epitaxial layer or other doped material formed on a semiconductor material, such as gallium arsenide, forms the resistor. For capacitors, a MEMS or other structure having two conductive plates (e.g. deposited metal layer or doped semiconductor material) separated by a gap or dielectric material is formed. For inductors, an air-bridge, planar spiral deposit or etch of metal, or a spiral of conductive material formed in one or multiple layers of material is formed. The values of inductors, resistors and capacitors can be a function of the material in which the amplifier component is formed. For transmission lines, conductive material is deposited on one or more surfaces or layers of material.

Line couplers are another passive device used for integrating control devices. Line couplers are formed of two or more adjacent but separated conductors. For example, a plurality of interspersed conductors is formed (e.g. interleaved conductors deposited, patterned or generated by selective doping). Close spacing, such as 5 microns or closer of small geometry or tight tolerance topography, integration provides electromagnetic communication between the conductors. Lange, branch-line, ring hybrid or other couplers can be used. The signals from the separate conductors interact due to electromagnetic forces. In alternative embodiments, a power splitter, such as a Wilkinson power splitter, is used.

The passive devices are formed in any of the materials discussed herein, including compound semiconductor materials, Group IV semiconductor materials, amorphous layers, intermediate layers and other materials.

Additional control or controlled devices are formed as circuits from the passive or active devices discussed herein. A switch comprises any of the transistors discussed above. In alternative embodiments, the switch comprises a micro-electromechanical system (MEMS) device (e.g. a mechanical member formed in a semiconductor material that is moveable in response to electric signals) or other device for selecting two or more connections. The switch is formed in one or more of the materials discussed herein, such as Group IV or compound semiconductor materials, an amorphous material or an intermediate material. In one embodiment, the switch comprises a CMOS transistor formed in monocrystalline silicon.

Processors are formed as controlling or controlled circuits. Processors, including digital signal processors, general processors or application specific integrated circuits, comprise one or more transistors and/or memory devices now known or later developed. For example, the Group IV semiconductor material includes digital logic (e.g. transistors) and memory arrays (e.g. RAM or ROM), or other semiconductor devices for processing data. The control transistors include any of the transistors discussed herein.

Part or the entire processor or ASIC is integrated on the monolithic device. In one embodiment, the processor or ASIC is formed as a array of transistors at least partly or entirely in the Group IV semiconductor portion of the integrated circuit. Other parts of the processor or ASIC can be formed in other layers, such as the compound Group III-V semiconductor layer, the intermediate layer (e.g. amorphous oxide material), the accommodating buffer layer (e.g. monocrystalline perovskite oxide material), and/or external to the monolithic integrated circuit.

Memory devices can be formed on the monolithic device. In one embodiment, the memory device comprises one or more transistors connected with a capacitor for storing a charge. Other memory devices now known or later developed can be formed on the monolithic device. For example, random access memory (RAM), read only memory (ROM), programmable ROM (PROM), erasable PROM (EPROM), static PROM (SPROM), EEPROM or other memory devices are formed. The memory devices are formed in one or more of the Group IV material, compound semiconductor material, amorphous material, intermediate layer material or other material discussed herein.

A look-up table or network of memory devices can be formed on the monolithic device. Transistors for controlling storage of data are formed with the memory devices. Multiple bits of data are stored and retrieved from the memory devices for use by other devices or circuits. The memory devices and transistors are formed in the materials of the monolithic device as discussed above.

Amplifiers can be formed on the monolithic device from passive and active devices. In one embodiment, the amplifier comprises a radio and/or microwave frequency (RF/MW) monolithic integrated circuit, such as a monolithic microwave integrated circuit (MMIC). The amplifier can be a Doherty, distributed, low noise, high power, trans-impedance, other power combining, operational, differential or other non-power combining amplifier. For example, one or more FETs are formed in indium phosphide for a low noise amplifier. In this embodiment, a shorter gate length and/or shaped gate provide lower resistance for lower noise. The gate can be shaped as a large T or mushroom shape of metal deposited on a material layer or surface of the integrated circuit. The amplifier includes components, such as transistors, inductors, capacitors, resistors, switches, combiners, splitters and/or other semiconductor devices. Other amplifier structures and components now known or later developed formed in any of the materials discussed herein can be used, such as CMOS transistors, LDMOS transistors or other transistors formed in a Group IV material, or FET, MESFET, BEMT, PHEMT, HBT or other transistors formed in compound semiconductor materials.

Matching circuitry is formed in the monolithic device. Matching circuitry comprises a network of one or more transmission lines, inductors, resistors and/or capacitors. For use with an amplifier, the matching circuit connects with ground, in a feed back loop, to the amplifier input, to the amplifier output or combinations thereof. Combinations of these configurations can also be formed in the semiconductor structure. Matching circuitry is formed on semiconductor material, another material discussed herein or combinations thereof.

Other networks of transmission lines, inductors, resistors and/or capacitors can be formed in the monolithic device. In one embodiment, harmonic termination circuitry is formed. Harmonic termination circuitry corresponds to a capacitance or inductance associated with a frequency or frequency band for attenuating signals. The harmonic termination circuitry acts to short circuit or ground signals at selected frequencies with minimum capacitance or inductance effects on signals at other frequencies, such as fundamental frequency band. The harmonic termination circuitry is formed in semiconductor material, another material discussed herein or combinations thereof.

In another embodiment, a load impedance circuit is formed. A load impedance circuit includes one or more inductors or capacitors. The load impedance circuit connects with a load to maximize power provided to the load or maximize the efficiency of the amplifier. The load impedance circuit acts to adjust a load impedance with respect to unity. The load impedance circuit is formed in semiconductor material, another material discussed herein or combinations thereof.

In yet another embodiment, a blocking capacitor or bypass circuit is formed. The blocking capacitor comprises one or more capacitor devices connected to ground or between other devices to prevent transmission of direct current. The blocking capacitor is formed in semiconductor material, another material discussed herein or combinations thereof. Bypass circuits are formed of a blocking capacitor or an inductor.

In another embodiment, filters can be formed on the monolithic device. Filters comprise one or more transmission lines, resistors, capacitors, inductors and combinations thereof. Active components, such as transistors or diodes, can also be used. Filters are arranged as high pass, low pass or band pass filters using designs now know or later developed. Filters are formed in semiconductor material, another material discussed herein or combinations thereof.

Voltage controlled oscillators can be formed on the monolithic device. Voltage controlled oscillators comprise a network of transistors and resistors with a feedback connection or loop. Different frequencies are generated in response to an input voltage. Voltage controlled oscillators now known or later developed can be used. The voltage controlled oscillator or components of the voltage controlled oscillator are formed in any of the materials of the monolithic device. For example, active components, such as any of the transistors discussed above, are formed in one or more semiconductor (e.g. Group IV or compound) materials.

Mixers can be formed on the monolithic device. Mixers comprise one or more diodes arranged with multiple inputs for non-linear frequency conversion. Any nonlinear (e.g. diodes, transistors, or semiconductor optical amplifier) or combination of non-linear devices (e.g. dual-gate FET mixer, or a ring or star configuration of diodes) with associated matching circuitry can be used. The diodes or other components of the mixers are formed in part or entirely in the monolithic device, such as in Group IV or compound semiconductor materials. The frequency response of the mixer is a function of the material used to form the parts of the mixer. Compound semiconductor materials provide operation at high frequencies. For example, gallium arsenide components operate at higher frequencies than components formed on silicon or other Group IV materials. As another example, indium phosphide components operate at higher frequencies than gallium arsenide components. The material or materials used for the mixer correspond to the desired operating frequencies.

Analog-to-digital converters (ADC) can be formed on the monolithic device. The ADC comprises a network of voltage dividing resistors with one or more comparators (e.g. operational amplifier) and logic devices (e.g. transistors). For digital-to-analog converters, a network of voltage dividing resistors and switches (e.g. transistors, MEMS or other switches) can be used. Other active and/or passive components can be use for ADC and DAC as know or later developed.

Phase shifters can be formed on the monolithic device. Phase shifters comprise a line coupler, a switch for connecting different lengths of transmission line, a coplanar transmission line, a ferroelectric or ferromagnetic material responsive to an applied control voltage and deposited on the monolithic device, or other devices for shifting the phase of signals in the desired frequency range. In one embodiment, a transistor or MEMS switch selects between different lengths of transmission lines deposited in the monolithic device. For example, a switch network for selecting phase shifts in 22.5-degree increments (4 bit switching) is formed in the compound or Group IV semiconductor materials. Other increments of phased shift or materials for forming the switches or transmission lines can be used. For low loss phase shifting with a component formed in a Group IV semiconductor material, a ground plane shielding the phase shifter is formed or deposited.

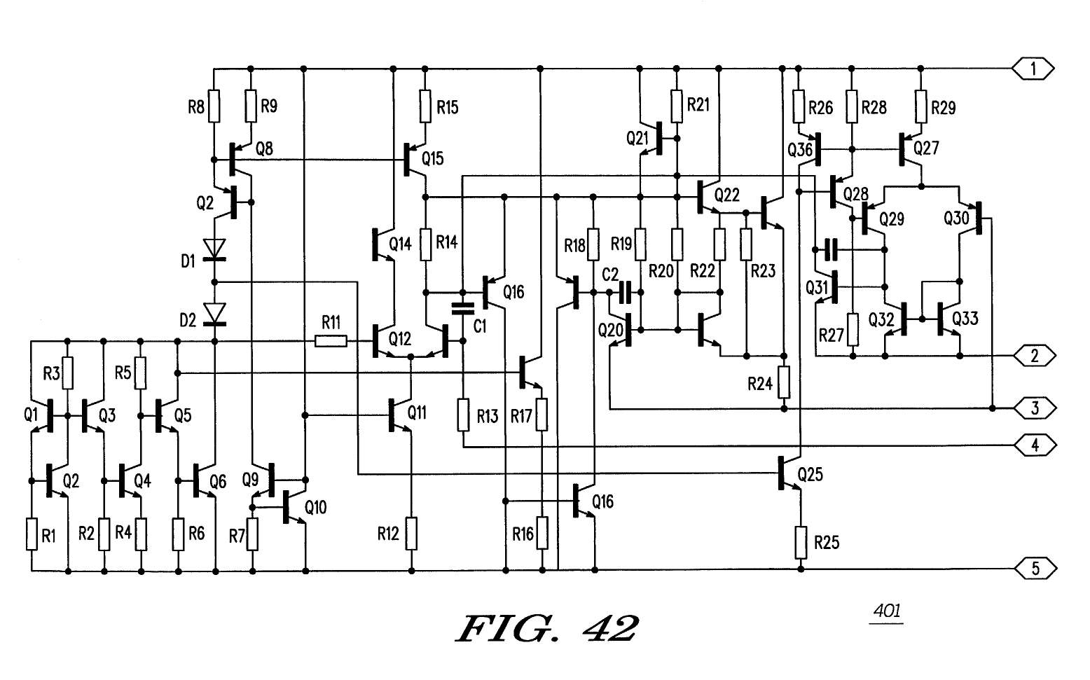

Voltage regulators can be formed on the monolithic device. Voltage regulators comprise transistors, amplifiers, resistors, capacitors, inductors, transmission lines and/or combinations thereof. Various configurations now known or later developed may be used, such as a differential amplifier, a transistor and resistors as shown and later described in FIG. 39 or more complex networks of multiple transistors, capacitors and resistors arranged as a current source, reference source, error amplifier, thermal protection, comparator or other devices, such as illustrated in FIG. 42. In response to a reference or control voltage, an unregulated voltage is converted to an output regulated voltage. Programmable voltage regulators with or without a DAC for converting digital control signals to an analog reference voltage can be used. The passive and active components of the voltage regulator are formed in semiconductor material, amorphous material, intermediate layer material or combinations thereof.

Other control or controlled devices or components can be formed on the monolithic device. Any device or circuit can be formed in one or a plurality of the materials of the monolithic device. For example, one transistor or diode of a component is formed in a Group IV material and another transistor or diode of the component is formed in a compound semiconductor material. As another example, an active device is formed in a semiconductor material (e.g. compound or Group IV) and a passive device is formed in a different semiconductor material, the same semiconductor material, an amorphous layer material, an intermediate layer material or other material.

Using any of the devices or circuits discussed above, controlling devices are integrated with controlled devices on the semiconductor structure of the monolithic device. Devices or circuits formed on compound semiconductor materials are integrated with control devices on Group IV material in the same monolithic device or vise versa. Fewer discrete components are used due to integration on multiple materials of one device. Smaller, cheaper and less lossy circuits are formed by integration on the monolithic device.

By using what is shown and described herein, it is now simpler to integrate devices that work better in compound semiconductor materials with other components that work better in Group IV semiconductor materials. This allows a device to be shrunk, the manufacturing costs to decrease, and yield and reliability to increase.

Although not illustrated, a monocrystalline Group IV wafer can be used in forming only compound semiconductor electrical components over the wafer. In this manner, the wafer is essentially a “handle” wafer used during the fabrication of the compound semiconductor electrical components within a monocrystalline compound semiconductor layer overlying the wafer. Therefore, electrical components can be formed within III-V or II-VI semiconductor materials over a wafer of at least approximately 200 millimeters in diameter and possibly at least approximately 300 millimeters.

By the use of this type of substrate, a relatively inexpensive “handle” wafer overcomes the fragile nature of the compound semiconductor wafers by placing them over a relatively more durable and easy to fabricate base material. Therefore, an integrated circuit can be formed such that all electrical components, and particularly all active electronic devices, can be formed within the compound semiconductor material even though the substrate itself may include a Group IV semiconductor material. Fabrication costs for compound semiconductor devices should decrease because larger substrates can be processed more economically and more readily, compared to the relatively smaller and more fragile, conventional compound semiconductor wafers.

A composite integrated circuit may include components that provide electrical isolation when electrical signals are applied to the composite integrated circuit. The composite integrated circuit may include a pair of optical components, such as an optical source component and an optical detector component. An optical source component may be a light generating semiconductor device, such as an optical laser (e.g., the optical laser illustrated in FIG. 33), a photo emitter, a diode, etc. An optical detector component may be a light-sensitive semiconductor junction device, such as a photodetector, a photodiode, a bipolar junction, a transistor, etc.

A composite integrated circuit may include processing circuitry that is formed at least partly in the Group IV semiconductor portion of the composite integrated circuit. The processing circuitry is configured to communicate with circuitry external to the composite integrated circuit. The processing circuitry may be electronic circuitry, such as a microprocessor, RAM, logic device, decoder, etc.

For the processing circuitry to communicate with external electronic circuitry, the composite integrated circuit may be provided with electrical signal connections with the external electronic circuitry. The composite integrated circuit may have internal optical communications connections for connecting the processing circuitry in the composite integrated circuit to the electrical connections with the external circuitry. Optical components in the composite integrated circuit may provide the optical communications connections that may electrically isolate the electrical signals in the communications connections from the processing circuitry. Together, the electrical and optical communications connections may be for communicating information, such as data, control, timing, etc.

A pair of optical components (an optical source component and an optical detector component) in the composite integrated circuit may be configured to pass information. Information that is received or transmitted between the optical pair may be from or for the electrical communications connection between the external circuitry and the composite integrated circuit. The optical components and the electrical communications connection may form a communications connection between the processing circuitry and the external circuitry while providing electrical isolation for the processing circuitry. If desired, a plurality of optical component pairs may be included in the composite integrated circuit for providing a plurality of communications connections and for providing isolation. For example, a composite integrated circuit receiving a plurality of data bits may include a pair of optical components for communication of each data bit.

In operation, for example, an optical source component in a pair of components may be configured to generate light (e.g., photons) based on receiving electrical signals from an electrical signal connection with the external circuitry. An optical detector component in the pair of components may be optically connected to the source component to generate electrical signals based on detecting light generated by the optical source component. Information that is communicated between the source and detector components may be digital or analog.

If desired the reverse of this configuration may be used. An optical source component that is responsive to the on-board processing circuitry may be coupled to an optical detector component to have the optical source component generate an electrical signal for use in communications with external circuitry. A plurality of such optical component pair structures may be used for providing two-way connections. In some applications where synchronization is desired, a first pair of optical components may be coupled to provide data communications and a second pair may be coupled for communicating synchronization information.

For clarity and brevity, optical detector components that are discussed herein are discussed primarily in the context of optical detector components that have been formed in a compound semiconductor portion of a composite integrated circuit. In application, the optical detector component may be formed in many suitable ways (e.g., formed from silicon, etc.).

A composite integrated circuit will typically have an electric connection for a power supply and a ground connection. The power and ground connections are in addition to the communications connections that are discussed above. Processing circuitry in a composite integrated circuit may include electrically isolated communications connections and include electrical connections for power and ground. In most known applications, power supply and ground connections are usually well protected by circuitry to prevent harmful external signals from reaching the composite integrated circuit. A communications ground may be isolated from the ground signal in communications connections that use a ground communications signal.

Combinations of the exemplary devices described above, other active devices or other passive devices form controlled devices integrated with controlling devices in one monolithic device. By using different semiconductor materials in one monolithic device, an integrated circuit with broader possible application is formed. For example, processor or application specific integrated circuit components formed in silicon or other Group IV material controls amplifier, mixer, phase shifter, transistor or other components formed in gallium arsenide. The Group IV material comprises a substrate or epitaxial layer. Combining multiple devices in multiple materials in an integrated circuit provides improved cost of manufacture, less noise and more versatility. Integration provides for smaller devices.

Controlling devices include circuits that control or alter the operation of controlled components. For example, a feedback loop or processor controls the bias of an amplifier circuit. As another example, the operation of a radio frequency circuit is controlled by a temperature sensing circuit. As yet other examples, an automatic gain control is integrated with an amplifier. A same device can both be controlled by another device and also control yet another device. Other examples are discussed below.

Controlling and controlled devices or components include (1) single or multiple circuits, (2) single or multiple active or passive devices, (3) groupings of circuits, (4) groupings of active or passive devices and (5) combinations thereof. For example, controlled devices can include a transistor, a switch, a passive device, an attenuator circuit, a mixer or other devices. As another example, controlling devices can include a temperature sensor, a voltage regulator, a switch, a processor, a memory device or other devices. Various combinations of one or more controlling devices can be used with various combinations of one or more controlled devices.

Controlled and controlling devices can be integrated on the monolithic device. For example, temperature, bias, automatic gain, redundant circuit, switchable matching or termination, amplifier selection, modulation, feedback or look-up table control of an integrated circuit is integrated on the semiconductor structure of the monolithic device. FIGS. 38-53 illustrate various integrated control functions with controlled devices. Other integrated control and controlled devices and functions can be provided.

The devices are formed in any of the materials discussed above. Different parts of one device or circuit can be formed in different materials. For brevity, particular examples of the material used for each device are given below for FIGS. 38-53, but other materials can be used, such as materials discussed above for the various integrated devices. For example, an amplifier or transistor formed in a compound semiconductor structure can be formed in a Group IV semiconductor material or vice versa.

FIG. 38 illustrates integrating a temperature sensor 302 with a variable gain element 304 on a semiconductor structure or monolithic device 300. A processor 306 and driver circuit 308 are also integrated to control the variable gain element. Additional, different or fewer components can be integrated on the semiconductor structure 300. For example, in alternative embodiments, the processor 306 is formed on a separate device or device different than the monolithic device 300. The driver circuit 306 and/or the processor 306 are responsive to an output of the temperature sensor 302. The processor 306 controls operation of the driver circuit 308. The driver circuit 308 controls operation of the variable gain element 304.

The temperature sensor 302 comprises a Zener diode circuit. The Zener diode circuit includes active devices, such as bi-polar transistors, arranged to function as a Zener diode. FIG. 39 illustrates an exemplary Zener diode circuit having integrated transistors 310, capacitors 312 and resistors 314. Other Zener diode circuits can be used. In another embodiment, a microelectromechanical system (MEMS) temperature sensor is formed. MEMS temperature sensors comprise bimetallic or other structures that warp or coil as a function of temperature. The location of a contact changes or a difference in capacitance is measured to determine the temperature. Other MEMS temperature sensors can be used. In yet another alternative embodiment, a thermistor having a resistance that changes as a function of temperature is used. In other alternative embodiments, other transistor or active elements can be used. The temperature sensor 302 of FIG. 38 outputs different voltage or current as a function of the temperature of the temperature sensor 302. The response of the temperature sensor 302 to changes in temperature is linear or non-linear.

The driver circuit 308 includes an operational amplifier 316 and a transistor 318. The operational amplifier 316 includes a differential amplifier that draws little current arranged with a feedback from the output to the input. Other driver circuits 308, such as analog and/or digital transistor or amplifier circuits, can be integrated. The driver circuit 308 converts, such as converting the signal to a linear or non-linear signal or converting a voltage to a current, the output of the temperature sensor 302 to a signal appropriate for the variable gain element 304.

The driver circuit 308 operates in response to the processor 306. The processor 306 comprises a general processor, a digital signal processor or an ASIC. In alternative embodiments, the processor 306 comprises a look-up table, latch, shift register, multiplexer, buffer, memory device or a bi-polar and/or CMOS device. The processor 306 is responsive to the temperature sensor 302 in one embodiment. In alternative embodiments, the processor 306 is responsive to other inputs, such as user selections, with or without input from the temperature sensor 302. The processor 306 controls the conversion provided by the driver circuit 308, such as selecting a different temperature to voltage or current curve for control of the variable gain element 304. In one embodiment, the processor 306 controls a bias of the driver circuit 308, such as changing a gate or emitter voltage of the transistor 318 or the operational amplifier 316. In other embodiments, the processor 306 selects analog or other circuitry used by the driver circuit 308.

The variable gain element 304 comprises diodes 320, line couplers 322 and resistors 324 arranged as illustrated in FIG. 38. The driver circuit 308 controls a bias applied to the diodes 320. Other arrangements with different, fewer or additional devices can be used. In one alternative embodiment, the variable gain element 304 comprises a variable gain amplifier or a transistor. The driver circuit 308 controls a bias of the amplifier or transistor. Alternatively or additionally, a variable resistor on a voltage divider or other variable attenuating device is used. Signals input to the variable gain element 304 are attenuated or amplified as a function of temperature sensed by the variable gain element 304 on the same monolithic device 300.

In one embodiment, part or the entire variable gain element 304 is integrated in a compound semiconductor material. For example, the diodes 320 are formed in gallium arsenide and the line couplers 322 and resistors 324 are formed in any of the materials of the semiconductor structure 300. The processor 306, driver circuit 308 and temperature sensor 302 are integrated in a Group IV material. Various transistors, diodes or other active devices of the above listed components 306, 308, and 302 can be formed in compound semiconductor material.

Integrating the temperature sensor 302 on the semiconductor structure 300 with other circuitry provides more efficient and accurate temperature control. The temperature sensor 302 compensates for temperature changes associated with the operation of other circuits integrated on the same device 300. For example, the temperature sensor 302 is used with an amplifier in a radio, microwave or other frequency circuit. Devices formed in compound semiconductor materials provide higher frequency operation, and temperature sensing and control are provided in other semiconductor material on the same device. As an alternative to variable gain, the temperature control sensor 302 controls an oscillator. The control devices are integrated in appropriate materials. The monolithic device 300 provides for integration of both control and controlling components.

FIG. 40 illustrates one embodiment of bias control integrated with controlling and controlled devices on a monolithic device or semiconductor structure 330. The bias of a transistor in one or more integrated devices is controlled by another device integrated on the monolithic device 330. For example, voltage regulators 334 responsive to an ASIC controller 336 control the bias of an amplifier 332. Constant current circuit 338 conditions the voltage signal provided by the voltage regulators 334 to the amplifier 332. Any of the constant current circuit 338, ASIC controller 336 and voltage regulators 334 comprise controlling devices. Different, additional or fewer devices can be integrated, such as integrating the monolithic device 330 without the ASIC controller 336.

The ASIC controller 336 comprises an ASIC. Alternatively or additionally, a general processor, a digital signal processor, a look-up table, latch, shift register, multiplexer, buffer, memory device or a bi-polar and/or CMOS device is used. The ASIC controller 336 controls the voltage output by the voltage regulators 334.

The voltage regulators 334 comprise an error amplifier 340, a transistor 342, capacitors 344, resistors 346, unregulated voltage sources 348, and reference voltage sources 350 arranged as illustrated in FIG. 40. Other voltage regulators 334 including additional, fewer or different components can be used. The reference voltage source 350 is provided by, set by or responsive to signals from the ASIC controller 336. For example, the ASIC controller 336 provides a DC voltage. As another example, a square wave or oscillating signal is provided, and the voltage regulators 334 operate in response to the duty cycle or RMF of the signal. In response to the ASIC controller 336, the voltage regulators output positive and negative regulated or adjustable voltages to the constant current circuit 338.

The constant current circuit 338 comprises a plurality of resistors 352 connected with a transistor 354. The transistor 354 comprises a BJT, but other transistors can be used. Other constant current circuits 338 can be used. The constant current circuit 338 provides stable current and voltage output over a broad temperature range and minimizes variation due to manufacturing, reducing time used for aligning amplifiers and voltage regulators. The voltages output by the constant current circuit 338 connect as bias sources to the amplifier 332. The amplifier 332 comprises a FET or HEMT transistor 356 connected with two resistors 358 and matching circuitry 360. In alternative embodiments, a semiconductor laser (e.g. vertical cavity surface emitting laser or a side emitting laser), an LED, a semiconductor optical amplifier or other optical device is provided instead of or in addition to the amplifier 332. The bias sources connect through the resistors 358 to each of the gate and drain of the transistor 356. In alternative embodiments, a IHBT transistor is provided with the bias sources connected to the base and collector. Different amplifiers with one or more transistors can be used. The amplifier 332 amplifies input signals as a function of the bias voltages controlled by the constant current circuit 338, the voltage regulators 334 and the ASIC controller 336.

The ASIC controller 336, voltage regulators 334 and constant current circuit 338 provide voltage regulation and constant current control to the amplifier 332. The ASIC controller 336 and voltage regulators 334 also provide bias sequencing or timing for operation of the amplifier 332. Where the amplifier 332 comprises a depletion mode N type device, the gate and drain bias sources are turned on and off in sequence. For example, a negative voltage is applied to the gate, and then a positive voltage is applied to the drain for turning on the amplifier 332. For turning off the amplifier 332, the drain bias voltage is turned off before the gate bias voltage. Other sequencing can be used.

In one embodiment, the amplifier 332 or part thereof is integrated on compound semiconductor material of the semiconductor structure 330. Amplifiers implemented with Group III-V combinations use regulated and filtered DC voltages for radio or microwave frequency operation. To avoid line loss, reduce manufacturing costs, provide better response time, provide less noisy feedback signals, and provide smaller circuits, the voltage regulation, constant current control and/or sequencing control are integrated on the same semiconductor structure 330. The voltage regulators 334, constant current circuit 338, ASIC controller 336 and/or parts thereof are integrated in the Group IV or other materials of the semiconductor structure 330. Amplification with bias control is integrated on one semiconductor structure 330.

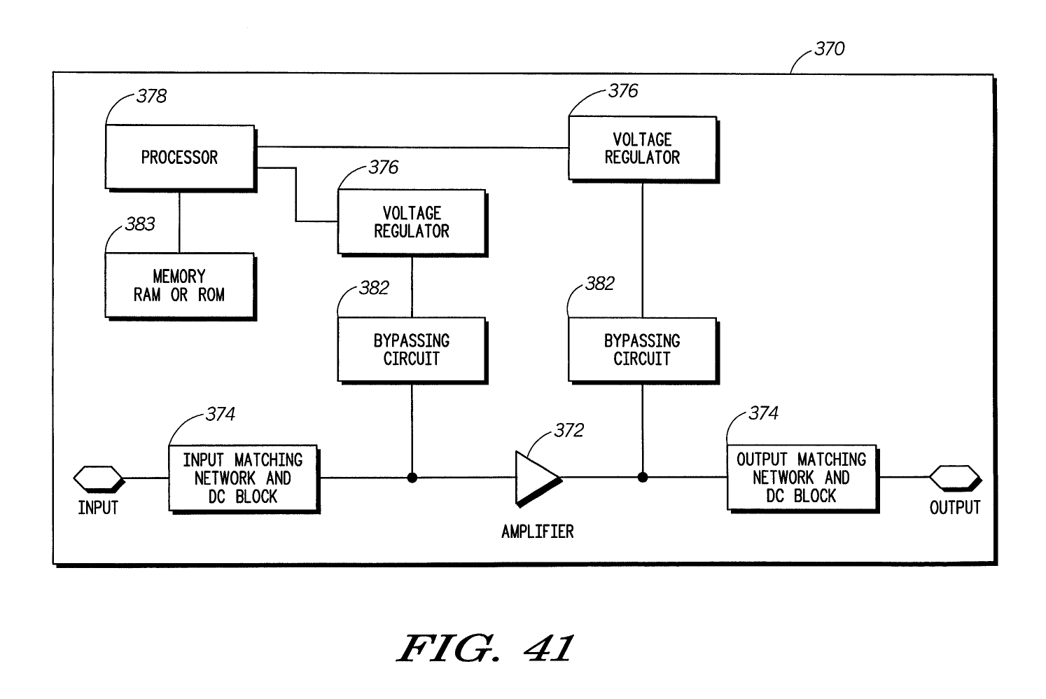

Other bias control can be provided. FIG. 41 illustrates (1) modulating the bias and (2) controlling a class of operation of an amplifier 372 formed in a monolithic device 370. The monolithic device 370 includes the amplifier 372 operative to amplify an input signal and matching/DC block circuitry 374. The bias of the amplifier 372 is controlled by voltage regulators 376 connected to the amplifier 372 with bypass circuits 382. A processor 378 and a memory 380 control the voltage regulators 376. Different, fewer or additional devices can be integrated. For example, the memory 380 and/or the processor 378 are formed on different devices.

The amplifier 372, matching/DC block circuitry 374, processor 378, memory 380, and bypassing circuits 382 include any of the devices discussed above, including alternatives. In one embodiment, the amplifier 372 includes a FET with a drain connected with one voltage regulator 376 and a gate connected with another voltage regulator 376. As discussed above for FIG. 40, the processor 378 controls the voltage regulators 376. The processor 378 with the memory 378 selects appropriate operation or parameters for operation of the voltage regulators 376.

The voltage regulators 376 comprise the voltage regulators discussed above and illustrated in FIG. 40 or alternatives discussed above. FIG. 42 illustrates a voltage regulator 401 of an alternative embodiment. The voltage regulator 401 includes a plurality of transistors Q1-33, capacitors C1-3, resistors R1-29, Zener diodes Z1-3 and diodes D1-2.

To modulate the bias, the bias voltage provided to the drain of a transistor of the amplifier 372 is varied. Varying the drain bias voltage varies the gain of the amplifier 372. To control the class of operation of the amplifier 372, the bias voltage provided to the gate of a transistor of the amplifier 372 is varied. The amplifier 372 operates as a class A, B or AB amplifier as a function of the bias voltage at the gate. In alternative embodiments, the voltage regulator 376 for only one of controlling the class of amplifier 372 or for modulating the bias is provided.

In one embodiment, the amplifier 372 or portions of the amplifier 372 (e.g. transistor) are integrated on the compound semiconductor material of the semiconductor structure 370. The matching circuits/DC block 374 and bypassing circuits 382 are integrated in any of the materials, such as the Group IV material or the compound semiconductor material, of the monolithic device 370. The voltage regulators 376, processor 378 and memory 380 are integrated on the Group IV material, such as silicon. The multiple semiconductor material monolithic device 370 allows bias control formed in silicon or other Group IV material to be integrated with circuitry, such as the amplifier 372, formed in compound semiconductor material. The integration of different devices on different materials of the same structure or monolithic device 370 provides for smaller, less lossy and cheaper integrated circuits with different performance characteristics.

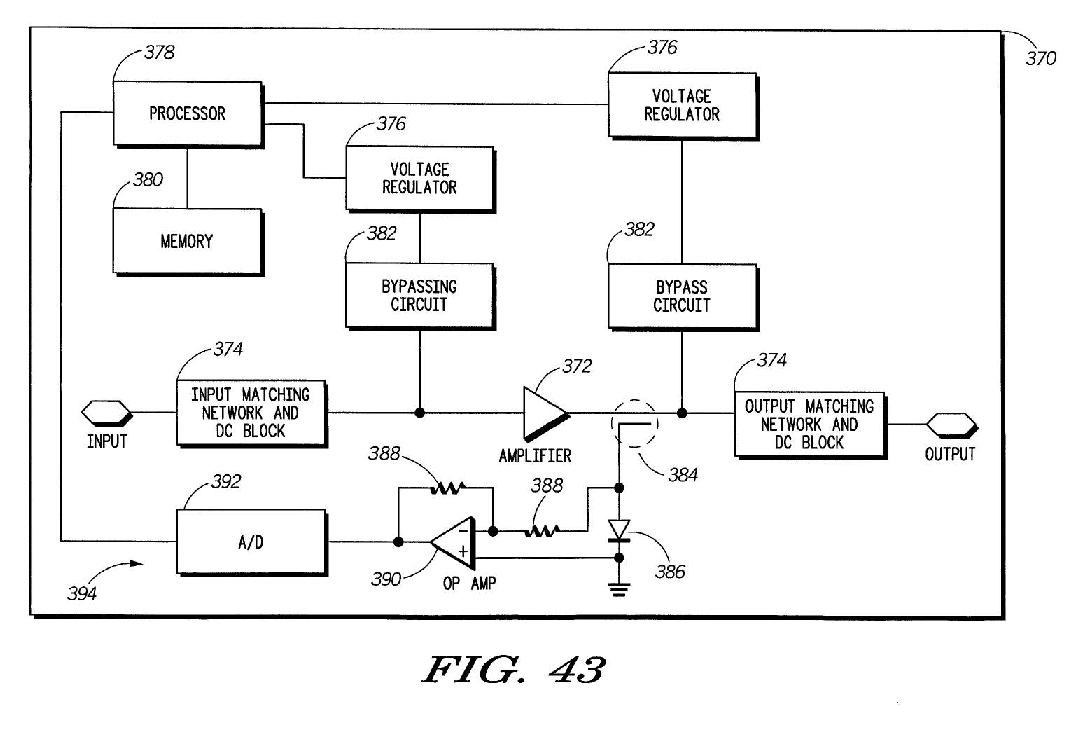

FIG. 43 illustrates an alternative embodiment of the bias control of the integrated circuit of the monolithic device 370 of FIG. 41. The amplifier 372 and bias control devices are integrated with a feedback loop 394. The feedback loop 394 includes a line coupler 384, a diode 386, resistors 388, an operational amplifier 390 and an ADC 392. Different feedback loops 394 with additional, fewer or different devices may be used. The feedback loop 394 comprises a bias controlling device that controls the processor 378 and voltage regulator 376 connected with the drain of the transistor of the amplifier 372. The feedback loop 394 allows the amplifier 372 to maintain a desired or constant output or to vary the output by a selected amount.

The line coupler 384, diode 386, resistors 388, operational amplifier 390 and ADC 392 comprise any of the various devices or alternatives discussed above. In one embodiment, the line coupler 384 comprises a 20 dB line coupler, but other line couplers with different sensitivities can be used. The line coupler 384, diode 386, resistors 388, operational amplifier 390 and ADC 392 are integrated in a Group IV semiconductor material, but one or more or parts of these devices can be integrated in other materials of the monolithic device 370. For example, the diode 386 is formed on a compound semiconductor.

A voltage responsive to the output of the amplifier 372 is generated in the line coupler 384. The resulting voltage across the diode 386 is amplified by the operational amplifier 390 as a function of the resistors 388. The ADC 392 converts the output of the operational amplifier 390 to a digital signal. The sampled data is provided to the processor 378. The processor 378 compares the sampled data representing the output of the amplifier 372 with a desired output level. One or both of the voltage regulators 376 are adjusted to provide a desired bias. In response to the changed bias, the gain of the amplifier 372 changes. The diode 386 allows the integrated circuit to adjust power output based on signals within the monolithic device 370 without external input. Other devices, such as a resistor, providing a voltage proportional to the output from the amplifier 372 can be used.

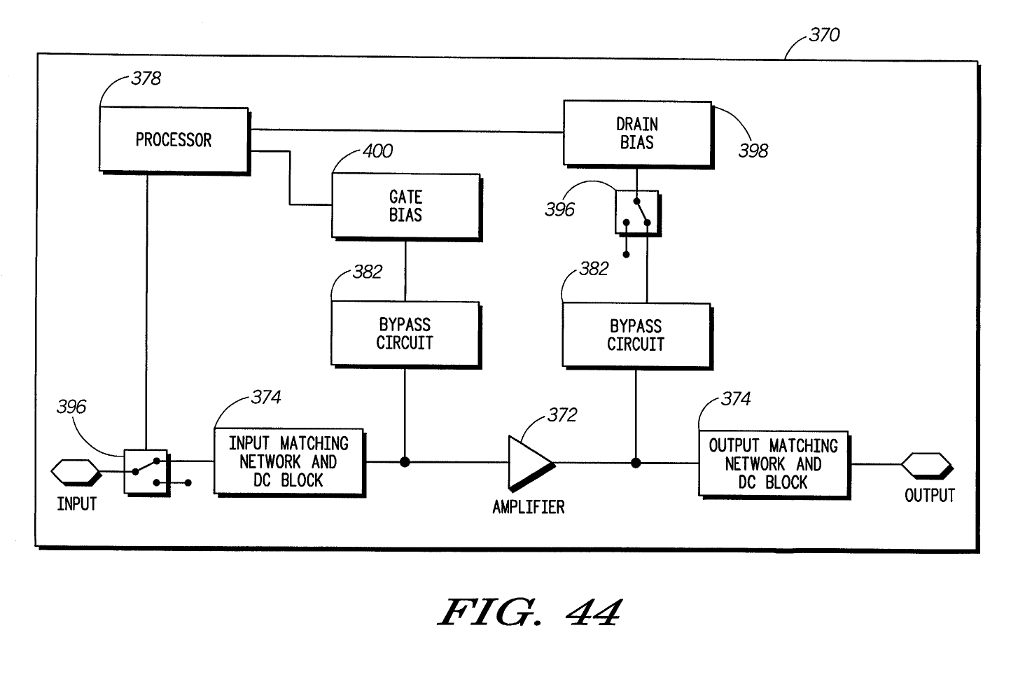

FIG. 44 illustrates another embodiment of bias control integrated on the monolithic device 370 of FIG. 41. The bias control operates the amplifier 372 in pulsed or continuous modes. For example, the amplifier 372 amplifies transmit signals, so is turned off periodically during receive operation. In one embodiment, the voltage regulators 376 turn on or off the bias voltage provided to the drain of the transistor of the amplifier 372. In the embodiment illustrated in FIG. 44, switches 396 connected with a drain bias 398 and a gate bias 400 control operation during different modes of operation.

The switches 396 comprise any of the various devices discussed above, including alternatives. The gate bias 400 and drain bias 396 comprise voltage sources, such as voltage regulators, constant current sources or other devices now know or later developed, integrated on the monolithic device 370 or connected external to the semiconductor structure 370. The switches 396 are formed in a Group IV material, such as silicon, but can be formed in other materials of the monolithic device. The gate and drain bias 398 and 400 are provided externally to the monolithic device 370 or formed on the monolithic device 370. For formation on the monolithic device, a voltage regulator or other voltage source is provided, such as shown in FIG. 41.

During transmit modes of operation, the processor 378 causes the switches 396 to connect an input signal and the drain bias 398 to the amplifier 372. During receive modes of operation, the processor 378 causes the switches 396 to disconnect the input and the drain bias 398 from the amplifier 372. In alternative embodiments, only one switch 396 associated with the drain bias 398 is provided, but additional switches can be used (e.g. providing a switch for the gate bias voltage). In other embodiments, power or the drain bias voltage is selectively provided to the amplifier 372 based on modes of operation other than transmit and receive modes.

Disconnecting the drain bias 396 may prolong the operation of the amplifier 372 and the drain bias 396. Integration of this timing or mode control of the bias for the amplifier 372 on the same semiconductor structure 370 provides for smaller, less lossy and cheaper integrated circuits. Integration also allows control using active or passive devices on a different type of semiconductor material than the controlled active or passive devices. For example, the amplifier 372 is formed on compound semiconductor materials for operation at radio or microwave frequencies and the bias control devices are formed in a Group IV material.

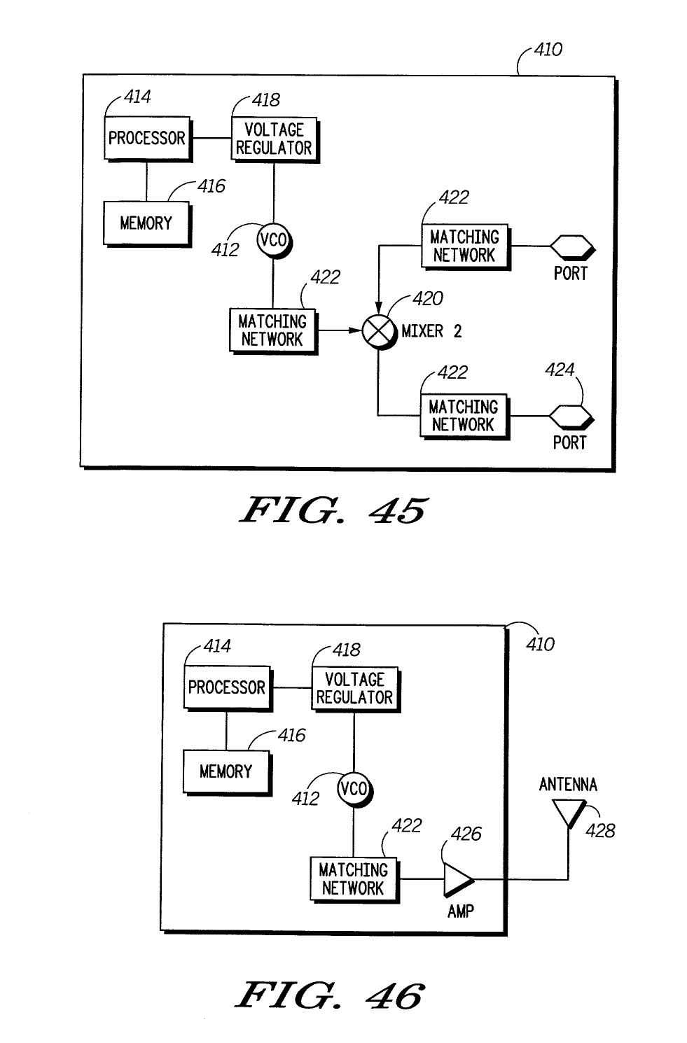

FIGS. 45 and 46 illustrate bias control of an output frequency. In FIG. 45, control devices for a voltage controlled oscillator 412 and the voltage controlled oscillator 412 are integrated on a monolithic device or the same semiconductor structure 410. A processor 414 and associated memory 416 control a voltage regulator 418. The voltage regulator 418 controls the bias of a transistor of the voltage controlled oscillator 412. In alternative embodiments, the voltage controlled oscillator 412 comprises a phased locked loop. The voltage controlled oscillator 412 controls the mixer 420. Matching circuitry 422 connects with the mixer 420. Different, fewer or additional devices can be included. These various devices 412, 414, 416, 418, 420 and 422 comprise the devices discussed above and alternatives disclosed herein.

A radio frequency or other frequency signal is input through matching circuitry 422 to the mixer 420. The output of the voltage controlled oscillator 412 connected through matching circuitry 422 is a local oscillator signal or tone used by the mixer 412. The mixer 412 mixes the input signals or demodulates one signal with the other. An intermediate output signal of the mixer 412 passes through matching circuitry 422 to an output port 424.

In one embodiment, the voltage controlled oscillator 412 and mixer 420 are formed in compound semiconductor material of the monolithic device 410. The matching circuitry 422 is integrated in any of the materials of the monolithic device 410, such as the compound semiconductor material. The voltage controlled oscillator 412 and mixer 420 operate at frequencies, such as radio or microwave frequencies, corresponding to the compound semiconductor material. The voltage regulator 418, processor 414 and memory 416 are formed in a Group IV material, such as silicon, on the monolithic device 410. Since the monolithic device 410 includes both compound and Group IV semiconductor structures, control of compound semiconductor devices is integrated on one semiconductor structure 410.

FIG. 46 illustrates using the frequency control circuit (e.g. processor 414, memory 416, voltage regulator 418 and/or voltage controlled oscillator 412) to generate a transmit signal. The voltage controlled oscillator 412 connects through matching circuitry 422 to an amplifier 426. The amplifier 426 connects with an antenna 428. Different, additional or fewer devices can be used. These various devices 412, 414, 416, 418, 426 and 422 comprise the devices discussed above and alternatives disclosed herein. For example, the amplifier 426 comprises a power combining amplifier formed from one or more transistors for increasing an amplitude of the input signal.

The processor 414 and voltage regulator 418 control the bias of the voltage controlled oscillator 412. The frequency modulated or other signal output by the voltage controlled oscillator 412 is amplified by the amplifier 426. The antenna 428 transmits the amplified signal. The antenna 428 comprises wires, patches, piezoelectric material, charge coupled devices, light sensing diodes or a microelectromechanical systems (MEMS)(e.g. membranes) antenna. In one embodiment, the antenna 428 is integrated on the monolithic device. For example, a metalized trace or patch is deposited within or on an outer surface of the monolithic device 410. As another example, a MEMS device is formed on the monolithic device 410 by deposition and etching, such as using complementary metal-oxide semiconductor (CMOS) processing. In yet another example, a light sensitive diode is formed in Group IV or compound semiconductor material. In other alternative embodiments, the antenna 428 is separate from but electrically connects with the monolithic device 410.

In one embodiment, all or parts of the voltage controlled oscillator 412 and amplifier 426 are integrated in compound semiconductor material of the monolithic device 410. The compound semiconductor material allows operation of the amplifier 426 and voltage controlled oscillator 412 at higher frequencies than Group IV materials. For example, the monolithic device 410 comprises a radio or microwave frequency transmitter. Since the monolithic device 410 also includes Group IV semiconductor material, additional control components (e.g. memory 416, processor 414 and voltage regulator 418) are integrated on the same device. The controlling and controlled devices integrated on the same semiconductor structure 410 provide for cheaper, less lossy and smaller circuits with a broader range of possible frequencies of operation.

As an alternative to generating a signal for modulation by a mixer with a voltage controlled oscillator as shown in FIG. 45, a processor can be used to generate the signal. FIG. 47 illustrates control of a mixer 434 with a processor 432 integrated on the same monolithic device 430. The processor 432 comprises a signal generator or other device as discussed above. The alternatives to the processor 432 discussed above can also be used. The processor 432 generates a signal to be modulated, such as an envelope or carrier signal. Phase, amplitude, frequency, other modulation, time division multiplexing, code division multiplexing or other multiplexing can be used.

The mixer 434 comprises the devices or alternatives discussed above. The mixer 434 modulates the signal from the processor 432 with another signal, such as a low frequency signal. In an alternative embodiment, a voltage controlled oscillator as illustrated in FIG. 45 generates the low frequency signal. The other signal and the output of the mixer 434 are provided from or to other integrated circuitry or external devices.

In one embodiment, the mixer 434 is integrated on compound semiconductor material, and the processor 432 is integrated on Group IV semiconductor material. The controlling processor 434 is integrated on the same monolithic device 430 as the mixer 434.

Integrated circuits other than the bias control illustrated in FIGS. 40-47 can be formed on different semiconductor materials of one monolithic device. Both controlling and controlled devices are formed on one semiconductor structure. For example, automatic gain control through feedback of an amplifier is provided. As another example, redundancy or selection of amplifiers is controlled. As yet another example, selection of matching or termination circuits is controlled.

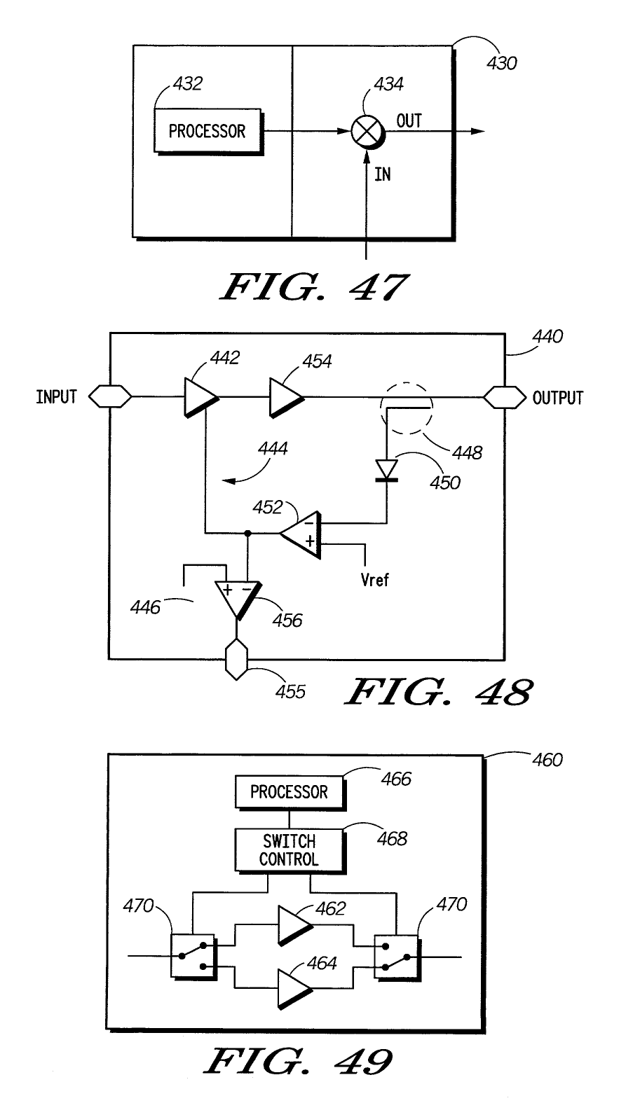

FIG. 48 illustrates control of an amplifier 442 with a feed back loop 444 integrated on a monolithic device 440. FIG. 48 also illustrates a telemetry circuit 446 integrated on the monolithic device 440. In alternative embodiments, the feed back loop 444 is integrated without the telemetry circuit 446 or vice versa.

The feedback loop 444 comprises a line coupler 448, a diode 450, and an operational amplifier 452. These devices 448, 450 and 452 comprise the devices or alternatives discussed above. Different, additional, or fewer devices can be used, such as the feedback loop illustrated in FIG. 43.

The line coupler 448 is positioned by the output of an amplifier 454. The amplifier 454 comprises a power combining amplifier or other amplifier discussed above. In alternative embodiments, the line coupler 448 connects with the output of the amplifier 442 with or without integration or inclusion of the amplifier 454. The amplifier 442 comprises any of the amplifiers discussed above with variable gain.

The signal generated in the line coupler 448 passes through the diode 450 to the operational amplifier 452. A reference voltage is also input to the operational amplifier 452. The operational amplifier 452 outputs a signal indicating a difference between the two inputs. The difference controls the bias of the amplifier 442. In alternative embodiments, a processor or voltage regulator receives the output of the operational amplifier 452 and controls the bias of a transistor of the amplifier 442 accordingly.

In one embodiment, the amplifiers 442 and 454 are integrated in compound semiconductor material of the monolithic device 440. Accordingly, the characteristics of amplifiers formed at least in part in compound semiconductor material are provided. All or part of the feedback loop 444 is integrated in Group IV material. Multiple semiconductor materials on the monolithic device 440 provides for amplification with compound semiconductor devices and control by devices integrated in Group UV semiconductor material. Smaller, cheaper and less lossy automatic gain control amplifier integrated circuits are formed.

The telemetry circuit 446 includes the line coupler 448, the diode 450, the amplifier 452 and another amplifier 456. Fewer, different or additional devices can be used. For example, in alternative embodiments, the telemetry circuit 446 includes the amplifier 452 but not the amplifier 456 or includes neither amplifier 452, 456.

The telemetry circuit 446 provides status or operation information to other integrated circuits or for transmission from the monolithic device 440. The strength or other characteristic of the output of the amplifier 454 is measured to verify proper operation. The signal generated in the line coupler 448 passes through the diode 450 and is input to the operational amplifier 452. A reference voltage is also provided to the operational amplifier 452. The operational amplifier 452 outputs a signal representing the difference between the reference voltage and the line coupler signal. The output of the operational amplifier 452 can be used as a telemetry signal. Where a different signal is used for telemetry than for automatic gain control, the further operational amplifier 456 converts the output to a signal appropriate for telemetry. A reference voltage is also input to the operational amplifier 456. The output at port 455 of the operational amplifier 456 represents the difference between the two inputs. Matching circuitry can be used to weight the inputs to one or both of the operational amplifiers 452 and 456. The output of the telemetry circuit 446 is provided to a connector, such as a trace or via, for external connection (i.e. connection to a device external to the monolithic device 440). Alternatively, the output is provided to other integrated circuitry, such as processor.

In one embodiment, part or all of the telemetry circuit 446 is integrated in Group IV semiconductor material of the monolithic device 440. Multiple semiconductor materials on the monolithic device 440 provides for amplification with compound semiconductor devices and telemetry by devices integrated in Group IV semiconductor material. Smaller, cheaper and less lossy telemetry amplifier integrated circuits are formed.

FIG. 49 illustrates integrating both redundant circuits and control circuits for selecting redundant circuits on a monolithic device 460. Two amplifiers 462 and 464 are integrated on the monolithic device 460. In one embodiment, the amplifiers 462 and 464 comprise substantially similar devices, but different devices can be used. In alternative embodiments, other circuits, such as any combination of one or more of passive or active devices, are used instead of or in addition to the amplifiers 462 and 464 as redundant circuits. More than two redundant circuits can be provided.

Selection of the redundant amplifiers 462 and 464 is controlled by a processor 466, a switch control 468 and switches 470. The processor 466 and switches 470 comprise any of the devices or alternative discussed above. The switch control 468 comprises programmable voltage regulator, DAC or other voltage source. In alternative embodiments, the switches 470 respond to the processor 466 without the switch control 468. In other embodiments, the processor 466 with or without voltage regulators also controls the bias of the amplifiers 462 and 464. In yet another alternative, the switch 470, such as a programmable switch, is controlled in response to digital input.

The processor 466 controls the switch control 468 for selecting redundant circuits. Using feedback, such as illustrated in FIG. 43 or other inputs, the processor determines an appropriate amplifier 462 or 464 and outputs a corresponding control signal. The switch control 468 controls the switches 470 for selecting redundant circuits, such as one of the redundant amplifiers 462 or 464. The switches 470 connect to the same amplifier 462 or 464. If one amplifier 462, 464 fails or performs poorly, the other amplifier 464, 462 can be selected. The amplifiers 462, 264 can alternatively or additionally be selected as a function of time, mode of operation or other factor.

In an alternative embodiment, the amplifiers 462 or 464 (or other circuits) comprise different devices, such as higher gain and lower gain amplifiers or amplifiers with different frequency response. For example, one amplifier 462 is formed in compound semiconductor material and the other amplifier 464 is formed in Group IV semiconductor material. The processor 466 selects one amplifier 462 or 464 as a function of the desired performance. For different performance, a different amplifier 462, 464 is selected with the switches 470.

In yet another alternative embodiment, the switches 470 are operable to connect one or both of the amplifiers 462 and 464 or other circuits to an input or output. The amplifiers 462 and 464 can be used in parallel or separately in response to control signals from the processor 466.

In one embodiment, the amplifiers 462 and 464 (or other circuits) are integrated on a compound semiconductor material of the monolithic device 460. The switches 470 are integrated on any of the materials of the monolithic device 460, such as the compound or Group IV semiconductor material. The processor 466 and switch control 468 are integrated on Group IV semiconductor material (e.g. monocrystalline silicon substrate). Controlling and controlled devices are integrated on one monolithic device 460. The monolithic device 460 also includes redundant or alternative circuits formed in the same or different materials, allowing for more versatile circuit design or operation on one semiconductor structure.

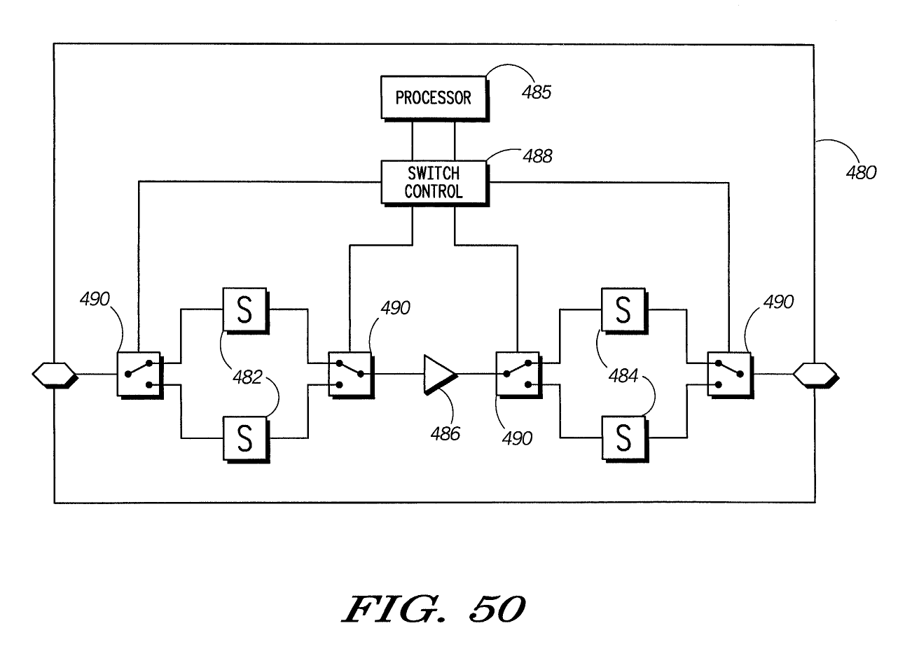

FIG. 50 illustrates integrating multiple input and output matching circuits 482 and 484 with control circuits for selecting the input and output matching circuits 482 and 484 on a monolithic device 480. An amplifier 486 is integrated on the monolithic device 460 with the associated input and output matching circuits 482 and 484. In alternative embodiments, active or passive devices arranged as circuits other than an amplifier can be used instead of or in addition to the amplifier 486. The two input matching circuits 482 comprise different matching circuits, such as circuits with different resistor values. Likewise, the two output matching circuits 484 comprise different matching circuits, such as circuits with different resistor values. More than two input or output matching circuits 482 and 484 can be provided.

One or more input and one or more output matching circuits 482 and 484 are selected for operation with the amplifier 486. A processor 485, a switch control 488 and switches 490 control selection of the matching circuits 482 and 484. The processor 485, matching circuitry 482 and 484 and switches 490 comprise any of the devices or alternative discussed above. The switch control 488 comprises programmable voltage regulator, DAC or other voltage source. In alternative embodiments, the switches 490 respond to the processor 485 without the switch control 488. In yet another alternative, the switch 470, such as a programmable switch, is controlled in response to digital input. In other embodiments, the processor 485 with or without voltage regulators also controls the bias of the amplifier 486.

The processor 485 controls the switch control 488 for selecting input and output matching circuits 482 and 484. Using feedback, such as illustrated in FIG. 43 or other inputs, the processor determines an appropriate one or more input and one or more output matching circuits 482 and 484 and outputs a corresponding control signal. The switch control 488 controls the switches 490 for selecting the matching circuits 482 and 484. The switches 490 connect the selected input matching circuit or circuits 482 to the input and to the amplifier 486. Other switches connect the selected output matching circuit or circuits 484 to the amplifier 486 and to the output. The operation of the amplifier 486 is controlled by selection of matching circuits 482 and 484.

Different combinations of input and output matching circuits 482 and 484 can be used on the same monolithic device 480. In one embodiment, two or more input matching circuits 482 are connected to the input and to the amplifier 486 at a same time. Likewise, multiple output matching circuits 484 can be connected with the amplifier 486 and with the output. In alternative embodiments, all of or part of the input or output matching circuit is fixed or not selectable.

In one embodiment, the amplifier 486 is integrated on a compound semiconductor material of the monolithic device 480. The switches 490 are integrated on any of the materials of the monolithic device 480, such as the compound or Group IV semiconductor material. The processor 485 and switch control 488 are integrated on Group IV semiconductor material (e.g. monocrystalline silicon substrate). Controlling and controlled devices are integrated on one monolithic device 480. The monolithic device 480 includes alternative circuits formed in the same or different materials, allowing for more versatile circuit design on one semiconductor structure 480.

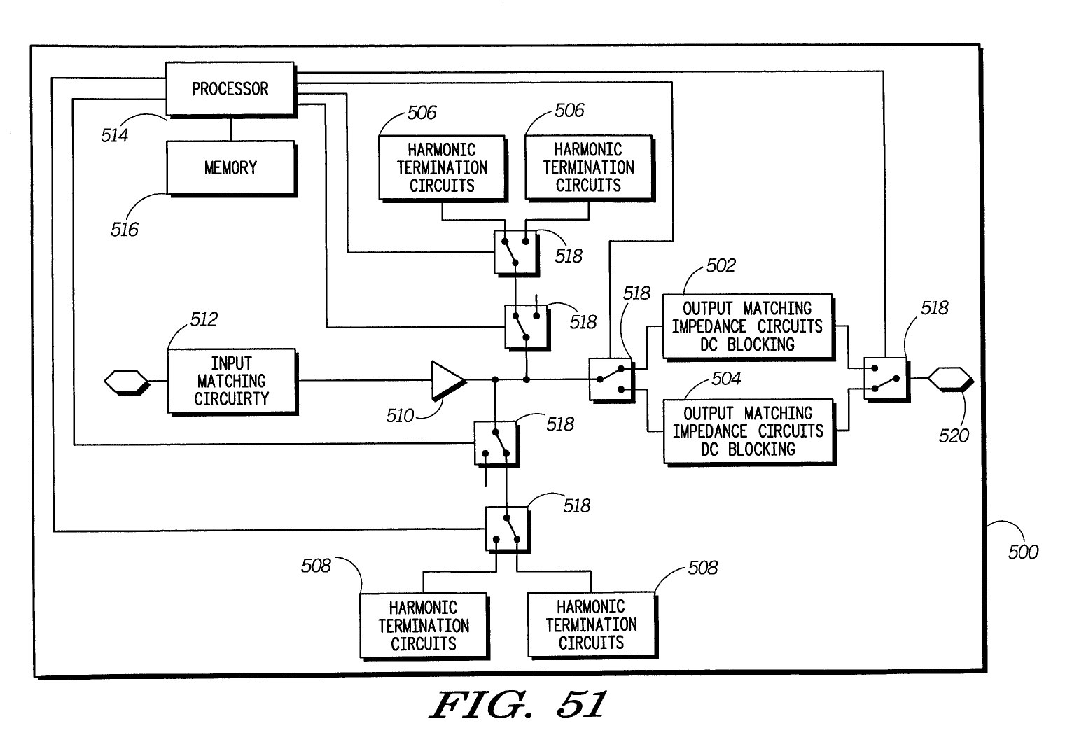

FIG. 51 illustrates integrating multiple output matching circuits, impedance circuits, and/or DC blocking circuits 502 and 504 and control circuits for selecting the output matching, load impedance, and/or DC blocking circuits 502 and 504 on a monolithic device 500. Multiple second and third harmonic termination circuits 506 and 508 are also integrated on the monolithic device 500. An amplifier 510 and associated input matching and DC blocking circuit 512 is also integrated on the monolithic device 500. In alternative embodiments, active or passive devices arranged as circuits other than an amplifier can be used instead of or in addition to the amplifier 510.

The output matching, load impedance, and/or DC blocking circuits 502 and 504 comprise one or more of the circuits or alternative circuits discussed above. For example, the circuits 502 and 504 comprise a resistor network for matching with the amplifier 510, a capacitor for DC blocking and an inductor for phase adjustment of the load. One, more or all of these circuits is different in one circuit 502 than the other circuit 504. In alternative embodiments, one, some or all of the output circuits 502, 504 comprise none or a subset of matching, impedance and DC blocking circuits.

The second harmonic termination circuits 506 comprise one or more of the circuits or alternative circuits discussed above for termination of second harmonics. In one embodiment, different frequency bands are terminated by the two or more second harmonic termination circuits 506. Likewise, the third harmonic termination circuits 508 comprise one or more of the circuits or alternative circuits discussed above for termination third harmonics. In one embodiment, different frequency bands are terminated by the two or more third harmonic termination circuits 508. In one alternative embodiment, only second harmonic or only third harmonic termination circuits 506, 508 are provided. In yet another alternative embodiment, any combination of two or more termination circuits for the same or different harmonics is provided.

None, one or more second harmonic termination circuits 506, third harmonic termination circuits 508 and output circuits 502, 504 are selected for operation with the amplifier 510. A processor 514, memory 516 and switches 518 control selection. The processor 514, memory 516, amplifier 510, input matching circuitry 512 and switches 518 comprise any of the devices or alternatives discussed above. As illustrated, single pole, double throw switches 518 are used, but triple more throw or double or more poles can be used. In alternative embodiments, a switch control is provided for operating the switches 518 in response to the processor 514. In other embodiments, the processor 514 with or without voltage regulators also controls the bias of the amplifier 510.

The processor 514 controls the switches 518 for selecting none, one or more output circuits 502, 504 and none, one or more harmonic termination circuits 506, 508. Using feedback, such as illustrated in FIG. 43 or other inputs, the processor 514 determines an appropriate circuit 502, 504, 506, 508 and outputs a corresponding control signal. The switches 518 connect the selected circuit or circuits 502, 504, 506, 508 to the output of the amplifier 510. For example, one second harmonic termination circuit, one third harmonic termination circuit and one of the output circuits 502 are connected with the output of the amplifier 510 and an output port 520. As another example, the second and/or third harmonic circuits 506 and/or 508 are disconnected from the output of the amplifier 510.

The output signal of the amplifier 510 is controlled by selection of circuits 506, 508, 502 and 504. In alternative embodiments, selectable input circuits, such as input matching, input termination, input blocking or input impedance circuits are provided.

Different combinations of output and termination circuits 502, 504, 506 and 508 can be used on the same monolithic device 500. In one embodiment, two or more output circuits 502, 504 are connected to the amplifier 510 at a same time. Likewise, multiple termination circuits 502 or 504 can be connected with the output of the amplifier 510.

In one embodiment, the amplifier 510 is integrated on a compound semiconductor material of the monolithic device 500. The switches 518 are integrated on any of the materials of the monolithic device 500, such as the compound or Group IV semiconductor material. The processor 514 and memory 516 are integrated on Group IV semiconductor material (e.g. monocrystalline silicon substrate). Controlling and controlled devices are integrated on one monolithic device 500.

The monolithic device 500 includes alternative circuits formed in the same or different materials, allowing for more versatile circuit design on one semiconductor structure 500. Integrated termination circuits 506, 508 can improve efficiency of the amplifier 510, and selectable termination circuits can provide more versatile operation, increase the power output, improve efficiency or alter another characteristic of the amplifier. Providing integrated selectable impedance matching circuitry allows for different loads to be connected with the output 520 without reducing efficiency (i.e. poorly matched inductance or capacitance).

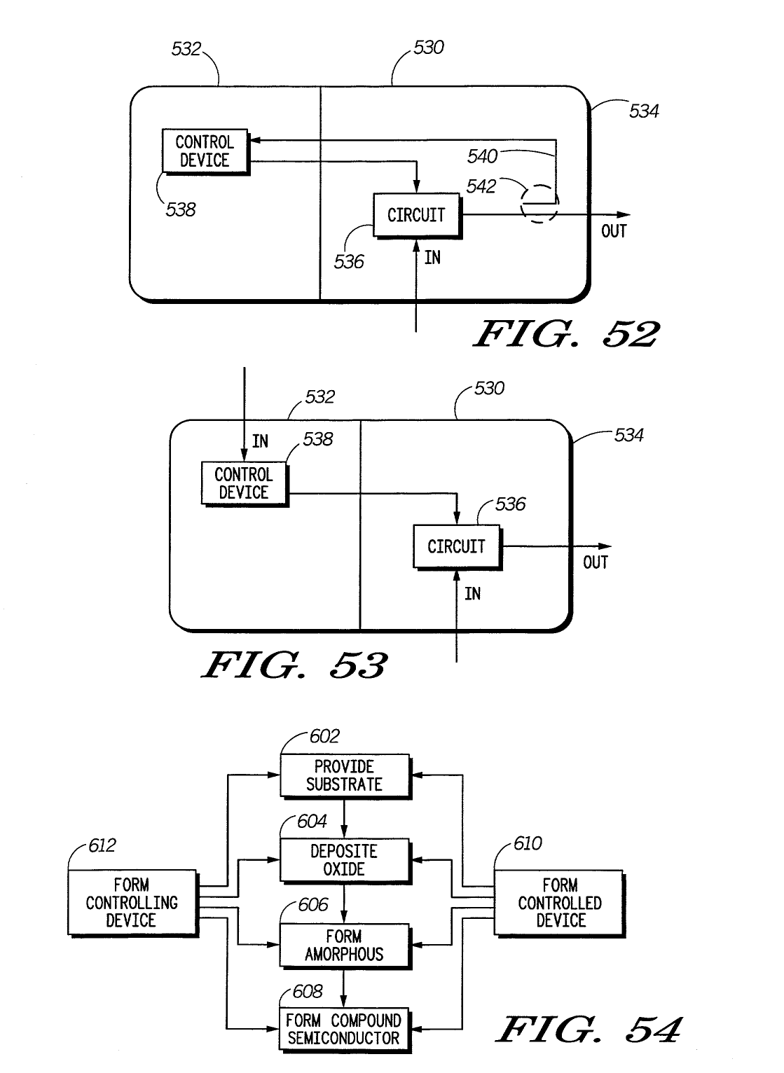

FIGS. 52 and 53 illustrate general integration of controlling devices and controlled devices on a monolithic device 530 having Group IV and compound semiconductor materials 532 and 534. A circuit 536 for operation at radio, microwave or other frequencies is integrated on the compound semiconductor material 534. The circuit 536 includes any of the passive or active devices discussed herein, such as optical, radio or microwave wavelength devices. The circuit 536 receives an input and generates an output. The circuit 536 is responsive to control signals from a control device 538.

The control device 538 comprises a processor, a digital signal processor, an ASIC, a memory device, temperature sensor, current or voltage sensor and/or a lookup table. The control device 538 is integrated, at least in part, on the Group IV semiconductor material, such as monocrystalline silicon. The controlled device or circuit 536 is responsive to the controlling device 538.

In the embodiment of FIG. 53, the control device 538 is responsive to an input from devices on or external to the monolithic device 530. For example, the control device 538 comprises a look-up table that outputs control signals or data in response to an input. The input indicates an address or information to determine an address in the lookup table.

In the embodiment of FIG. 52, the control device 538 is responsive to a feedback loop 540. For example, the feedback loop 540 includes a line coupler or power splitter 542 for measuring an output characteristic. The control device 538 controls the gain or other parameter of the circuit 536 as a function of the signal on the feedback loop 540.

In alternative embodiments, the feedback loop 540 of FIG. 52 is used with the embodiment of FIG. 53 or the input to the control device 538 of FIG. 53 is used with the embodiment of FIG. 52. Other circuitry can be integrated on the monolithic device 534.

Various example integrated circuits on a monolithic device are discussed above. Combinations of the integrated circuits can be used. For example, two or more of temperature sensing and control, bias modulation, bias control of class of operation, timing control of bias, control of bias voltage, bias control of frequency, automatic gain control, redundant circuit selection, telemetry sensing, selectable circuits (e.g. matching, termination, amplifier or other circuits), look-up table control, feedback control or other circuits are integrated on the same monolithic device with controlled devices. For example, temperature sensing with bias control can be used to control an optical device, such as a semiconductor laser. Any of the circuits discussed above can be used for controlling radio frequency, microwave frequency, optical wavelength or other controlled devices on the monolithic device.

FIG. 54 illustrates a flow chart summarizing the process of one embodiment discussed above for fabricating the semiconductor structure. In act 602, a monocrystalline silicon substrate or other Group IV substrate is provided. A monocrystalline perovskite oxide film or other oxide is deposited overlying the monocrystalline silicon substrate in act 604. The film has a thickness less than a thickness of the material that would result in strain-induced defects. In act 606, an amorphous oxide interface layer or layer of other intermediate materials (e.g. amorphous oxide interface layer containing at least silicon and oxygen) is formed at an interface between the monocrystalline perovskite oxide film and the monocrystalline silicon substrate. A monocrystalline compound semiconductor layer is epitaxially or otherwise formed overlying the monocrystalline perovskite oxide film in act 608.

In acts 610 and 612, during, between or after the formation of the layers discussed above, controlled and controlling devices are formed in at least one of the monocrystalline silicon substrate, the amorphous oxide interface layer, the monocrystalline perovskite oxide film and the monocrystalline compound semiconductor material. The controlled device comprises any of the devices discussed above, such as a variable gain element, a transistor, a voltage controlled oscillator, redundant circuits, an amplifier, matching circuitry, a switch or a mixer. The controlling device comprises any of the devices discussed above, such as a temperature sensor, a bias control device, a switch, a processor or a memory device. The controlled and controlling devices are integrated in any of various configurations, such as a temperature sensor with a variable gain element, a bias control with a transistor, a bias control with a voltage controlled oscillator, a control device with a feedback from a controlled device, a switch with selectable redundant circuits, a switch with an amplifier and a circuit, a switch with selectable matching circuitry, a device for controlling a mixer with the mixer, a memory device with a controlling circuit, and other combinations. In one alternative embodiment, an amplifier or other device for providing telemetry information is integrated with measured devices.

In the foregoing specification, the invention has been described with reference to specific embodiments. However, one of ordinary skill in the art appreciates that various modifications and changes can be made without departing from the scope of the present invention as set forth in the claims below. Accordingly, the specification and figures are to be regarded in an illustrative rather than a restrictive sense, and all such modifications are intended to be included within the scope of present invention.

Benefits, other advantages, and solutions to problems have been described above with regard to specific embodiments. However, the benefits, advantages, solutions to problems, and any element(s) that may cause any benefit, advantage, or solution to occur or become more pronounced are not to be construed as a critical, required, or essential features or elements of any or all the claims. As used herein, the terms “comprises,” “comprising,” or any other variation thereof, are intended to cover a non-exclusive inclusion, such that a process, method, article, or apparatus that comprises a list of elements does not include only those elements but may include other elements not expressly listed or inherent to such process, method, article, or apparatus.

We claim:

1. A semiconductor structure comprising:
a monocrystalline silicon substrate;
an amorphous oxide material overlying the monocrystalline silicon substrate;
a monocrystalline perovskite oxide material overlying the amorphous oxide material;
a monocrystalline compound semiconductor material overlying the monocrystalline perovskite oxide material;
a controlling device formed in at least one of the monocrystalline silicon substrate, the amorphous oxide material, the monocrystalline perovskite oxide material and the monocrystalline compound semiconductor material, and a controlled device formed in at least one of the monocrystalline silicon substrate, the amorphous oxide material, the monocrystalline perovskite oxide material and the monocrystalline compound semiconductor material.

2. The structure of claim 1 wherein the controlling device comprises a transistor formed in the monocrystalline silicon substrate.

3. The structure of claim 1 wherein the controlling device comprises a processor.

4. The structure of claim 1 wherein the controlling device comprises an application specific integrated circuit.

5. The structure of claim 1 wherein the controlling device comprises an amplifier.

6. The structure of claim 1 wherein the controlling device comprises a switch.

7. The structure of claim 1 wherein the controlling device comprises a voltage regulator.

8. The structure of claim 1 wherein the controlling device comprises a memory device.

9. The structure of claim 1 wherein the controlling device comprises a line coupler.

10. The structure of claim 1 wherein the controlled device comprises an amplifier.

11. The structure of claim 1 wherein the controlled device comprises a voltage controlled oscillator.

12. The structure of claim 1 wherein the controlled device comprises a transistor.

13. The structure of claim 1 wherein the controlled device comprises a switch.

14. The structure of claim 1 wherein the controlled device comprises a passive device.

15. The structure of claim 1 wherein the controlled device comprises an attenuator.

16. The structure of claim 1 wherein the controlled device comprises a mixer.

17. The structure of claim 1 wherein the controlling device comprises a temperature sensor and the controlled device comprises an amplifier.

18. The structure of claim 1 wherein the controlled device comprises an amplifier and the controlling device comprises a voltage regulator connected to a bias input of the amplifier.

19. The structure of claim 18 wherein the bias input comprises a drain bias.

20. The structure of claim 18 wherein the bias input comprises a gate bias.

21. The structure of claim 1 wherein the controlled device comprises an amplifier and the controlling device comprises a switch operable to select a bias source connected to the amplifier.

22. The structure of claim 1 wherein the controlled device comprises a transistor and the controlling device comprises a voltage regulator, further comprising a constant current circuit connected between the controlled and controlling devices.

23. The structure of claim 1 wherein the controlled device comprises a voltage controlled oscillator and the controlling device comprises a voltage regulator.

24. The structure of claim 1 wherein the controlled device comprises a first amplifier formed in the monocrystalline compound semiconductor material and the controlling device comprises a second amplifier formed in the monocrystalline silicon substrate, the second amplifier responsive to an output of the first amplifier and the first amplifier responsive to an output of the second amplifier.

25. The structure of claim 1 wherein the controlled device comprises first and second amplifiers and the controlling device comprises a switch operable to select the first and second amplifiers.

26. The structure of claim 25 further comprising a processor formed in the monocrystalline silicon substrate, the processor operable to control the switch.

27. The structure of claim 25 wherein the first amplifier is formed on the monocrystalline compound semiconductor material and the second amplifier is formed on the monocrystalline silicon substrate.

28. The structure of claim 1 further comprising an output from the control device, the output available external to the structure.

29. The structure of claim 1 wherein the controlled device comprises a switch connected with an amplifier and the controlling device comprises a processor connected with the switch to select a matching circuit connectable to the amplifier.

30. The structure of claim 1 wherein the controlled device comprises a switch connected with an amplifier and the controlling device comprises a processor connected with the switch to select a harmonic termination circuit connectable to the amplifier.

31. The structure of claim 1 wherein the controlled device comprises a mixer formed in the monocrystalline compound semiconductor material and the controlling device comprises a processor formed in the monocrystalline silicon substrate, the processor connected with the mixer.

32. The structure of claim 1 wherein the controlled device comprises a voltage controlled oscillator formed in the monocrystalline compound semiconductor material and the controlling device comprises a processor formed in the monocrystalline silicon substrate, the processor connected with the voltage controlled oscillator.

33. The structure of claim 1 wherein the controlled device is formed in the monocrystalline compound semiconductor material and the controlling device is formed in the monocrystalline silicon substrate, the controlling device responsive to an output of the controlled device and connected with the controlled device.

34. The structure of claim 1 wherein the controlling device is responsive to an output of the controlled device and connected with the controlled device.

35. The structure of claim 1 wherein the controlling device comprises a memory device and the controlled device is responsive to the memory device.

36. The structure of claim 35 wherein the controlled device is formed in the monocrystalline compound semiconductor material and the memory device is formed in the monocrystalline silicon substrate.

37. The structure of claim 1 wherein the controlled device comprises an optical device.

38. The structure of claim 37 wherein the controlled device comprises a semiconductor laser.

39. A process for fabricating a semiconductor structure comprising:
(a) providing a monocrystalline silicon substrate;
(b) depositing a monocrystalline perovskite oxide film overlying the monocrystalline silicon substrate, the film having a thickness less than a thickness of the material that would result in strain-induced defects;
(c) forming an amorphous oxide interface layer containing at least silicon and oxygen at an interface between the monocrystalline perovskite oxide film and the monocrystalline silicon substrate;
(d) epitaxially forming a monocrystalline compound semiconductor layer overlying the monocrystalline perovskite oxide film;
(e) forming a first device in one of the monocrystalline silicon substrate, the amorphous oxide material, the monocrystalline perovskite oxide material and the monocrystalline compound semiconductor material;
(f) forming a second device in one of the monocrystalline silicon substrate, the amorphous oxide material, the monocrystalline perovskite oxide material and the monocrystalline compound semiconductor material; and
(g) connecting the second device to control operation of the first device.

40. The process of claim 39 further comprising:
(h) forming a temperature sensor in one of the monocrystalline silicon substrate, the amorphous oxide material, the monocrystalline perovskite oxide material and the monocrystalline compound semiconductor material;
wherein the first device is responsive to the temperature sensor.

41. The process of claim 39 wherein (g) comprises connecting the second device to a bias input of the first device.

42. The process of claim 41 wherein (g) comprises connecting the second device to a drain bias of the first device.

43. The process of claim 41 wherein (g) comprises connecting the second device to a gate bias of the first device.

44. The process of claim 41 wherein the second device comprises a switch connected to a bias input of the first device.

45. The process of claim 39 wherein the first device comprises a voltage controlled oscillator and (g) comprises connecting the second device to a voltage input of the voltage controlled oscillator.

46. The process of claim 39 wherein the second device comprises a differential amplifier;
further comprising:
(h) connecting in the semiconductor device a diode between two inputs of the differential amplifier.

47. The process of claim 39 wherein the first device comprises redundant circuits and a switch operable to select the redundant circuits.

48. The process of claim 39 wherein the first device comprises first and second matching circuitry and a switch operable to select one of the first and second matching circuitry.

49. The process of claim 39 wherein the first device comprises harmonic termination circuitry and switch operable to connect with the harmonic termination circuitry.

50. The process of claim 39 wherein the first device comprises a plurality of amplifiers and a switch operable to select combinations of amplifiers.

51. The process of claim 39 wherein the first device comprises a mixer, the second device comprises a signal generator, and (g) comprises connecting the signal generator to the mixer.

52. The process of claim 39 wherein the first device comprises a voltage controlled oscillator, the second device comprises a processor and (g) comprises connecting the processor to a voltage input of the voltage controlled oscillator.

53. The process of claim 39 wherein (g) comprises connecting the second device in a feedback from an output of the first device.

54. The process of claim 39 wherein the second device comprises a memory device and (g) comprises connecting the first device to receive data from the second device.

55. The process of claim 39 wherein (e) comprises forming an optical device.

56. The process of claim 55 wherein (e) comprises forming a semiconductor laser.

57. A process for fabricating a semiconductor structure comprising:
(a) providing a monocrystalline silicon substrate;
(b) depositing a monocrystalline perovskite oxide film overlying the monocrystalline silicon substrate, the film having a thickness less than a thickness of the material that would result in strain-induced defects;
(c) forming an amorphous oxide interface layer containing at least silicon and oxygen at an interface between the monocrystalline perovskite oxide film and the monocrystalline silicon substrate;
(d) epitaxially forming a monocrystalline compound semiconductor layer overlying the monocrystalline perovskite oxide film;
(e) integrating a temperature sensor with a variable gain element on the semiconductor structure.

58. The process of claim 57 wherein the variable gain element comprises an amplifier, and further comprising:
(f) controlling a gain of the amplifier in response to the temperature sensor.

59. The process of claim 57 wherein (e) comprises integrating the temperature sensor with an optical device.

60. The process of claim 59 wherein (e) comprises integrating the optical device as a semiconductor laser.

61. A semiconductor structure comprising:
a monocrystalline silicon substrate;
an amorphous oxide material overlying the monocrystalline silicon substrate;
a monocrystalline perovskite oxide material overlying the amorphous oxide material;
a monocrystalline compound semiconductor material overlying the monocrystalline perovskite oxide material;
a temperature formed in at least one of the monocrystalline silicon substrate, the amorphous oxide material, the monocrystalline perovskite oxide material and the monocrystalline compound semiconductor material; and
a variable gain element formed in at least one of the monocrystalline silicon substrate, the amorphous oxide material, the monocrystalline perovskite oxide material and the monocrystalline compound semiconductor material, the variable gain element connected with the temperature sensor.

62. A process for fabricating a semiconductor structure comprising:
(a) providing a monocrystalline silicon substrate;
(b) depositing a monocrystalline perovskite oxide film overlying the monocrystalline silicon substrate, the film having a thickness less than a thickness of the material that would result in strain-induced defects;
(c) forming an amorphous oxide interface layer containing at least silicon and oxygen at an interface between the monocrystalline perovskite oxide film and the monocrystalline silicon substrate;
(d) epitaxially forming a monocrystalline compound semiconductor layer overlying the monocrystalline perovskite oxide film;
(e) integrating a bias control device with a transistor on the semiconductor structure.

63. The process of claim 62 wherein (e) comprises forming the bias control device in the monocrystalline silicon substrate and forming the transistor in the monocrystalline compound semiconductor material.

64. The process of claim 62 wherein (e) comprises integrating the bias control device as a voltage regulator connected with a drain of the transistor.

65. The process of claim 62 wherein (e) comprises integrating the bias control device as a voltage regulator connected with a gate of the transistor.

66. The process of claim 62 further comprising:
(f) selecting a class of operation of the transistor in response to the bias control device.

67. The process of claim 62 further comprising:
(f) integrating a switch on the semiconductor structure, the switch operative to connect and disconnect a bias voltage source from the transistor.

68. The process of claim 62 further comprising:
(f) integrating a constant current circuit connected between the bias control device and the transistor.

69. The process of claim 62 wherein (e) comprises integrating the bias control device as a voltage regulator connected with the transistor.

70. The process of claim 62 wherein (e) comprises integrating the bias control device with the transistor comprising an optical device.

71. The process of claim 70 wherein (e) comprises integrating a semiconductor laser.

72. A semiconductor structure comprising:
a monocrystalline silicon substrate;
an amorphous oxide material overlying the monocrystalline silicon substrate; a monocrystalline perovskite oxide material overlying the amorphous oxide material;
a monocrystalline compound semiconductor material overlying the monocrystalline perovskite oxide material;
a bias control device formed in at least one of the monocrystalline silicon substrate, the amorphous oxide material, the monocrystalline perovskite oxide material and the monocrystalline compound semiconductor material; and
a transistor formed in at least one of the monocrystalline silicon substrate, the amorphous oxide material, the monocrystalline perovskite oxide material and the monocrystalline compound semiconductor material, the bias control device electrically connected with the transistor.

73. A process for fabricating a semiconductor structure comprising:
(a) providing a monocrystalline silicon substrate;
(b) depositing a monocrystalline perovskite oxide film overlying the monocrystalline silicon substrate, the film having a thickness less than a thickness of the material that would result in strain-induced defects;
(c) forming an amorphous oxide interface layer containing at least silicon and oxygen at an interface between the monocrystalline perovskite oxide film and the monocrystalline silicon substrate;
(d) epitaxially forming a monocrystalline compound semiconductor layer overlying the monocrystalline perovskite oxide film;
(e) integrating a bias control device with a voltage controlled oscillator on the semiconductor structure.

74. The process of claim 73 further comprising:
(f) integrating a mixer responsive to the voltage controlled oscillator on the semiconductor device.

75. The process of claim 73 further comprising:
(f) integrating on the semiconductor device an amplifier responsive to an output of the voltage controlled oscillator.

76. A semiconductor structure comprising:
a monocrystalline silicon substrate;
an amorphous oxide material overlying the monocrystalline silicon substrate;
a monocrystalline perovskite oxide material overlying the amorphous oxide material;
a monocrystalline compound semiconductor material overlying the monocrystalline perovskite oxide material;
a bias control device formed in at least one of the monocrystalline silicon substrate, the amorphous oxide material, the monocrystalline perovskite oxide material and the monocrystalline compound semiconductor material; and
a voltage controlled oscillator formed in at least one of the monocrystalline silicon substrate, the amorphous oxide material, the monocrystalline perovskite oxide material and the monocrystalline compound semiconductor material, the bias control device electrically connected with the voltage controlled oscillator.

77. A process for fabricating a semiconductor structure comprising:
(a) providing a monocrystalline silicon substrate;
(b) depositing a monocrystalline perovskite oxide film overlying the monocrystalline silicon substrate, the film having a thickness less than a thickness of the material that would result in strain-induced defects;
(c) forming an amorphous oxide interface layer containing at least silicon and oxygen at an interface between the monocrystalline perovskite oxide film and the monocrystalline silicon substrate;
(d) epitaxially forming a monocrystalline compound semiconductor layer overlying the monocrystalline perovskite oxide film;
(e) integrating a control device with feedback from a controlled device on the semiconductor structure.

78. The process of claim 78 wherein (e) comprises:
(e1) forming an amplifier in the monocrystalline compound semiconductor material; and
(e2) forming a line coupler adjacent an output of the amplifier and connected with the control device.

79. The process of claim 78 wherein (e) comprises:
(e1) forming a processor in the monocrystalline silicon substrate; and
(e2) forming a line coupler adjacent an output of the controlled device and connected with the processor.

80. semiconductor structure comprising:
a monocrystalline silicon substrate;
an amorphous oxide material overlying the monocrystalline silicon substrate;
a monocrystalline perovskite oxide material overlying the amorphous oxide material;
a monocrystalline compound semiconductor material overlying the monocrystalline perovskite oxide material;
a control device formed in at least one of the monocrystalline silicon substrate, the amorphous oxide material, the monocrystalline perovskite oxide material and the monocrystalline compound semiconductor material; and
a controlled device formed in at least one of the monocrystalline silicon substrate, the amorphous oxide material, the monocrystalline perovskite oxide material and the monocrystalline compound semiconductor material, the control device electrically connected with a feedback connection from the controlled device.

81. A process for fabricating a semiconductor structure comprising:
(a) providing a monocrystalline silicon substrate;
(b) depositing a monocrystalline perovskite oxide film overlying the monocrystalline silicon substrate, the film having a thickness less than a thickness of the material that would result in strain-induced defects;
(c) forming an amorphous oxide interface layer containing at least silicon and oxygen at an interface between the monocrystalline perovskite oxide film and the monocrystalline silicon substrate;
(d) epitaxially forming a monocrystalline compound semiconductor layer overlying the monocrystalline perovskite oxide film;
(e) integrating a first circuit and a redundant circuit on the semiconductor device;
(f) integrating on the semiconductor structure a switch operable to select the first and redundant circuits.

82. The processor of claim 82 further comprising:
(g) integrating a processor in the monocrystalline silicon substrate wherein the switch is responsive to the processor.

83. A semiconductor structure comprising:
a monocrystalline silicon substrate;
an amorphous oxide material overlying the monocrystalline silicon substrate;
a monocrystalline perovskite oxide material overlying the amorphous oxide material;
a monocrystalline compound semiconductor material overlying the monocrystalline perovskite oxide material;
redundant circuits formed in at least one of the monocrystalline silicon substrate, the amorphous oxide material, the monocrystalline perovskite oxide material and the monocrystalline compound semiconductor material; and
a switch formed in at least one of the monocrystalline silicon substrate, the amorphous oxide material, the monocrystalline perovskite oxide material and the monocrystalline compound semiconductor material, the switch operable to select one of the redundant circuits.

84. A process for fabricating a semiconductor structure comprising:
(a) providing a monocrystalline silicon substrate;
(b) depositing a monocrystalline perovskite oxide film overlying the monocrystalline silicon substrate, the film having a thickness less than a thickness of the material that would result in strain-induced defects;
(c) forming an amorphous oxide interface layer containing at least silicon and oxygen at an interface between the monocrystalline perovskite oxide film and the monocrystalline silicon substrate;
(d) epitaxially forming a monocrystalline compound semiconductor layer overlying the monocrystalline perovskite oxide film;
(e) integrating a first amplifier on the semiconductor device;
(f) integrating on the semiconductor device a switch operable to connect the first amplifier to a circuit.

85. The process of claim 85 further comprising:
(g) integrating a processor in the monocrystalline silicon substrate wherein the switch is responsive to the processor.

86. The process of claim 85 further comprising:
(g) integrating a second amplifier on the semiconductor device, the second amplifier connectable in parallel with the first amplifier.

87. The process of claim 85 wherein (e) comprises integrating an optical amplifier.

88. A semiconductor structure comprising:
a monocrystalline silicon substrate;
an amorphous oxide material overlying the monocrystalline silicon substrate;
a monocrystalline perovskite oxide material overlying the amorphous oxide material;
a monocrystalline compound semiconductor material overlying the monocrystalline perovskite oxide material;
an amplifier formed in at least one of the monocrystalline silicon substrate, the amorphous oxide material, the monocrystalline perovskite oxide material and the monocrystalline compound semiconductor material; and
a switch formed in at least one of the monocrystalline silicon substrate, the amorphous oxide material, the monocrystalline perovskite oxide material and the monocrystalline compound semiconductor material, the switch operable to selectively electrically connect the amplifier to a circuit.

89. A process for fabricating a semiconductor structure comprising:
(a) providing a monocrystalline silicon substrate;
(b) depositing a monocrystalline perovskite oxide film overlying the monocrystalline silicon substrate, the film having a thickness less than a thickness of the material that would result in strain-induced defects;
(c) forming an amorphous oxide interface layer containing at least silicon and oxygen at an interface between the monocrystalline perovskite oxide film and the monocrystalline silicon substrate;
(d) epitaxially forming a monocrystalline compound semiconductor layer overlying the monocrystalline perovskite oxide film;
(e) integrating on the semiconductor device a first device;
(f) integrating a line coupler adjacent an output of the first device; and
(g) integrating an external connector operable to output a signal responsive to the line coupler.

90. The process of claim 90 further comprising:
(h) integrating an amplifier responsive to the line coupler and having an output connected with the external connector.

91. A semiconductor structure comprising:
a monocrystalline silicon substrate;
an amorphous oxide material overlying the monocrystalline silicon substrate;
a monocrystalline perovskite oxide material overlying the amorphous oxide material;
a monocrystalline compound semiconductor material overlying the monocrystalline perovskite oxide material;
a first device formed in at least one of the monocrystalline silicon substrate, the amorphous oxide material, the monocrystalline perovskite oxide material and the monocrystalline compound semiconductor material; and
a telemetry circuit formed in at least one of the monocrystalline silicon substrate, the amorphous oxide material, the monocrystalline perovskite oxide material and the monocrystalline compound semiconductor material, the telemetry circuit connected with an output of the first device.

92. A process for fabricating a semiconductor structure comprising:
(a) providing a monocrystalline silicon substrate;
(b) depositing a monocrystalline perovskite oxide film overlying the monocrystalline silicon substrate, the film having a thickness less than a thickness of the material that would result in strain-induced defects;
(c) forming an amorphous oxide interface layer containing at least silicon and oxygen at an interface between the monocrystalline perovskite oxide film and the monocrystalline silicon substrate;
(d) epitaxially forming a monocrystalline compound semiconductor layer overlying the monocrystalline perovskite oxide film; and
(e) integrating on the semiconductor device a switch and first matching circuitry connected with the switch.

93. The process of claim 93 wherein (e) comprises integrating on the semiconductor device second matching circuitry where the switch is operable to select one of the first and second matching circuitry.

94. The process of claim 93 wherein the first matching circuitry comprises harmonic termination circuitry and (e) comprises integrating the switch to selectively connect the harmonic termination circuitry.

95. The process of claim 93 further comprising:
(f) integrating on the semiconductor device an amplifier selectively responsive to the first matching circuitry.

96. The process of claim 96 wherein (f) comprises integrating the amplifier as an optical device.

97. A semiconductor structure comprising:
a monocrystalline silicon substrate;
an amorphous oxide material overlying the monocrystalline silicon substrate;
a monocrystalline perovskite oxide material overlying the amorphous oxide material;
a monocrystalline compound semiconductor material overlying the monocrystalline perovskite oxide material;
a switch formed in at least one of the monocrystalline silicon substrate, the amorphous oxide material, the monocrystalline perovskite oxide material and the monocrystalline compound semiconductor material; and
matching circuitry formed in at least one of the monocrystalline silicon substrate, the amorphous oxide material, the monocrystalline perovskite oxide material and the monocrystalline compound semiconductor material, the switch operative to electrically connect the matching circuitry to a circuit.

98. A process for fabricating a semiconductor structure comprising:
(a) providing a monocrystalline silicon substrate;
(b) depositing a monocrystalline perovskite oxide film overlying the monocrystalline silicon substrate, the film having a thickness less than a thickness of the material that would result in strain-induced defects;
(c) forming an amorphous oxide interface layer containing at least silicon and oxygen at an interface between the monocrystalline perovskite oxide film and the monocrystalline silicon substrate;
(d) epitaxially forming a monocrystalline compound semiconductor layer overlying the monocrystalline perovskite oxide film;
(e) integrating on the semiconductor device a mixer and a controlling device.

99. The process of claim 99 wherein (e) comprises:
(e1) integrating the mixer on the monocrystalline compound semiconductor; and
(e2) integrating the controlling device on the monocrystalline silicon substrate.

100. The process of claim 100 wherein (e) comprises:
(e1) integrating the controlling device as a processor; and
further comprising:
(f) integrating a voltage controlled oscillator on the semiconductor device, the voltage controlled oscillator responsive to the processor and the mixer responsive to the voltage controlled oscillator.

101. A semiconductor structure comprising:
a monocrystalline silicon substrate;
an amorphous oxide material overlying the monocrystalline silicon substrate;
a monocrystalline perovskite oxide material overlying the amorphous oxide material;
a monocrystalline compound semiconductor material overlying the monocrystalline perovskite oxide material;
a mixer formed in at least one of the monocrystalline silicon substrate, the amorphous oxide material, the monocrystalline perovskite oxide material and the monocrystalline compound semiconductor material; and
a controlling device formed in at least one of the monocrystalline silicon substrate, the amorphous oxide material, the monocrystalline perovskite oxide material and the monocrystalline compound semiconductor material, the controlling device electrically connected with the mixer.

102. A process for fabricating a semiconductor structure comprising:
(a) providing a monocrystalline silicon substrate;
(b) depositing a monocrystalline perovskite oxide film overlying the monocrystalline silicon substrate, the film having a thickness less than a thickness of the material that would result in strain-induced defects;
(c) forming an amorphous oxide interface layer containing at least silicon and oxygen at an interface between the monocrystalline perovskite oxide film and the monocrystalline silicon substrate;
(d) epitaxially forming a monocrystalline compound semiconductor layer overlying the monocrystalline perovskite oxide film;
(e) integrating on the semiconductor device a controlled circuit and a memory device, the controlled circuit responsive to the memory device.

103. The process of claim 103 wherein (e) comprises integrating a look-up table on the monocrystalline silicon substrate.

104. A semiconductor structure comprising:
a monocrystalline silicon substrate;
an amorphous oxide material overlying the monocrystalline silicon substrate;
a monocrystalline perovskite oxide material overlying the amorphous oxide material;
a monocrystalline compound semiconductor material overlying the monocrystalline perovskite oxide material;
a memory device formed in at least one of the monocrystalline silicon substrate, the amorphous oxide material, the monocrystalline perovskite oxide material and the monocrystalline compound semiconductor material; and
a controlled circuit formed in at least one of the monocrystalline silicon substrate, the amorphous oxide material, the monocrystalline perovskite oxide material and the monocrystalline compound semiconductor material, the controlled circuit electrically connected with the memory device.
